(19) United States
(12) Patent Application Publication
(10) Pub. No.: US 2014/0061545 A1
(43) Pub. Date: Mar. 6, 2014

(54) BIS(SULFONYL)BIARYL DERIVATIVES AS ELECTRON TRANSPORTING AND/OR HOST MATERIALS

(71) Applicants: Julie Leroy, Brussels (BE); Annabelle Scarpaci, Seattle, WA (US); Stephen Barlow, Atlanta, GA (US); Seth Marder, Atlanta, GA (US); Sung-Jin Kim, Atlanta, GA (US); Bernard Kippelen, Decatur, GA (US); Dengke Cai, Atlanta, GA (US)

(72) Inventors: Julie Leroy, Brussels (BE); Annabelle Scarpaci, Seattle, WA (US); Stephen Barlow, Atlanta, GA (US); Seth Marder, Atlanta, GA (US); Sung-Jin Kim, Atlanta, GA (US); Bernard Kippelen, Decatur, GA (US); Dengke Cai, Atlanta, GA (US)

(73) Assignee: GEORGIA TECH RESEARCH CORPORATION

(21) Appl. No.: 13/882,110

(22) PCT Filed: Dec. 7, 2011
(86) PCT No.: PCT/US11/63760

§ 371 Date: Nov. 8, 2013

Related U.S. Application Data
(60) Provisional application No. 61/421,016, filed on Dec. 8, 2010.

(51) Int. Cl. H01L 51/00

(52) U.S. Cl. CPC H01L 51/0058; H01L 51/005; H01L 51/0052
USPC 252/500; 568/34

(57) ABSTRACT

The inventions disclosed, described, and/or claimed herein relate to bis(sulfonyl)biaryl compounds that are useful as electron transporting materials useful for making novel organic electronic devices, including the electron transport layers of organic light-emitting diodes (“OLEDs”), or as an electron transporting guest for phosphorescent guests in the emissive layer of OLEDs.

### STATEMENT OF GOVERNMENT LICENSE RIGHTS

The inventors received partial funding support through the STC Program of the National Science Foundation under Agreement Number DMR-020967 and the Office of Naval Research through a MURI program, Contract Award Number 68A-1060806. The Federal Government may retain certain license rights in this invention.

### TECHNICAL FIELD OF THE INVENTION

The various inventions disclosed, described, and/or claimed herein relate to bis(sulfonyl)biaryl compounds that are useful as electron transporting and/or hole-blocking materials for making novel organic electronic devices, with specific applications including the electron transporting/hole blocking layers of organic light-emitting diodes, or as electron transporting host materials for phosphorescent guests, for use in making the emissive layer of organic light-emitting diodes.

### BACKGROUND OF THE INVENTION

The prospect of making novel and electronic devices on common substrates, using inexpensive and/or solution processable organic semiconductors, has been the inspiration for much research in recent years. One area of research that has attracted much interest, but yielded only incomplete success has been the area of new electron transporting organic materials for use in making organic light-emitting diodes (“OLEDs”). In such OLED devices, separate organic semiconductor layers are typically used to separately supply negative and positive electrical carriers, called electrons and holes, respectively, to an emission layer comprising an organic host material for a guest phosphor, where the transfer of the holes and the electrons on the host and/or phosphor to form excited states, also known as excitons, which, when located on the phosphor, can emit light through radiative recombination.

While much progress has been made in identifying solid organic materials (small molecules, oligomers, or polymers) capable of conducting electrical current in the form of holes, progress toward identifying stable organic solids with suitable and stable physical properties that are capable of conducting electrical current in the form of electrons has been substantially more limited.

A typical structure for current state-of-the art OLEDs is shown in the diagram shown in FIG. 1. Such OLEDs are typically composed of five layers; i.e. 1) a transparent anode for supplying holes to the device (typically a layer of indium tin oxide (ITO) coated on a glass or plastic substrate), 2) an organic hole transporting layer (HTL), 3) an emissive layer (EL) that comprises an semiconducting organic host material doped with a guest emitter (often a phosphorescent Ir or Pt complex), 4) an electron transporting/hole blocking layer comprising an organic semiconducting electron transport material, then finally 5) an cathode layer for injecting electrons into the device (often a thin layer of LiF in contact with aluminum).

Many OLED devices have been reported that employ red, green or blue emitters, but in most prior art devices several of the OLED layers are typically prepared by expensive vacuum deposition processes rather than by low cost solution processes (such as ink-jet printing) that would lower cost enough to enable many new applications. Furthermore the energy efficiency and/or long term stability of OLEDs that use phosphorescent blue and/or green emitters (as compared to low energy red emitters), are still in need of significant improvements in order to allow for economical and practical preparation of large screen displays and/or in lighting applications. There remains a need for significantly more efficient and more chemically, oxidatively, thermally, and physically stable electron transporting materials for use in the electron transporting/hole blocking layers of OLEDs, and/or host materials for use in the emissive layers of OLEDs employing green or blue phosphorescent emitters.

Producing organic materials that emit light in the green and blue part of the visible spectrum normally requires the use of organic conjugated electron transporting host materials with a limited conjugation length, but such short conjugation lengths can also negatively impact charge transport properties, such as electron mobility. Secondly, the value of the ionization energy (IE) of the organic host material should be close to that of the hole transporting material used in the adjacent hole transporting layer, to facilitate the injection of holes into the emissive layer. Here, ionization energy (IE) is approximated to a positive number and is defined as the energy difference between the vacuum level taken as a reference and the highest occupied molecular orbital (HOMO). Electron affinity (EA) is approximated to a negative number and is defined as the difference in energy between the vacuum level taken as a reference and the lowest occupied molecular orbital (LUMO). Thus, as the LUMO of a compound become increasingly stabilized the absolute value of the EA is increased. Finally, the host material should have good thermal and oxidative stability, and be capable of forming good amorphous films.

Satisfying all these constraints simultaneously, especially in view of the large number of potential variations of the hole transport material, the emitter, and the electron transport material, can be a complex and difficult problem, putting a premium on any potential ability to “tune” the peripheral substituents of the electron transporting or host materials in order to “tune” the resultant electronic and physical properties of the electron transport materials.

Applicants have discovered that the bis(sulfonyl)biaryl compounds described and claimed herein can unexpectedly solve such problems.

Holt and Jeffreys, J. Chem. Soc., 1965, 773, 4204-4205 disclosed a synthesis of the bis-sulfone compound (1) shown below, but did not disclose or suggest any uses as an electron carrier or host material, or in making electronic devices.

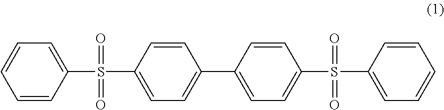 [SMILES: O=S(=O)(c1ccccc1)c1ccc(-c2ccc(S(=O)(=O)c3ccccc3)cc2)cc1]

US Patent Publication 2006/0255332 (and/or its equivalent WO 2005/003253) disclosed the use of a very wide variety of genera and subgenera of organo phosphorus, arsenic, antimony, bismuth, sulfur, selenium, and tellurium compounds as matrix (host) materials for use in OLEDs, including the sub-genera of compounds shown below,

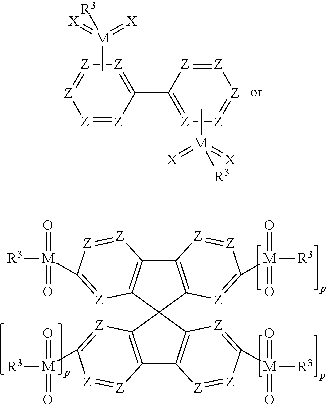

wherein (among many other possibilities) M can be sulfur, X can be oxygen, and Z can be either C—R or N, and p can be zero or one. US 2006/0255332 disclosed the particular spiro-bisfluorene bis-sulfone compound shown below, and disclosed an example of the use of the sulfoxide species compound M3 (shown below) as a host material for green emitters in an OLED.

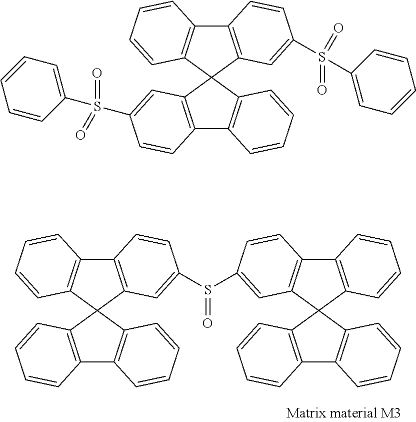 [SMILES: O=S(=O)(c1ccccc1)c1ccc2c(c1)C1(c3ccccc3-2)c2ccccc2-c2ccc(S(=O)(=O)c3ccccc3)cc21 ; O=S(c1ccc2c(c1)C1(c3ccccc3-c3ccccc31)c1ccccc1-2)c1ccc2c(c1)C1(c3ccccc3-c3ccccc31)c1ccccc1-2]

Hsu et al, (J. Mater. Chem., 2009|DOI 10, 1039/b910292b) disclosed a bis-sulfone compound “SAF” having the structure shown below, as an ambipolar host material (i.e. a host material that transmits both holes and electrons) that was suitable for use with phosphorescent red emitters in OLEDs, but Hsu conceded that the SAF compound would be unsuitable for use with blue or green emitters, due to a low energy emission of “SAF” that overlaps poorly with the absorption spectrum of the well known blue phosphor Flrpic or the green phosphor Ir(ppy)₃, “thereby prohibiting efficient energy transfer between the host and these phosphors.”

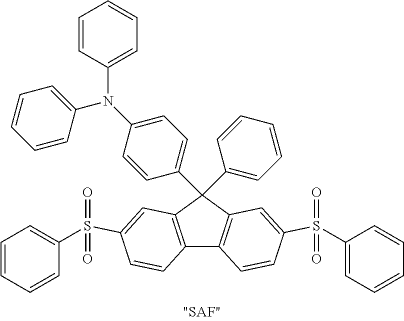 [SMILES: O=S(=O)(c1ccccc1)c1ccc2c(c1)C(c1ccccc1)(c1ccc(N(c3ccccc3)c3ccccc3)cc1)c1cc(S(=O)(=O)c3ccccc3)ccc1-2]

In view of the prior art and the unsolved problems discussed above, there remains an as yet unmet need in the art for improved electron transmitting and/or host materials for use with blue or green photon energy phosphors in OLEDs. Applicants have unexpectedly discovered that a considerable variety of bis(sulfonyl)biaryl compounds can be designed that do not exhibit problematic low photon energy electronic absorptions and emissions, and whose electronic and physical properties can be tuned so that as a result such bis(sulfonyl)biaryl compounds can serve as electron transporting or host materials suitable for use in OLEDs comprising blue or green phosphorescent emitters.

### SUMMARY OF THE INVENTION

In some of their many aspects, the inventions described herein relate to a variety of optionally substituted bis(sulfonyl)biaryl compounds comprising, somewhere within their structure, at least the generic bis(sulfonyl)biaryl group shown in Formula (I) shown below. Many such bis(sulfonyl)biaryl compounds have electronic and physical properties that allow them to serve as semiconducting materials in electronic devices, especially as electron transporting materials or host materials in OLED devices that employ blue or green emitting phosphors.

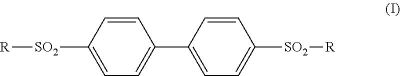

Some bis(sulfonyl)biaryl compounds that comprise the substructure shown in Formula (I) above include at least the following compounds of Formulas (Ia)-(Id) shown below;

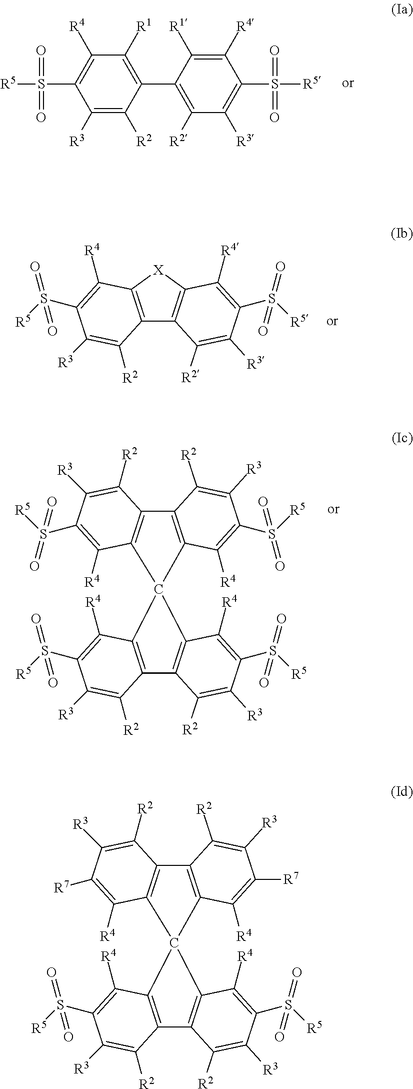

wherein
a. each of R¹-R⁴, R^{1′}-R^{4′} and R⁷ are independently selected from hydrogen, halogen, cyano, or an independently selected and optionally substituted organic group;
b. each of R⁵ and R^{5′} are independently selected from optionally substituted organic groups;
c. X is S, S(O), SO₂, or an organic group selected from C(R⁶)₂, C(R⁶)Ar, C(Ar)₂, Si(R⁶)₂, Si(R⁶)Ar, Si(Ar)₂, NR⁶, NAr, PR⁶, PAr, P(O)R⁶, or P(O)Ar group, wherein
i. R⁶ is an alkyl or perfluoroalkyl group, and
ii. Ar is an aryl or heteroaryl group that does not comprise a diphenyl amine group.

The unique electronic and physical properties of many compounds comprising the bis(sulfonyl)biaryl core Formula (I), such as the compounds of Formulas (Ia), (Ib), (Ic), and (Id), allow them to be used as electron-transporting or host materials to make electronic devices such as OLEDs. Many additional aspects of the inventions described herein relate to compositions and/or devices comprising one or more of the bis(sulfonyl)biaryl compounds, methods for making the various bis(sulfonyl)biaryl compounds, and methods for making organic electronic devices comprising the bis(sulfonyl)biaryl compounds.

Further detailed description of preferred embodiments of the various inventions broadly summarized above will be provided below in the Detailed Description section below. All references, patents, applications, tests, standards, documents, publications, brochures, texts, articles, etc. mentioned herein, either above or below are hereby incorporated herein by reference.

### BRIEF DESCRIPTION OF THE FIGURES

FIG. 1 shows a generic structure diagram of typical state-of-the-art organic light-emitting diodes.

FIG. 2a shows optical absorption and emission spectra of compound (1), (4,4′-Bis(phenylsulfonyl)-1,1′-biphenyl), in methylene chloride solution, and FIG. 2b shows a cyclic voltammogram of (1) in methylene chloride/0.1 Bu₄NPF₆, with ferrocene as an internal reference. See Example 1.

FIG. 3 shows a structure diagram of an OLED device comprising sulfone compound (1) as a host for Flrpic as a guest in the emitting layer of the OLED of Example 2.

FIG. 4 shows the J-V electrical characteristics of two OLED devices 1 and II that employ the sulfone compound (1) as a host for Flrpic in the emitting layer of an OLED, see Example 2.

FIG. 5a show the L-V electrical characteristics and EQE curves of OLED devices I and II that employ the sulfone compound (1) as a host in the emitting layer, see Example 2. FIG. 5b shows the emission spectrum of device II with 6 wt. % Flrpic.

FIG. 6 shows the L-V electrical characteristics and EQE curve of an OLED device that employs the sulfone compound (1) in an electron transport/hole-blocking layer, see Example 3.

FIG. 7a shows the optical absorption and fluorescent emission spectra of compound (2), 9,9-dihexyl-2,7-bis(phenylsulfonyl)-9-fluorene in dichloromethane solution, see Example 4. FIG. 7b shows the phosphorescent emission spectrum of the same compound at 77 K in a 2-methyl-THF glass.

FIG. 8a shows the optical absorption and fluorescent emission spectra of compound (3), 2,7-bis(phenylsulfonyl)-9,9′-spirobi[fluorene] in dichloromethane solution, see Example 5. FIG. 8b shows the phosphorescent emission spectrum of the same compound at 77 K in a 2-methyl-THF glass.

FIG. 9 shows a structure diagram of an OLED device comprising compound (3) as a host for Ir(ppy)₃ guest in the emission layer of the OLED. See Example 6.

FIG. 10 shows the J-V electrical characteristics of an OLED that employs compound (3) as a host in the emitting layer, see Example 6.

FIG. 11 shows the L-V electrical characteristics and EQE curves of an OLED device that employs compound (3) as a host in the emitting layer, see Example 6.

FIG. 12 shows the optical absorption and fluorescent emission spectra of compound (4), 2,2′,7,7′-tetrakis(phenylsulfonyl)-9,9′-spirobi[fluorene], see Example 7.

FIG. 13 shows the cyclic voltammogram of 2,2′,7,7′-tetrakis(phenylsulfonyl)-9,9′-spirobi[fluorene] in dichloromethane/tetrabutyl-ammonium hexafluorophosphate See Example 7.

FIG. 14 shows the optical absorption and fluorescent emission spectra of compound (5), 2,2′,6,6′-tetramethyl-4,4′-bis(phenylsulfonyl)biphenyl, see Example 8.

FIG. 15 shows the results of thermogravimetric analysis for several compounds whose synthesis is exemplified herein.

FIG. 16 shows the J-V characteristics of device employing solution processed compound (4) as a host in the emissive layer of an OLED using a green emitter, see Example 9.

FIG. 17 shows the L-V and EQE curves of the same OLED device.

FIG. 18 shows the J-V characteristics of device employing solution processed compound (4) as a host in the emissive layer of an OLED using a blue emitter, see Example 10.

FIG. 19 shows the L-V and EQE curves of the same OLED device.

FIG. 20 shows the J-V characteristics of device employing vacuum processed compound (5) as a guest in the emissive layer of an OLED using a green emitter, see Example 11.

FIG. 21 shows the L-V and EQE curves of the same OLED device.

FIG. 22 shows the shows a schematic of the resulting OLED device made in Example 12.

FIG. 23 shows the J-V characteristics of an OLED device made in Example 12.

FIG. 24 shows the L-V and EQE curves of the OLED device made in Example 12.

FIG. 25 shows the shows a schematic of the resulting OLED device made in Example 13.

FIG. 26 shows the J-V characteristics of an OLED device made in Example 13.

FIG. 27 shows the L-V and EQE curves of the OLED device made in Example 13.

FIG. 28 shows the shows a schematic of the resulting OLED device made in Example 14.

FIG. 29 shows the J-V characteristics of an OLED device made in Example 14.

FIG. 30 shows the L-V and EQE curves of the OLED device made in Example 14.

FIG. 31 shows the shows a schematic of the resulting OLED device made in Example 15.

FIG. 32 shows the J-V characteristics of an OLED device made in Example 15.

FIG. 33 shows the L-V and EQE curves of the OLED device made in Example 15.

FIG. 34 shows the shows a schematic of the resulting OLED device made in Example 16.

FIG. 35 shows the J-V characteristics of an OLED device made in Example 16.

FIG. 36 shows the L-V and EQE curves of the OLED device made in Example 16.

FIG. 37 shows the shows a schematic of the resulting OLED device made in Example 17.

FIG. 38 shows the J-V characteristics of an OLED device made in Example 17.

FIG. 39 shows the L-V and EQE curves of the OLED device made in Example 17.

FIG. 40 shows the shows a schematic of the resulting OLED device made in Example 18.

FIG. 41 shows the J-V characteristics of an OLED device made in Example 18.

FIG. 42 shows the L-V and EQE curves of the OLED device made in Example 18.

FIG. 43 shows the shows a schematic of the resulting OLED device made in Example 19.

FIG. 44 shows the J-V characteristics of an OLED device made in Example 19.

FIG. 45 shows the L-V and EQE curves of the OLED device made in Example 19.

FIG. 46 shows the shows a schematic of the resulting OLED device made in Example 20.

FIG. 47 shows the J-V characteristics of an OLED device made in Example 20.

FIG. 48 shows the L-V and EQE curves of the OLED device made in Example 20.

FIG. 49 shows the shows a schematic of the resulting OLED device made in Example 21.

FIG. 50 shows the J-V characteristics of an OLED device made in Example 21.

FIG. 51 shows the L-V and EQE curves of the OLED device made in Example 21.

FIG. 52 shows the shows a schematic of the resulting OLED device made in Example 22.

FIG. 53 shows the J-V characteristics of an OLED device made in Example 22.

FIG. 54 shows the L-V and EQE curves of the OLED device made in Example 22.

FIG. 55 shows the shows a schematic of the resulting OLED device made in Example 23.

FIG. 56 shows the J-V characteristics of an OLED device made in Example 23.

FIG. 57 shows the L-V and EQE curves of the OLED device made in Example 23.

FIG. 58 shows the shows a schematic of the resulting OLED device made in Example 24.

FIG. 59 shows the J-V characteristics of an OLED device made in Example 24.

FIG. 60 shows the L-V and EQE curves of the OLED device made in Example 24.

FIG. 61 shows the shows a schematic of the resulting OLED device made in Example 25.

FIG. 62 shows the J-V characteristics of an OLED device made in Example 25.

FIG. 63 shows the L-V and EQE curves of the OLED device made in Example 25.

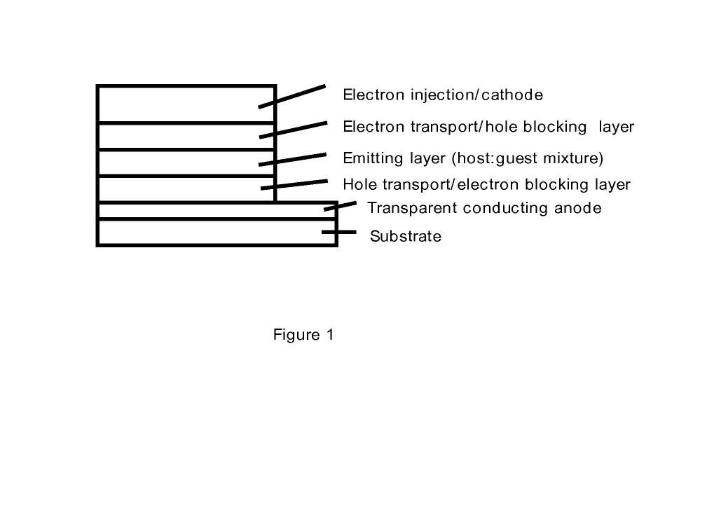

### DETAILED DESCRIPTION OF THE INVENTION

Many aspects, embodiments, sub-genera, and other more specific features or embodiments of the broad inventions initially disclosed and described above will now be set forth more fully in the detailed description that follows. As will become apparent to those having ordinary skill in the art upon examination of the following detailed description, and/or may be better known or understood in view of the background information and prior art discussed above or below, and practice of the present invention, the advantages of some aspects or embodiments of the multiple inventions described herein can be realized and obtained as particularly pointed out in the appended claims. As will be also realized by one of ordinary skill, the present invention is capable of other and different embodiments, and its several details are capable of modifications in various obvious respects, all without departing from the inventions disclosed and/or described herein. The description below is to be regarded as illustrative in nature, and not as restrictive of the various inventions defined by the claims.

### DEFINITIONS

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a +−10% variation from the nominal value unless otherwise indicated or inferred.

As used herein, the term “electronic device” refers to a man-made device comprising one or more of the organic compounds described herein, or mixtures thereof, whose functions involve the flow or modulation of electrical currents (in the form or either holes or electrons) or voltages within the device.

As used herein, “halo” or “halogen” refers to fluoro, chloro, bromo, and iodo.

For purposes of this document, the term “organic group” is intended to include any chemical group that is portion or part or a parent compound that contains at least one carbon atom bonded to at least one hydrogen atom, halogen atom, other carbon atom, or heteroatom (including at least N, O, S, P, Se, metalloid, or a main group, transition, lanthanide, or actinide metal atom). Organic groups are preferably thermally, chemically, and electrochemically stable and resistant to decomposition under the thermal and electrical conditions of operation of an organic electronic device comprising a compound comprising the organic group for at least about one hour or typically operation of electronic devices comprising the parent compound, such as OLEDs, transistors, and/or photovoltaic devices. Organic groups can contain any number of carbon atoms, but preferably comprise C₁-C₃₀ organic groups, C₁-C₂₀ organic groups, C₁-C₁₂ organic groups, C₁-C₄ organic groups C₂-C₃₀ organic groups, C₄-C₃₀ organic groups and C₆-C₃₀ organic groups. Preferred organic groups include alkyl, perfluoroalkyl, alkoxy, perfluoroalkoxy (any of which may be normal, branched, or cyclic) and, aryl, and heteroaryl groups. Organic groups can be optionally substituted, by hypothetical removal of at least one hydrogen atom from the organic group and its replacement with another organic group, heteroatom and/or heteroatomic group to form a carbon-carbon or carbon-heteroatom bond, such as for example substitution by halogens, alkoxy groups, amino groups, carboxylic acid ester groups, aryl groups, heteroaryl groups, and the like.

For purposes of this document, the term “alkyl” is intended to include any hydrocarbon group that contains only carbon-carbon or carbon-hydrogen single bonds (as opposed to double or triple bonds). Alkyls include normal, branched, and/or cyclic alkyls, and include C₁-C₃₀ alkyls, C₁-C₁₀ alkyls, C₁-C₁₂ alkyls, C₁-C₄ alkyls C₂-C₃₀ alkyls, C₄-C₃₀ alkyls, and C₆-C₃₀ alkyls. Examples of alkyls include methyl, ethyl, n-propyl, i-propyl, n-butyl, i-butyl, t-butyl, cyclopentyl, cyclohexyl, and the like. Alkyls can be optionally substituted by hypothetical removal of at least one hydrogen atom and its replacement with a heteroatom or heteroatomic group to form a carbon-heteroatom bond, such as for example substitution by one or more halogens, alkoxy groups, carboxylic acid ester groups, and the like. Perfluoroalkyls are alkyls that comprise no carbon-hydrogen bonds, but only carbon-carbon and carbon-fluorine single bonds.

For purposes of this document, the term “alkoxy” is intended to include any group bonded to a parent compound via an oxygen atom that is also terminally bonded to an alkyl group as defined above, or another alkoxy group, to form an ether group. Examples of alkoxy groups include methoxyl, ethoxyl, n-propoxyl, i-propoxyl, n-butoxyl, i-butoxyl, t-butoxyl, methoxymethyl, ethoxymethyl, and the like. Perfluoroalkoxys are alkoxy groups that comprise no carbon-hydrogen bonds, but only carbon-carbon, carbon-oxygen, and carbon-fluorine single bonds.

As used herein, “aryl” refers to an aromatic monocyclic hydrocarbon ring system or a polycyclic ring system in which two or more aromatic hydrocarbon rings are fused (i.e., having a bond in common with) together or at least one aromatic monocyclic hydrocarbon ring is fused to one or more cycloalkyl and/or cycloheteroalkyl rings. An aryl group can have 6 to 30 carbon atoms in its ring system and/or any organic substituent groups bonded thereto, which can include multiple fused rings. In some embodiments, a polycyclic aryl group can have 6 to 20 carbon atoms. Any suitable ring position of the aryl group can be covalently linked to the defined chemical structure. Examples of aryl groups having only aromatic carbocyclic ring(s) include phenyl, 1-naphthyl(bicyclic), 2-naphthyl(tricyclic), anthracenyl(tricyclic), phenanthrenyl(tricyclic), pentacenyl(pentacyclic), and like groups. Examples of polycyclic ring systems in which at least one aromatic carbocyclic ring is fused to one or more cycloalkyl and/or cycloheteroalkyl rings include, among others, benzo derivatives of cyclopentane (i.e., an indanyl group, which is a 5,6-bicyclic cycloalkyl/aromatic ring system), cyclohexane (i.e., a tetrahydronaphthyl group, which is a 6,6-bicyclic cycloalkyl/aromatic ring system), imidazoline (i.e., a benzimidazolinyl group, which is a 5,6-bicyclic cycloheteroalkyl/aromatic ring system), and pyran (i.e., a chromenyl group, which is a 6,6-bicyclic cycloheteroalkyl/aromatic ring system). Other examples of aryl groups include benzodioxanyl, benzodioxolyl, chromanyl, indolinyl groups, and the like. In some embodiments, aryl groups can be substituted as described herein. In some embodiments, an aryl group can have one or more halogen substituents, and can be referred to as a “haloaryl” group. Perhaloaryl groups, i.e., aryl groups where all of the hydrogen atoms are replaced with halogen atoms (e.g., —C6F5), are included within the definition of “haloaryl.” In certain embodiments, an aryl group is substituted with at least one additional alkyl, perfluoroalkyl, alkoxy, perfluoroalkoxyl, or aryl group

As used herein, “heteroaryl” refers to an aromatic monocyclic ring system containing at least one ring heteroatom selected from oxygen (O), nitrogen (N), sulfur (S), silicon (Si), and selenium (Se) or a polycyclic ring system where at least one of the rings present in the ring system is aromatic and contains at least one ring heteroatom. Polycyclic heteroaryl groups include those having two or more heteroaryl rings fused together, as well as those having at least one monocyclic heteroaryl ring fused to one or more aromatic carbocyclic rings, non-aromatic carbocyclic rings, and/or non-aromatic cycloheteroalkyl rings. A heteroaryl group, as a whole, can have, for example, 5 to 24 ring atoms and contain 1-5 ring heteroatoms (i.e., 5-20 membered heteroaryl group). The heteroaryl group can be attached to the defined chemical structure at any heteroatom or carbon atom that results in a stable structure. Generally, heteroaryl rings do not contain O—O, S—S, or S—O bonds. However, one or more N or S atoms in a heteroaryl group can be oxidized (e.g., pyridine N-oxide, thiophene S-oxide, thiophene S,S-dioxide). Examples of heteroaryl groups include, for example, the 5- or 6-membered monocyclic and 5-6 bicyclic ring systems shown below:

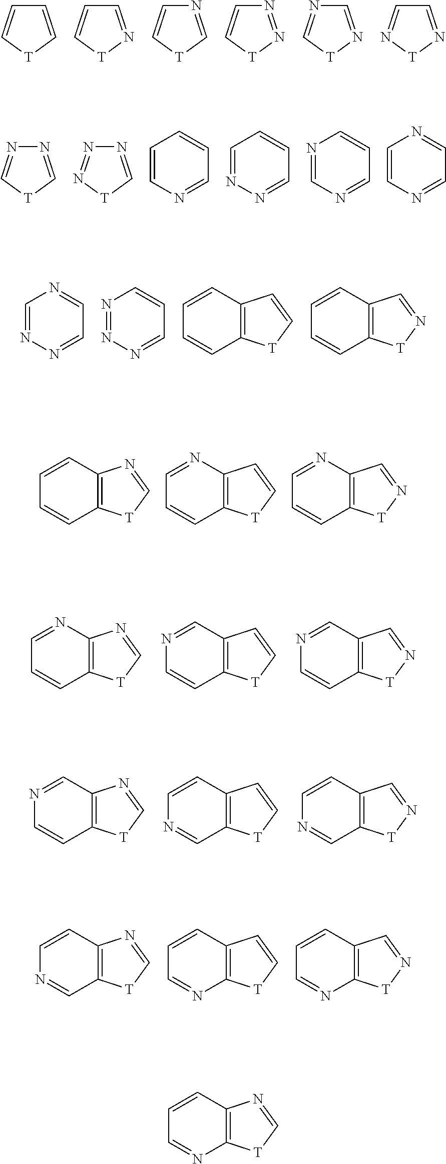

where T is O, S, NH, N-alkyl, N-aryl, N-(arylalkyl) (e.g., N-benzyl), SiH(alkyl), Si(alkyl)₂, SiH(arylalkyl), Si(arylalkyl)₂, or Si(alkyl)(arylalkyl). Examples of such heteroaryl rings include pyrrolyl, furyl, thienyl, pyridyl, pyrimidyl, pyridazinyl, pyrazinyl, triazolyl, tetrazolyl, pyrazolyl, imidazolyl, isothiazolyl, thiazolyl, thiadiazolyl, isoxazolyl, oxazolyl, oxadiazolyl, indolyl, isoindolyl, benzofuryl, benzothienyl, quinolyl, 2-methylquinolyl, isoquinolyl, quinoxalyl, quinazolyl, benzotriazolyl, benzimidazolyl, benzotbiazolyl, benzisothiazolyl, benzisoxazolyl, benzoxadiazolyl, benzoxazolyl, cinnolinyl, 1H-indazolyl, 2H-indazolyl, indolizinyl, isobenzofuyl, naphthyridinyl, phthalazinyl, pteridinyl, purinyl, oxazolopyridinyl, thiazolopyridinyl, imidazopyridinyl, furopyridinyl, thienopyridinyl, pyridopyrimidinyl, pyridopyrazinyl, pyridopyridazinyl, thienothiazolyl, thienoxazolyl, thienoimidazolyl groups, and the like. Further examples of heteroaryl groups include 4,5,6,7-tetrahydroindolyl, tetrahydroquinolinyl, benzothienopyridinyl, benzofuropyridinyl groups, and the like. In some embodiments, heteroaryl groups can be substituted as described herein.

### Requirements for Electron Transport and Host Materials for OLED Applications

To serve as a good electron transport material/layer for supplying electrons to OLED emission layers, the absolute value of the electron affinity (|EA|) of the electron transport material (related to the energy required to inject an electron into the lowest unoccupied molecular orbital (“LUMO”) of the electron transporting molecules) should be sufficiently high to permit facile electron injection from the cathode, but sufficiently low to present a relatively low barrier to electron injection into the adjacent emissive layer. The ionization energy (IE) of the electron transporting material (related to the energy required to remove an electron from the highest occupied molecular orbital (“HOMO”) of the electron transporting molecules) should also be significantly higher than the IE of the host material used in the emission layer, to provide good hole blocking properties in the electron transport layer. The electron transporting material should also have good thermal and oxidative stability, and be capable of forming good amorphous films in contact with the emissive layer.

To serve as a good hole transport material/layer for supplying holes to OLED emission layers, the value of IE of the hole transport material should be sufficiently low to permit facile hole injection from the anode, but sufficiently high to present a relatively low barrier to hole injection into the adjacent emissive layer. The absolute value of the electron affinity (|EA|) of the hole transporting material should also be significantly lower than the |EA| of the host material used in the emission layer, to provide good electron blocking properties in the hole transport layer. The hole transporting material should also have good thermal and oxidative stability, and be capable of forming good amorphous films in contact with the emissive layer.

To serve as a good host for higher photon energy blue and green emitters, a host material should fulfill multiple requirements. The absolute value of the EA, |EA|, of the host material should be sufficiently high that it can easily accept electrons from the electron transport layer, and the value of the IE should be sufficiently low that holes are readily injected from the hole transport layer, so that both holes and electrons can be injected into one or both of the host or the guest to form excitons.

When singlet or triplet excitons are formed in the host material, their energies (i.e., the energies of the lowest energy singlet and triplet excited states of the host) should be higher in energy than the corresponding lowest singlet and triplet excited states of the guest emitter, respectively, to favor an exergonic transfer of energy from the host to the guest. If the energy of the lowest triplet state of the host were lower than that of the guest phosphor, energy would not be transferred efficiently from the host to the guest. Flrpic (iridium(III)bis[(4,6-di-fluorophenyl)-pyridinato-N,C^{2′}]picolinate), a well known blue-green emitter has been reported to have a lowest excited triplet state at an energy of about 2.7 eV above the ground singlet state (see Chopra et al, IEEE Transactions on Electron Devices, 2010, Vol 57(1), 101-107). Ir(ppy)₃ (Iridium tris-2-phenylpyridinato-N,C^{2′}), a well known green emitter, has been reported to have a lowest triplet excited state energy of about 2.4 eV. M. A. Baldo et al. Phys. Rev. B 2000, 62, 16, 10958-10966.

Furthermore, in order for efficient energy transfer to occur from singlet excitons on the host to produce singlet excitons on the guest emitter (via Förster energy transfer, see Charge and Energy Transfer Dynamics in Molecular Systems, V. May and O. Kuhn, Wiley-VCH, Weinheim, 2004), there must be significant overlap between the fluorescent emission spectrum of the host material and the optical absorption spectrum of the guest phosphor.

Bis(Organo-Sulfonyl)-Biaryl Compounds

In some of their many aspects, the inventions described herein relate to a variety of optionally substituted bis(sulfonyl)biaryl compounds comprising somewhere within their structure at least the generic Formula (I) shown below. Compounds that comprise the bis(sulfonyl)biaryl group (1) typically have electronic and physical properties that allow them to serve as electron transmitting materials in electronic devices such as OLEDs, and are can also be suited for use as host materials in OLED devices that comprise blue or green emitting phosphors.

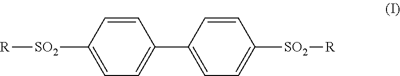

Some of the subgenera of such optionally bis(sulfonyl)biaryl compounds include at least the following sub-genera of compounds having Formulas (Ia)-(Id):

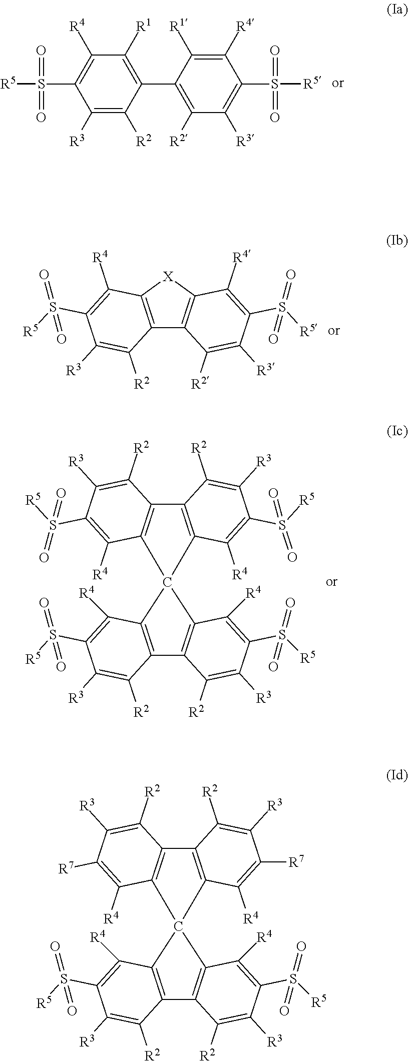

wherein
a. each of R¹-R⁴, R^{1′}-R^{4′} and R⁷ are independently selected from hydrogen, halogen, cyano, or an independently selected and optionally substituted organic group, wherein the organic group can be preferably selected from optionally substituted C₁-C₃₀ organic groups including alkyl, perfluoroalkyl, alkoxy, perfluoroalkoxy, aryl, and heteroaryl groups, or more preferably from hydrogen, cyano, and C₁-C₂₀ alkyl, and perfluoroalkyl groups;
b. each of R⁵ and R^{5′} are independently selected from optionally substituted organic groups, wherein the organic groups can preferably be independently selected from optionally substituted C₁-C₃₀ organic groups selected from alkyl, perfluoroalkyl, alkoxy, perfluoroalkoxy, aryl, or heteroaryl groups;
c. X is S, S(O), SO₂, or a C₁-C₃₀ organic group selected from C(R⁶)₂, C(R⁶)Ar, C(Ar)₂, Si(R⁶)₂, Si(R⁶)Ar, Si(Ar)₂, NR⁶, NAr, PR⁶, PAr, P(O)R⁶, or P(O)Ar group, wherein
   i. R⁶ is an alkyl or perfluoroalkyl group, and
   ii. Ar is an aryl or heteroaryl group that does not comprise a diphenyl amine group.

The bis(sulfonyl)biaryl compounds of Formulas (Ia)-(Id) are typically capable of being reduced by acceptance of electrons into their lowest unoccupied molecular orbital (LUMO) without chemical decomposition, as evidenced by the electrochemical data provided below. Because the sulfone groups do not substantially conjugate with the LUMOs on the biaryl groups, but the sulfone groups nevertheless exert a strong electron withdrawing effect on the aryl groups, both the LUMOs and HOMOs on the aryl groups tend to be stabilized relative to vacuum. As a result the IEs of the bis(sulfonyl)biaryl compounds of Formulas (Ia)-(Id) are often sufficiently high that they can sometimes have significant hole blocking properties when used as electron transport materials.

However in some cases the IEs can be sufficiently low that holes can be injected into host materials comprising the bis(sulfonyl)biaryl compounds, at least when used in combination with other commonly used electrodes and hole transport materials.

Moreover, the difference in the energies between the ground and first excited singlet state (“the optical bandgap”) of the bis(sulfonyl)biaryl compounds of Formulas (Ia)-(Id) is typically relatively large. Specifically, as a result of the relatively limited conjugation of the aryl groups of the bis(sulfonyl)biaryl compounds, and the inductive electron withdrawing capability of the sulfone groups, the lowest energy singlet and triplet excited states of the compounds of Formulas (Ia)-(Id) tend to have relatively high energies. As a result singlet and triplet excited states energies formed by the localization of holes and electrons within this material, most typically on individual host molecules, are sufficiently high that efficient energy transfer to the green or blue-emitting phosphors can take place from both singlet and triplet excited states. Accordingly, many of the bis(sulfonyl)biaryl compounds of Formulas (Ia)-(Id) can be used as host materials for OLEDs that employ high photon energy green or blue emitter guests.

However, if peripheral groups such as those from primary, secondary, or tertiary amine groups were to reduce the IE of these molecules, the electron rich lone pair on the amine group could in some cases, such as in the “SAF” compound of Hsu, raise the energy of the highest occupied molecular orbital (HOMO) relative to that of a compound lacking such a peripheral group. The presence of such a HOMO can therefore introduce an undesirable low energy singlet and/or triplet excited state that could render the materials unsuitable for transferring energy to blue or green emitting phosphors in OLEDs, as was admitted by Hsu et al.

Accordingly, in order to maintain high optical band gap energies so as to enable singlet energy transfer to high photon energy green or blue emitters, peripheral substituent groups that significantly raise the HOMO energy and lower the IE should normally be avoided.

Therefore, in many embodiments of the compounds of Formulas (Ia)-(Id), none of R¹-R⁴, R^{1′}-R^{4′}, R⁵-R^{5′}, Ar, R⁶, or R⁷ substituent groups of the bis(sulfonyl)biaryl compounds of Formulas (Ia)-(Id) comprise a primary, secondary, or tertiary amine group, such as for example a diphenyl amine group. It should however also be clarified that nitrogen atoms incorporated directly into the aromatic rings of heteroaryl groups, such as pyridine groups, do not ordinarily result in the undesirable destabilization of the HOMO or introduction of low energy excited states, and therefore such nitrogenous heteroaryl substituents may be present at R¹-R⁴, R^{1′}-R^{4′}, R⁵-R^{5′}, Ar, R⁶, or R⁷.

In some preferred embodiments of the compounds of Formulas (Ia)-(Id), each of R¹-R⁴, R^{1′}-R^{4′} and R⁷ can be independently selected from hydrogen, cyano, alkyl, and perfluoroalkyl groups.

In some embodiments of the compounds of Formulas (Ia)-(Id), R⁵ and R^{5′} can be independently selected alkyl or perfluoroalkyl groups, or alternatively R⁵ and R^{5′} can be independently selected aryl groups having the structure

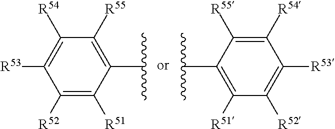

wherein each of R⁵¹-R⁵⁵ and R^{51′}-R^{55′} are independently selected from hydrogen, halogen, cyano, or an independently selected and optionally substituted C₁-C₃₀ organic groups selected from alkyl, perfluoroalkyl, alkoxy, perfluoroalkoxy, aryl, or heteroaryl group.

In many embodiments of the compounds of Formulas (Ia)-(Id), in order for the compounds to be useful as hosts for blue or green phosphorescent emitters in OLEDs, the compounds preferably have lowest energy singlet and triplet excited state energies that are at least equal to or preferably somewhat higher in energy than the corresponding singlet or triplet excited states of the guest blue or green emitters, so that exergonic electron and/or energy transfer from the compounds of Formulas (Ia)-(Id) to the guest emitters can occur. Examples of well known emitter complexes include the well known blue emitter Ir complex “Flrpic”, which has been reported to have a lowest excited triplet state at about 2.7 eV and the well known green emitter complex Ir(ppy)₃, which has a lowest triplet excited state at about 2.4 eV. Clearly however, the excited state energies of other green or blue emitter guests may vary somewhat.

Therefore, in some embodiments, the compounds of Formulas (Ia)-(Id) are suitable for use as hosts for green emitters, and therefore can have a lowest singlet excited state at an energy of about 2.27 eV or higher, and a lowest triplet excited state at an energy of about 2.17 eV or higher. In some preferred embodiments, the singlet and triplet energies are higher, i.e. the compounds of Formulas (Ia)-(Id) suitable for use as hosts for green emitters, can have a lowest singlet excited state at an energy of about 2.48 eV or higher, and a lowest triplet excited state at an energy of about 2.40 eV or higher.

In other embodiments, the compounds of Formulas (Ia)-(Id) are suitable for use as hosts for blue emitters, and can have a lowest singlet excited state at an energy of 2.63 eV or higher, and a lowest triplet excited state that yields a peak phosphorescence at an energy of 2.53 eV or higher. In some preferred embodiments, the compounds of Formulas (Ia)-(Id) suitable for use as hosts for blue emitters, can have a lowest singlet excited state at an energy of about 2.75 eV or higher, and a lowest triplet excited state at an energy of about 2.70 eV or higher.

Without wishing to be bound by theory, fluorescence and phosphorescence spectroscopy can be used to experimentally measure the energies of the singlet and triplet states of the compounds of Formulas (Ia)-(Id). Methods for measuring the fluorescence and phosphorescence spectra of the organic compounds of Formulas (Ia)-(Id), in order to experimentally measure the energies of their singlet and triplet energies are described in the Example section below.

As already noted above however, for transfer of energy from singlet excitons in the bis(sulfonyl)biaryl host compounds of Formulas (Ia)-(Id) to the guest phosphorescent emitter employed to occur efficiently in practice, the fluorescent emission spectrum of the bis(sulfonyl)biaryl compounds must also overlap to at least some extent with the absorption spectrum of the particular guest phosphorescent emitter employed in the particular device.

In any one or all of the sub-genera of compounds of Formulas (Ia)-(Id), it is often possible for one of ordinary skill in the art, in view of the teachings herein, to rationally vary and/or select the substitution positions and identity of the various “R” substituent groups cited above in order to rationally “tune” the electronic and/or electrochemical properties of the compounds of Formulas (Ia)-(Id), so that they better “match” the energies of the corresponding guest materials and/or materials in adjacent layers of electronic devices, in order to promote efficient transfer of electrons, holes, and/or energy toward the guest emitters.

In some embodiments, the inventions relate to a subgenus of compounds of Formula (Ia) having the formula

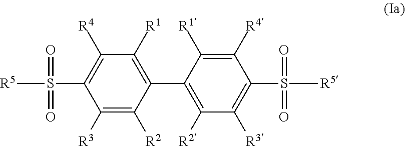

wherein
a. each of R¹-R⁴ and R^{1′}-R^{4′} are independently selected from hydrogen, halogen, cyano, or an independently selected and optionally substituted C₁-C₃₀ organic group selected from alkyl, periluoroalkyl, alkoxy, perfluoroalkoxy, aryl, and heteroaryl groups, with the proviso that at least one of R¹-R⁴ and R^{1′}-R^{4′} are not hydrogen; and
b. each of R⁵ and R^{5′} are independently selected from optionally substituted C₁-C₃₀ organic groups selected from alkyl, perfluoroalkyl, alkoxy, perfluoroalkoxy, aryl, or heteroaryl groups.

In such embodiments of the compounds of Formula (Ia), the use of one or more non-hydrogen substitutents at one or more of R¹, R^{1′}, R², or R^{2′} can be used to induce steric interactions between the two aryl rings that tend to cause the two aryl rings to rotate out of plane with respect to each other, decreasing the degree of electronic conjugation between them, and thereby raising the energies of the singlet and triplet excited states. Accordingly, in some embodiments of the compounds of Formula (Ia), at least one of R¹ and R^{1′} is independently selected from optionally substituted fluoro, cyano, or C₁-C₃₀ alkyl, alkoxy, perfluoroalkyl, perfluoroalkoxy, aryl, and heteroaryl groups. In some embodiments of the compounds of Formula (Ia), at least two, or at least three, or four of the R¹, R^{1′}, R², and R^{2′} groups can be independently selected from optionally substituted fluoro, cyano, or C₁-C₃₀ alkyl, alkoxy, perfluoroalkyl, perfluoroalkoxy, aryl, and heteroaryl groups.

In some embodiments, the invention relates to subgenera of compounds Formula (Ib);

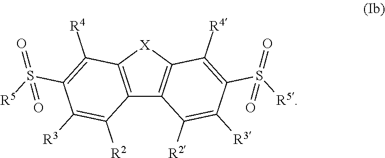

wherein
a. each of R¹-R⁴ and R^{1′}-R^{4′} are independently selected from hydrogen, halogen, cyano, or an independently selected and optionally substituted C₁-C₃₀ organic group selected from alkyl, perfluoroalkyl, alkoxy, perfluoroalkoxy, aryl, and heteroaryl groups;
b. each of R⁵ and R^{5′} are independently selected from optionally substituted C₁-C₃₀ organic groups selected from alkyl, perfluoroalkyl, alkoxy, perfluoroalkoxy, aryl, or heteroaryl groups;
c. X is S, S(O), SO₂, or a C₁-C₃₀ organic group selected from C(R⁶)₂, C(R⁶)Ar, C(Ar)₂, Si(R⁶)₂, Si(R⁶)Ar, Si(Ar)₂, NR⁶, NAr, PR⁶, PAr, P(O)R⁶, or P(O)Ar group, wherein
   i. R⁶ is a C₁-C₂₀ alkyl or perfluoroalkyl group,
   ii. Ar is a C₁-C₃₀ aryl or heteroaryl group that does not comprise a diphenyl amine group.

In some embodiments of the compounds of Formula (Ib), X can be S, S(O), SO₂, or a C₁-C₃₀ organic group selected from C(R⁶)₂, C(R⁶)Ar, Si(R⁶)₂, Si(R⁶)Ar, NR⁶, NAr, PR⁶, PAr, P(O)R⁶, or P(O)Ar group. In some related embodiments, X is a S, S(O), SO₂, or a C₁-C₃₀ organic group selected from C(R⁶)₂, C(R⁶)Ar, Si(R⁶)₂, Si(R⁶)Ar, or Si(Ar)₂, group.

In some embodiments of the compounds of Formula (Ib), X can be a C(R⁶)₂, C(R⁶)Ar, or C(Ar)₂ group, so that the compound is a bis-sulfonyl-fluorene derivative. In such embodiments, Ar is preferably a phenyl, fluorinated phenyl, pyridyl, pyrazine, or pyridazine group. In such embodiments, R⁶ can preferably be independently selected from hydrogen, fluoride, cyano, C₁-C₄ alkyl, C₁-C₄ perfluoroalkyl, phenyl, and perflurophenyl groups.

In some embodiments of the compounds of Formula (Ib), X can be a C(R⁶)₂ or C(R⁶)Ar group.

In some embodiments, the invention relates to spiro-bisfluorene-tetrasulfone compounds of Formula (Ic);

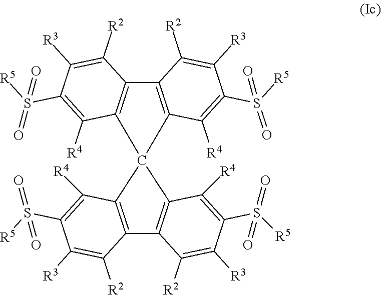

wherein
a. each of R¹-R⁴ and R^{1′}-R^{4′} are independently selected from hydrogen, halogen, cyano, or an independently selected and optionally substituted C₁-C₃₀ organic group selected from alkyl, perfluoroalkyl, alkoxy, perfluoroalkoxy, aryl, and heteroaryl groups;
b. each of R⁵ and R^{5′} are independently selected from optionally substituted C₁-C₃₀ organic groups selected from alkyl, perfluoroalkyl, alkoxy, perfluoroalkoxy, aryl, or heteroaryl groups.

In some embodiments, the invention relates to spiro-bisfluorene-bis-sulfone compounds of Formula (Id);

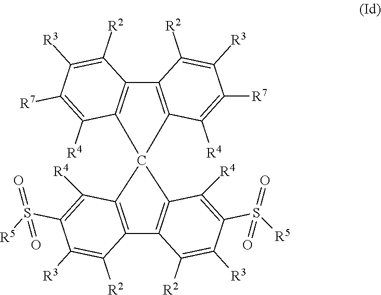

wherein
a. each of R¹-R⁴, R^{1′}-R^{4′} and R⁷ can be independently selected from hydrogen, halogen, cyano, or an independently selected and optionally substituted C₁-C₃₀ organic groups selected from alkyl, perfluoroalkyl, alkoxy, perfluoroalkoxy, aryl, and heteroaryl groups;
b. each of R⁵ and R^{5′} can be independently selected from optionally substituted C₁-C₃₀ organic groups selected from alkyl, perfluoroalkyl, alkoxy, perfluoroalkoxy, aryl, or heteroaryl groups.

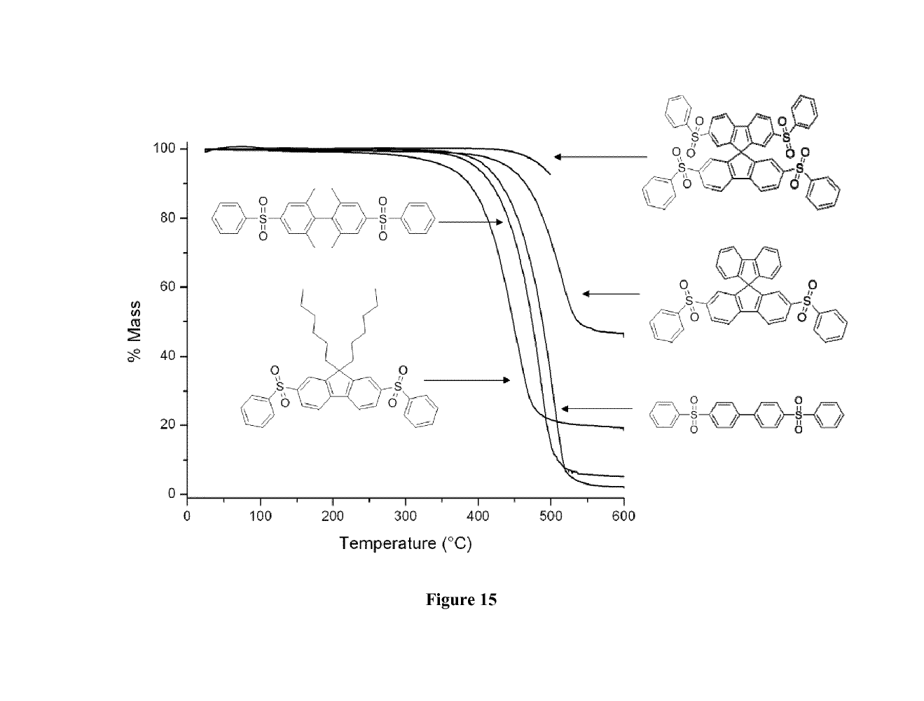

The compounds of Formulas (Ia)-I(d) are typically very stable thermally and electrochemically. For example, FIG. 15 shows the results of thermogravimetric analysis of five compounds whose synthesis is exemplified herein below. Most temperatures of thermal decomposition are above 350° C. Results of thermal analysis of these compounds by differential scanning calorimetry are summarized in Table 1 below.

TABLE 1
DSC measurements of synthesized compounds.

| Compound | Tg (° C.) | Tm (° C.) | Tc (° C.) |
|---|---|---|---|
| 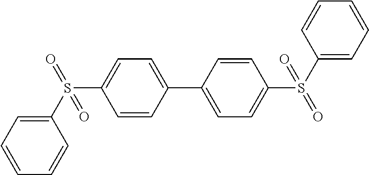 [SMILES: O=S(=O)(c1ccccc1)c1ccc(-c2ccc(S(=O)(=O)c3ccccc3)cc2)cc1] | n/a | 267^{a} | n/a |
| 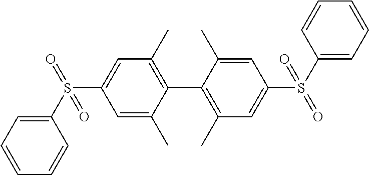 [SMILES: Cc1cc(S(=O)(=O)c2ccccc2)cc(C)c1-c1c(C)cc(S(=O)(=O)c2ccccc2)cc1C] | 93^{b} | 265^{a, b} | 134^{b} |
| 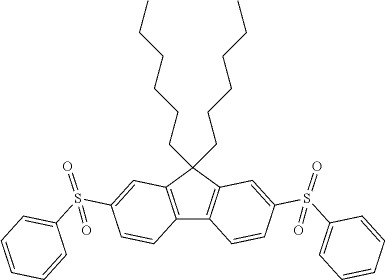 [SMILES: CCCCCCC1(CCCCCC)c2cc(S(=O)(=O)c3ccccc3)ccc2-c2ccc(S(=O)(=O)c3ccccc3)cc21] | 31^{b} | 159^{a, b} | 97^{b} |
| 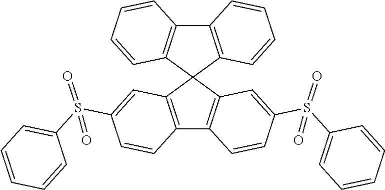 [SMILES: O=S(=O)(c1ccccc1)c1ccc2c(c1)C1(c3ccccc3-c3ccccc31)c1cc(S(=O)(=O)c3ccccc3)ccc1-2] | 125^{a, b} | 261^{a} | 161^{a} |
| 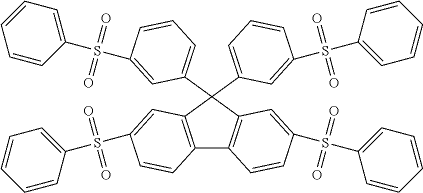 [SMILES: O=S(=O)(c1ccccc1)c1cccc(C2(c3cccc(S(=O)(=O)c4ccccc4)c3)c3cc(S(=O)(=O)c4ccccc4)ccc3-c3ccc(S(=O)(=O)c4ccccc4)cc32)c1] | n/a | 363^{a, b} | 287^{c} |

Rate: 5° C./min. Two scans were recorded for each compound.
Tg: glass transition temperature.
Tm: melting point temperature.
Tc: crystallization temperature..
^{a}observed in the first scan on heating.
^{b}observed in the second scan on heating.
^{c}observed in the first and second scan on cooling from melting.

Electrochemical analyses of several synthesized compounds were carried out by cyclic voltammetry in various solvents and tetrabutylammonium hexafluorophosphate supporting electrolytes, using ferrocene as an internal reference. Typically, two reversible reductions were observed, and the results are summarized in Table 2 below.

TABLE 2
Electrochemistry measurements of synthesized compounds vs the ferrocenium/ferrocene couple.

| | 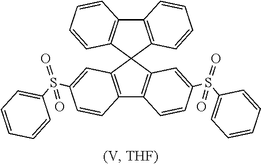 [SMILES: O=S(=O)(c1ccccc1)c1ccc2c(c1)C1(c3ccccc3-c3ccccc31)c1cc(S(=O)(=O)c3ccccc3)ccc1-2] | 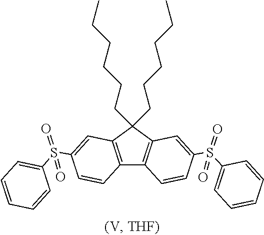 [SMILES: CCCCCCC1(CCCCCC)c2cc(S(=O)(=O)c3ccccc3)ccc2-c2ccc(S(=O)(=O)c3ccccc3)cc21] | 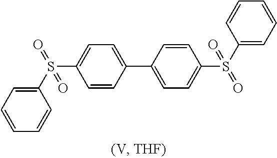 [SMILES: O=S(=O)(c1ccccc1)c1ccc(-c2ccc(S(=O)(=O)c3ccccc3)cc2)cc1] |
|---|---|---|---|
| E_{1/2/0/-1} | −2.12 | −2.19 | −2.16 |
| | 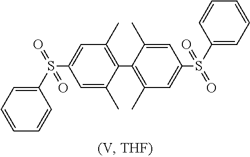 [SMILES: Cc1cc(S(=O)(=O)c2ccccc2)cc(C)c1-c1c(C)cc(S(=O)(=O)c2ccccc2)cc1C] | 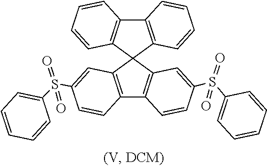 [SMILES: O=S(=O)(c1ccccc1)c1ccc2c(c1)C1(c3ccccc3-c3ccccc31)c1cc(S(=O)(=O)c3ccccc3)ccc1-2] | 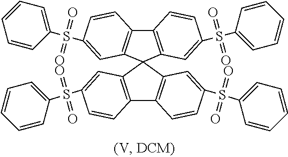 [SMILES: O=S(=O)(c1ccccc1)c1ccc2c(c1)C1(c3cc(S(=O)(=O)c4ccccc4)ccc3-2)c2cc(S(=O)(=O)c3ccccc3)ccc2-c2ccc(S(=O)(=O)c3ccccc3)cc21] |
| E_{1/2/0/-1} | −2.35 | −2.28 | −2.24 |

The bis(sulfonyl)biaryl compounds of Formulas (Ia)-(Id) whose synthesis is described herein are typically reasonably soluble in a large variety of common organic solvents, such as chlorobenzene and toluene, as well as polar solvents such as acetonitrile, DMF, DMSO or methanol. Therefore the compounds can often be solution processed, especially from the more polar solvents or solvent mixtures, to form films without dissolving or unacceptably damaging the underlying organic layers of precursors of multilayer devices, such as organic hole transporting and emissive layers in OLEDs. Therefore, in some aspects, the inventions described herein can relate to a process for making an electronic device comprising the compounds, wherein the one or more compounds are applied during the manufacture of the device by a solution deposition process, preferably to form a film of the compounds on a surface of a precursor of the device.

Synthetic Methods For the Compounds of Formulas (Ia)-(Id)

Methods for the synthesis of compounds of Formulas (Ia)-(Id) are disclosed below.

### Generic Synthesis of 4,4′-Bis(organo-sulfonyl)-biphenyls

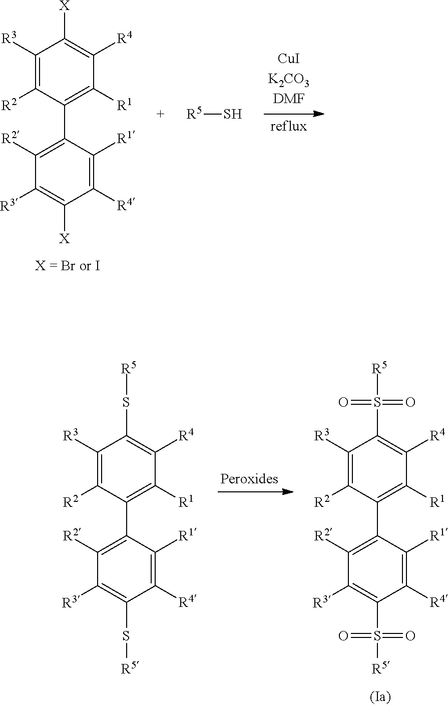

Similar strategies can be employed by those of ordinary skill for making the sulfone compounds of the inventions, involving first a copper catalyzed nucleophilic coupling of the desired aryl bromides or iodides with thiol precursors of the R⁵ groups, to produce the aryl thioethers, followed by oxidation with peroxides to form the sulfones. See the attached examples for specific procedures.

A suitable precursor for the fluorene compounds of Formula (Ib) are commercially available from Alfa Aesar of Ward Hill, Mass., and can be elaborated as shown below:

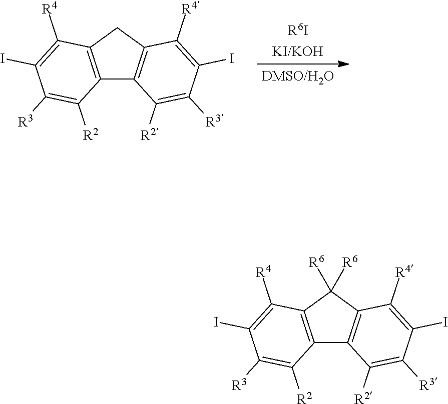

Other precursors of compounds of Formula (Ib) are commercially available or know in the prior art, as described below, and incorporated herein by reference for the disclosed synthetic methodologies;

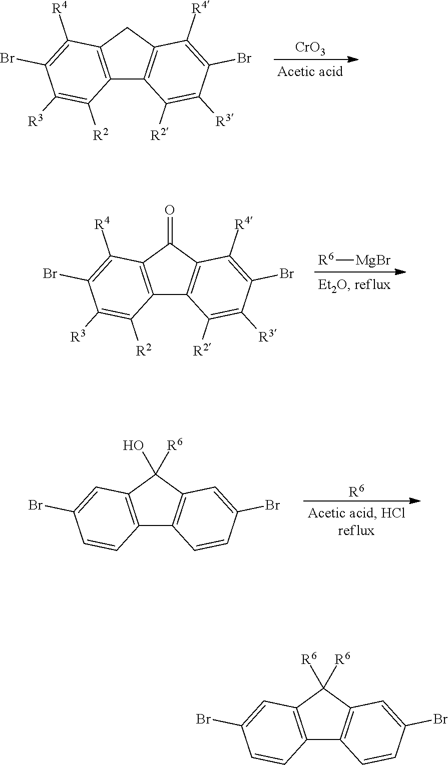

Chen et al. J. Polym. Sci.: Part A: Polym. Chem. 2009, 47, 2821-2834. R6=Ar

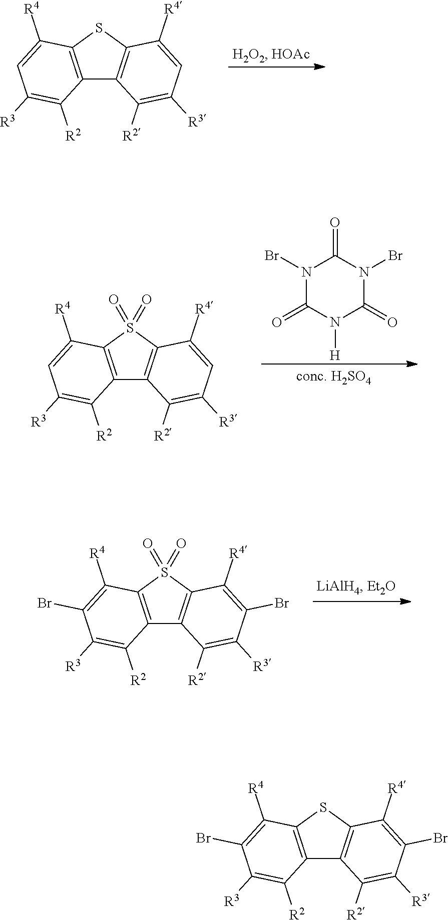

See Sirringhaus et al, J. Mater. Chem. 1999, 9, 2095-2101.

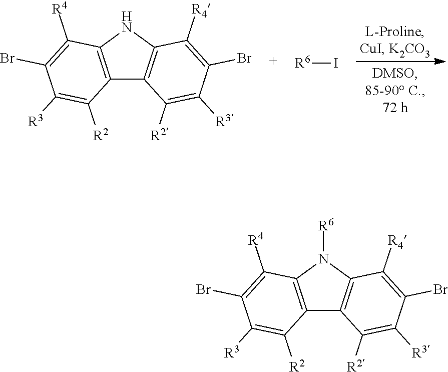

See Wakim et al, Macromol. Rapid Commun. 2007, 28, 1798-1803. R═Ar

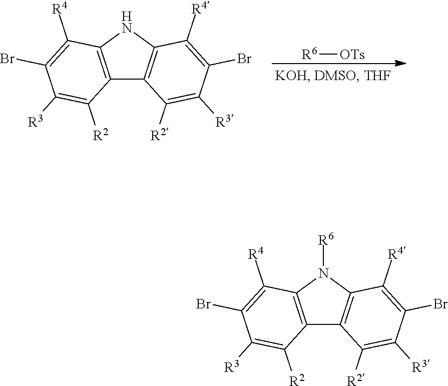

Zhou et al. Chem. Mater. 2009, 21, 4055-4061. R=Alk

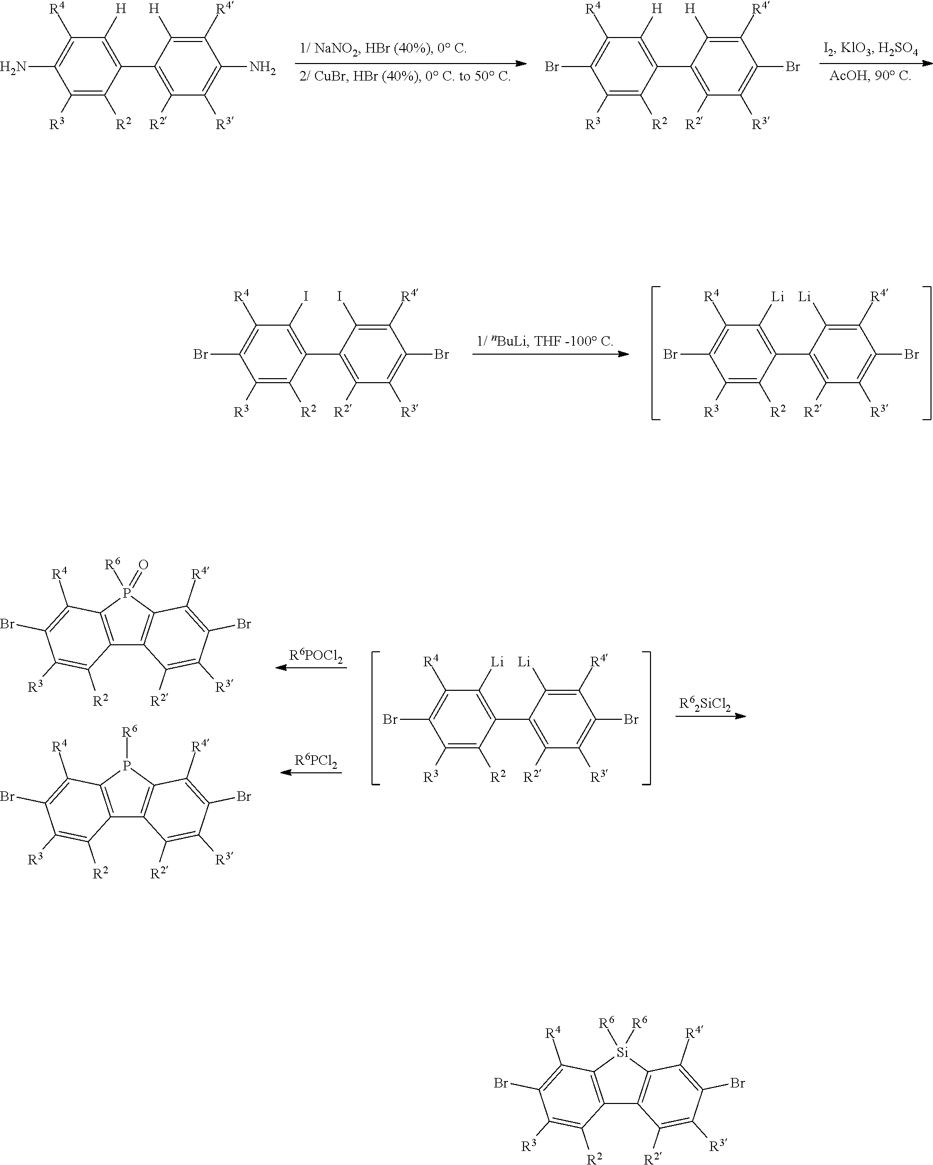

See Chen et al. Org. Lett., 2006, 8, 2, 203-205; Zhang et al. Org. Lett. 2010, 12, 15, 3438-3441; Chen et al. Org. Lett. 2008, 10, 13, 2913-2916. R═Ar or Alk

Methods for the synthesis of precursors of spiro compounds of Formulas (Ic) and (Id) are disclosed in the Examples below.

### Electronic Devices Comprising Bis(organo-sulfonyl)-Biaryl Compounds

The various devices of the invention, including the OLED devices of the invention, typically comprise one or more of compounds of Formulas (Ia)-(Id) as described above, wherein the various “R” substitutents can be defined in any of the ways described above in connection with the compounds themselves. Moreover, in certain preferred embodiments, the inventions described and/or claimed herein relate to electronic device comprising any one of more compounds having the formulas:

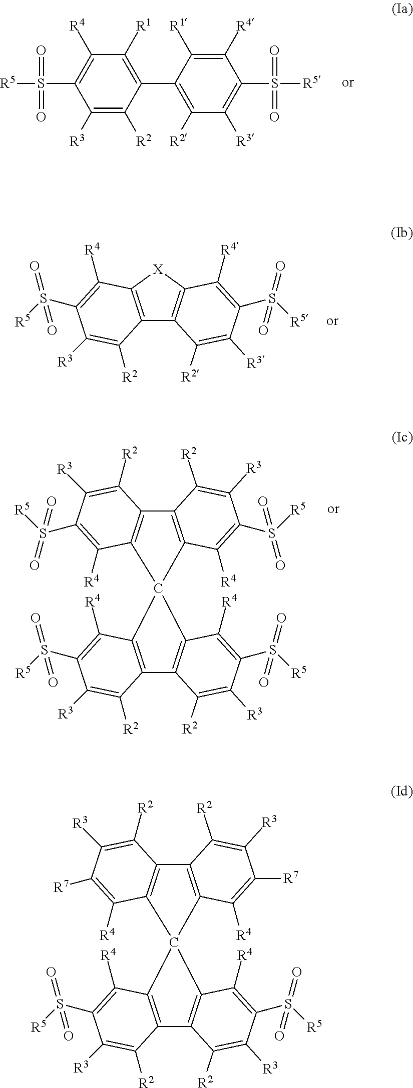

wherein
a. each of R¹-R⁴, R^{1′}-R^{4′} and R⁷ are independently selected from hydrogen, halogen, cyano, or an independently selected and optionally substituted C₁-C₃₀ organic group selected from alkyl, perfluoroalkyl, alkoxy, perfluoroalkoxy, aryl, and heteroaryl groups;
b. each of R⁵ and R^{5′} are independently selected from optionally substituted C₁-C₃₀ organic groups selected from alkyl, perfluoroalkyl, alkoxy, perfluoroalkoxy, aryl, or heteroaryl groups;
c. X is S, S(O), SO₂, or a C₁-C₃₀ organic group selected from C(R⁶)₂, C(R⁶)Ar, C(Ar)₂, Si(R⁶)₂, Si(R⁶)Ar, Si(Ar)₂, NR⁶, NAr, PR⁶, PAr, P(O)R⁶, or P(O)Ar group, wherein
   i. R⁶ is a C₁-C₂₀ alkyl or perfluoroalkyl group, and
   ii. Ar is a C₁-C₃₀ aryl or heteroaryl group that does not comprise a diphenyl amine group.

In some preferred embodiments of the devices above having Formula (Ib), X is C(R⁶)₂, C(R⁶)Ar, or C(Ar)₂. In such embodiments, preferably neither Ar or R⁶ comprise a primary, secondary, or tertiary amine group as a substituent group.

In many preferred embodiments, the devices of the invention are light-emitting diodes (OLEDs). In many embodiments, such OLEDs comprise at least five sequential layers, i.e. a transparent anode layer for injecting holes into the device (such as indium tin oxide coated on a glass or plastic substrate). Over the anode layer is an organic hole transporting layer (HTL) is typically applied for transmitting the holes from the anode to an emissive layer (EL) that typically comprises an semiconducting organic host material (such as the bis(sulfonyl)biaryl compounds of the invention doped about 1-30% of a guest emitter (typically a phosphorescent Ir(III) or Pt(II) complex). Then an electron transporting/hole blocking layer comprising an organic semiconducting electron transport material (which can be one of the bis(sulfonyl)biaryl compounds of the invention is applied over the emissive layer, then finally a cathode layer for injecting electrons into the device (often aluminum on top of a thin layer of LiF) is applied to the electron transporting/hole blocking layer. Many suitable materials for use in the anode, HTL, or cathode layers are well known in the art, and may be used in the OLED devices described herein. Somebody skilled in the art will understand that OLEDs can also be constructed by starting with a substrate that is comprised of a transparent cathode layer for injecting electrons into the device. Over the cathode layer is then an organic electron transport layer (ETL). Over the ETL layer is an emissive layer (EL). Over the EL is a HTL. Finally, over the HTL is an anode.

The compounds of the invention, including one or compounds having Formulas (Ia)-(Id) as described above, or mixtures thereof, can often be employed in one or both of the emissive layer and/or the electron transporting/hole blocking layers of the OLEDs of the invention, or in combinations or mixtures with other known host or electron transporting materials.

In many preferred embodiments, the light-emitting diodes of the invention comprise an electron transporting layer that comprises the one or more of the compounds of Formulas (Ia)-(Id), or any of the sub-genera of those compounds.

In many preferred embodiments, the light-emitting diodes of the invention comprise an emissive layer that comprises at least one or more compounds of Formulas (Ia)-(Id) as a host material, doped with a phosphorescent emitter. In many preferred embodiments of the light-emitting diodes of the invention, the phosphorescent emitter emits blue or green light, but preferably does not emit red light.

Well-known blue emitters commonly used as guest emitters in OLED devices include Flrpic (Y. Kawamura et al. Appl. Phys. Lett. 2005, 86, 071104/1), Flr₆ (T. Sajoto et al. Inorg. Chem. 2005, 44, 7992-8003) and Ir(ppz)₃ (C. H. Yang et al. Angew. Chem. Int. Ed. 2007, 46, 2418-2421). Commonly used green emitters include Ir(ppy)₃ (Y. Kawamura et al. Appl. Phys. Len. 2005, 86, 071104/1), and Ir(mppy)₃ (H. Wu et al. Adv. Mater. 2008, 20, 4, 696-702).

The electronic devices comprising one or more compounds of Formulas (Ia)-(Id), including OLEDs, transistors, photovoltaic devices, and the like can be made in organic electronic device geometries that are well known to those of ordinary skill in the art of organic electronics, as illustrated in part by the various pieces of prior art referenced herein and incorporated by reference herein, as well as the attached examples. Techniques for depositing thin films in OLEDs include direct vacuum deposition or co-deposition of the compounds, or solution processes in which film forming compounds of the invention are dissolved in common organic solvents and optionally mixed with film forming polymers or oligomers, then applied to device precursors by a solution deposition process, such as “spin coating,” as exemplified below, or by liquid ink-jet printing.

### EXAMPLES

The various inventions described above are further illustrated by the following specific examples, which are not intended to be construed in any way as imposing limitations upon the scope of the invention disclosures or claims attached herewith. On the contrary, it is to be clearly understood that resort may be had to various other embodiments, modifications, and equivalents thereof which, after reading the description herein, may suggest themselves to one of ordinary skill in the art without departing from the present invention or the scope of the appended claims.

Starting materials were obtained from commercial sources and used without further purification. Electrochemical measurements were carried out under nitrogen on dry deoxygenated THF or DCM solutions ca. 10⁻⁴ M in analyte and 0.1 M in tetra-n-butylammonium hexafluorophosphate using a BAS Potentiostat, a glassy carbon working electrode, a platinum auxiliary electrode, and, as a pseudo-reference electrode, a silver wire anodized in 1 M aqueous potassium chloride. Potentials were referenced to ferrocenium/ferrocene. Cyclic voltammograms were recorded at a scan rate of 250 mVs⁻¹. UV-vis.-NIR spectra were recorded in 1 cm cells using a Varian Cary 5E spectrometer. NMR spectrometers Bruker 400. Elemental analyses were performed by Atlantic Microlabs.

The fluorescence and phosphorescence spectral measurements believed to be necessary to experimentally measure the singlet and triplet energies of examples of compounds Formulas (Ia)-(Id) were performed on highly diluted (≈10⁻⁵ mol/l) solutions, in order to minimize self-absorption of the emitted light, in spectroscopic grade dichloromethane or 2-methyl-THF, the latter one, which leads at 77 K to clear glasses, being preferred for the low temperature measurements.

Fluorescence spectra were recorded in fluid solutions (typically dichloromethane, THF, or 2-methyl THF) at room temperature in 1 cm cells on a Horiba Jobin Yvon Fluorolog 3 fluorimeter. The wavelength of the emission peak from such spectra were used to calculate an experimental measurement of the lowest singlet state energies of several compounds described below. An experimental estimate of the singlet and triplet energies of compounds Formulas (Ia)-(Id) referenced in the specification and claims herein can be measured via these fluorescent spectroscopic procedures.

In many cases, the phosphoresce of compounds Formulas (Ia)-(Id) cannot be detected at room temperature, but can be measured at low temperatures.

Accordingly, phosphorescence spectra (using a pulsed xenon lamp) were measured in 2-methyl THF glasses at low temperature using a J Y Horiba FluoroMax-4P spectrofluorimeter. Specifically, low temperature (77 K) emission spectra (gated and nongated) were recorded in 5 mm diameter quartz tubes placed in a liquid nitrogen Dewar equipped with quartz wall (J Y Horiba FL-1013 Liquid Nitrogen Dewar Assembly). Nongated and gated spectra were recorded to enable discrimination of phosphorescence from fluorescence. Generally, the gate delay (=initial delay), which corresponds to the time between the start of the lamp flash and the onset of data-acquisition, was fixed to 2 ms and the gate width (=sample window), which sets the duration of signal acquisition, to 50 ms.

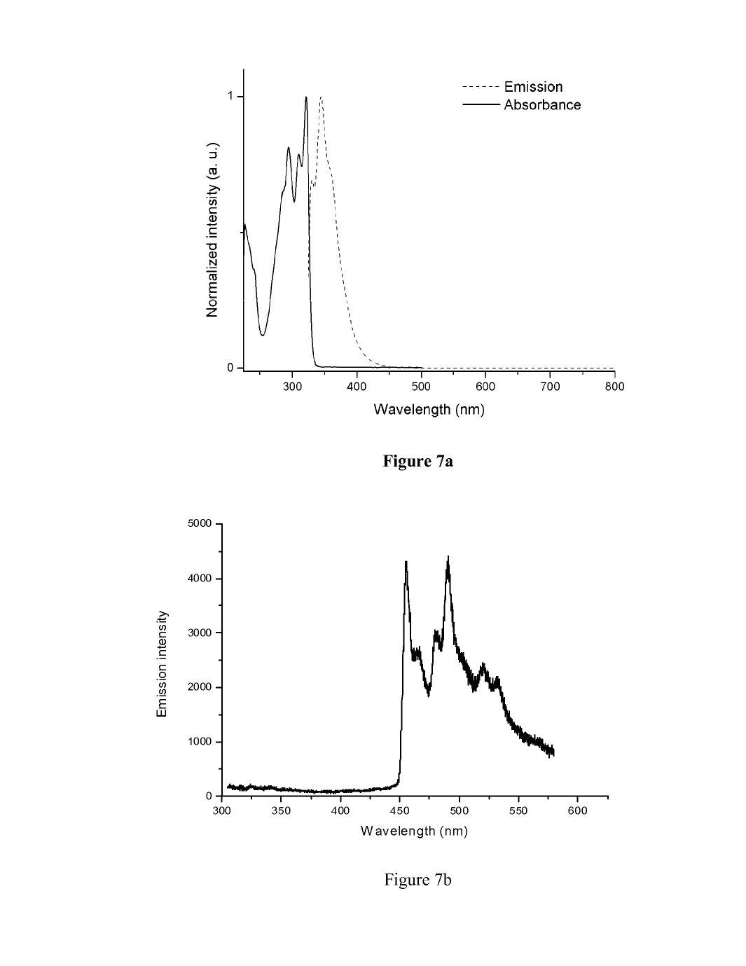

Vibronic splitting of the phosphorescence spectrum into multiple peaks can often be observed in such low temperature solid samples. For purposes of consistent and accurate measurement, the triplet energies of the bis(sulfonyl)biaryl compounds of Formulas (Ia)-(Id) mentioned in the specification and claims herein can be measured from the wavelength of most energetic observed peak of the phosphorescence spectra in dilute 2-methyl-THF glasses at 77 K. See for example FIG. 7b. While not wishing to be bound by theory, such a measurement is believed to be an experimental measurement of the energy of the T₁^{v=0}→S₀^{v=0} transitions, i.e. the “lowest energy triplet excited state” of the bis(sulfonyl)biaryl compounds as repeatedly referenced herein in the specification and claims. The lower energy peaks of the vibronically structured spectra can be attributed to transitions from T₁^{v=0}→S₀^{v>0}.

In the following examples, the following known materials were used to make portions of the organic light-emitting diodes:

Glass substrates precoated with indium tin oxide (ITO) with a sheet resistance of 20 Ω/sq Colorado Concept Coatings, L.L.C.). The substrates were first cleaned in an ultrasonic bath using a dilute solution of Triton-X (Aldrich) in de-ionized (DI) water (20 min) followed by successive ultrasonication in DI water, acetone, and finally ethanol (20 min each). Cleaned ITO substrates were then dried in a vacuum oven at 70° C. under vacuum (1×10⁻² Torr) for 1 h.

At least three polycarbazole materials were employed as hole transport materials. PVK (polyvinylcarbazole) was obtained commercially from Sigma Aldrich of St. Louis Mo., and CZ-I-25 was prepared as described in WO 2009/080799 A1. Films of PVK CZ-I-25 with a thickness of 35 nm were spin-coated from toluene onto the air-plasma treated ITO coated substrates in a nitrogen inert atmosphere. The coated substrates were then loaded into a Kurt J. Lesker SPECTROS vacuum system without being exposed to atmosphere. Additionally, a third polytriscarbazole polymer (a) was used as described in below.

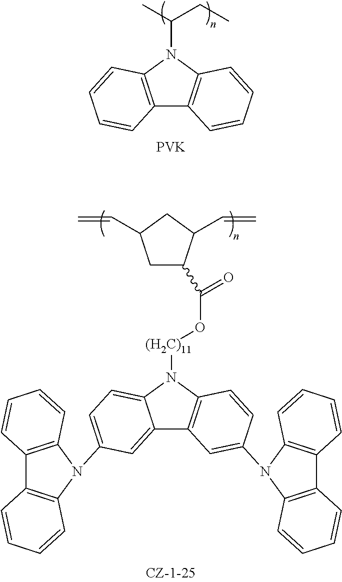

In some experiments, the known cross-linkable bis(diarylamino)biphenyl/methacrylate-cinnamate/methacrylate copolymer poly-TPD-F, whose structure is shown below and whose synthesis has been described elsewhere (Hreha et al. Proc. SPIE Int. Soc. Opt. Eng. 2002, 4642, 88-96; Haldi et al. Appl. Phys. Lett. 2008, 92, 25, 253502/1-253502/3) was used as a hole-transport material.

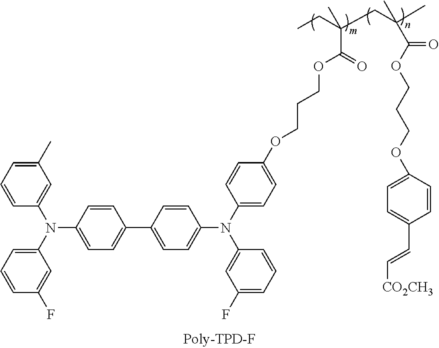

Flrpic (Bis(4,6-difluorophenylpyridinato-N,C2)picolinato iridium), obtained from Lumtec of Hsin-Chu Taiwan, was used as a bluephosphorescent guest emitter in the OLED emissive layers, and Ir(ppy)₃ (tris(2-phenyl-pyridininato-N,C^{2′}) iridium, obtained from H.W. Sands Corp., Jupiter Fla.) was used as a green emitter. BCP (2,9-dimethyl-4,7-diphenyl-1,10-phenanthroline), obtained from Sigma Aldrich, was used as an electron transmission/hole blocking layer. Both materials were purified via gradient zone sublimation prior to use, and applied by vacuum deposition as further described below.

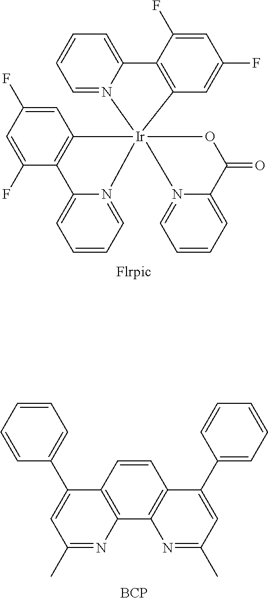

In some experiments detailed below, the norbonenyl-bis-oxadiazolyl polymer YZ-I-293, i.e. Poly(2-(3-(bicyclo[2,2,1]hept-5-en-2-ylmethoxy)phenyl)-5-(3-(5-(4-tert-butylphenyl)-1,3,4-oxadiazol-2-yl)phenyl)-1,3,4-oxadiazole), whose synthesis and properties as solution processable, electron carrying/hole blocking material were reported in WO 2009/080797 A1, was used a host material for forming emissive layers.

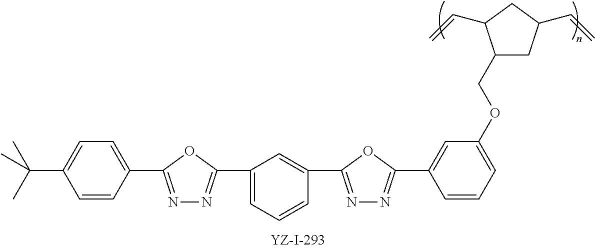

### Example 1

### Synthesis of 4,4′-Bis(phenylsulfonyl)-1,1′-biphenyl, Compound (1)

4,4′-Bis(phenylsulfonyl)-1,1′-biphenyl is a compound first reported by Holt and Jeffreys, J. Chem. Soc. 1965, 773, 4204-4205, Applicants have developed a higher yielding synthesis for making quantities suitable for use in the device work described below.

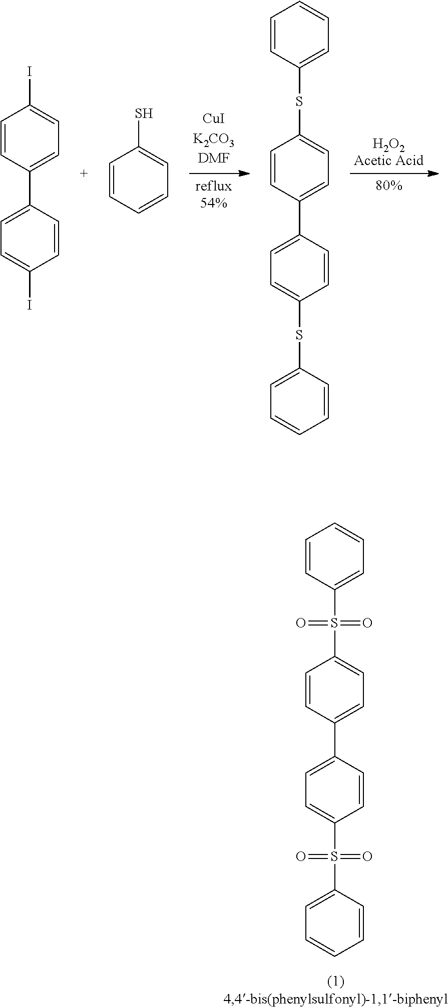 [SMILES: Ic1ccc(-c2ccc(I)cc2)cc1 ; Sc1ccccc1 ; c1ccc(Sc2ccc(-c3ccc(Sc4ccccc4)cc3)cc2)cc1 ; O=S(=O)(c1ccccc1)c1ccc(-c2ccc(S(=O)(=O)c3ccccc3)cc2)cc1]

### 4,4′-Bis(phenylthio)biphenyl

A solution of 3.99 mL of thiobenzene (39 mmol), 6.09 g of 4,4′-diiodobiphenyl (15 mmol), 4.56 g of K₂CO₃ (33 mmol) and 71 mg of CuI (0.4 mmol) in DMF (10 mL) were placed in a preheated oil bath at 100° C. The solution was stirred 2411 at 100° C. Then the solution was cooled to room temperature and 10 mL of water was added. Extractions were done with CH₂Cl₂ (3×20 mL). The organic layer was dried on MgSO₄, filtered and the solvents were removed under vacuum. The yellow solid is purified by chromatography with hexane/CH₂Cl₂ (8:2) as eluant to obtain a white solid (3.0 g, 54%). ¹H NMR (300 MHz, CDCl₃): δ (ppm) 7.50 (d, J=9 Hz, 4H,), 4.42-7.24 (m, 14H). ¹³C NMR (75 MHz, CDCl₃): δ (ppm) 138.9, 135.4, 135.3, 131.3, 131.1, 129.3, 127.6, 127.2. GC-MS m/z (% relative intensity, ion): 370 (100, M⁺).

### 4,4′-Bis(phenylsulfonyl)biphenyl (1)

A solution of 2 g of 4,4′-bis(phenylthio)biphenyl (5.4 mmol) and 40 mL of H₂O₂ in acetic acid (100 mL) and chloroform (20 mL) was stirred 24 h at room temperature. The solution was filtered and the white solid was washed with water. The solid was recrystallized from THF (1.87 g, 80%). ¹H NMR (300 MHz, DMSO): δ (ppm) 8.06 (d, J=9 Hz, 4H), 8.02-7.99 (m, 4H), 7.93 (d, J=9 Hz, 4H), 7.71-7.61 (m, 6H); EIMS (70 eV) m/z″ M+434; UV (CH₂Cl₂) λₘₐₓ, nm 277.

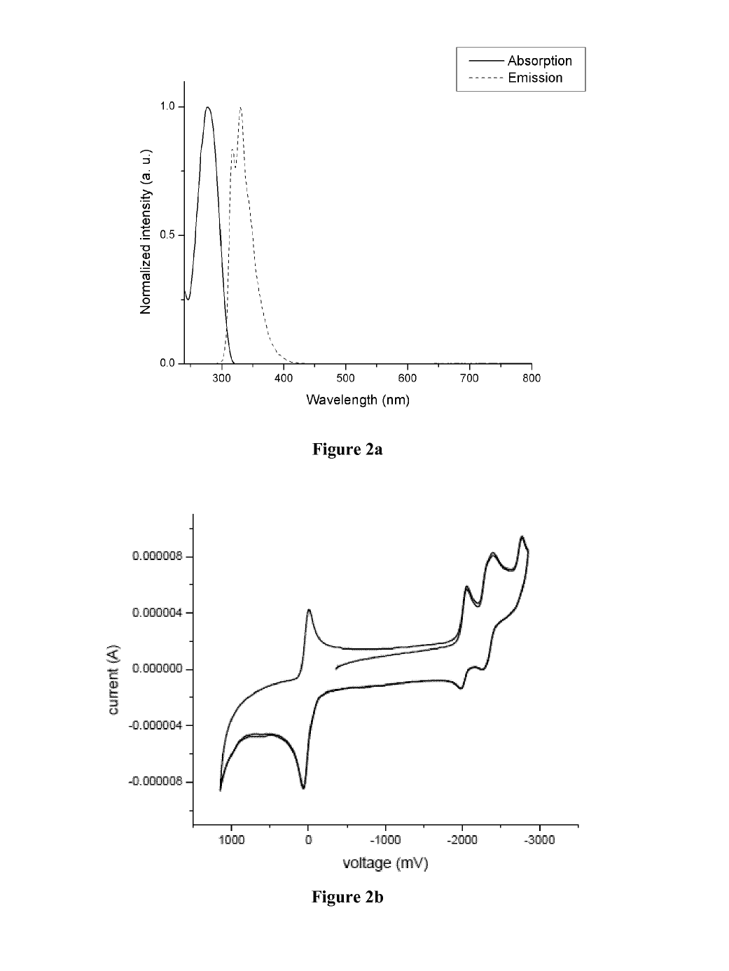

The optical absorption and fluorescent emission spectra, and cyclic voltammogram of (1) in methylene chloride/in 0.1 Bu₄NPF₆, using ferrocene as an internal reference, are shown in FIGS. 2a and 2b. The absorption and emission maxima in the optical spectra are at 277 nm and 331 nm respectively, and the first reduction occurs at −2.06 V vs ferrocene.

### Example 2

### OLED Devices Employing 4,4′-Bis(phenylsulfonyl)-1,1′-biphenyl, (1) as a Host in the Emissive Layer

OLED devices employing 4,4′-Bis(phenylsulfonyl)-1,1′-biphenyl, (1) as a host in the emissive layer, with the architectures ITO/PVK or CZ-I-25/(1)-Flrpic/BCP/LiF/Al were prepared as follows. Glass/ITO/spin coated PVK or CZ-I-25 substrates were loaded into a Kurt J. Lesker SPECTROS vacuum system without air exposure and then samples of sulfone compound (1) and 6 or 10 wt % Flrpic were thermally co-evaporated onto the substrates, at a pressure below 1×10⁻⁷ Torr, to form an emissive layer of thickness 20 nm on the polycarbazole coated ITO substrates. BCP (40 nm), LiF (2.5 nm) and Al (200 nm), as electron transmitting/hole blocking, cathode, and electrode layers were then applied by thermal vacuum deposition.

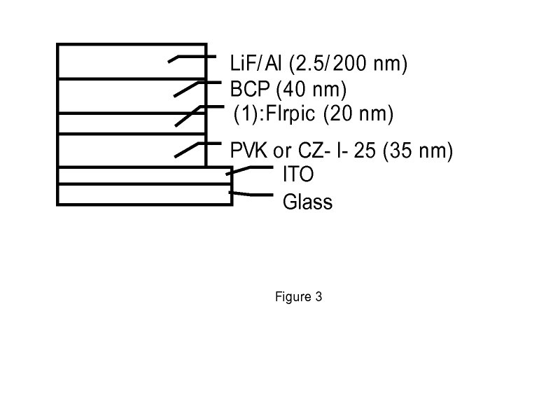

The resulting device structures are shown in FIG. 3. Luminance-current-voltage (L-I-V) characteristics of the devices were measured using a Keithley 2400 source meter for current-voltage measurements inside a nitrogen-tilled glovebox with O₂ and H₂O levels <20 and <1 ppm, respectively.

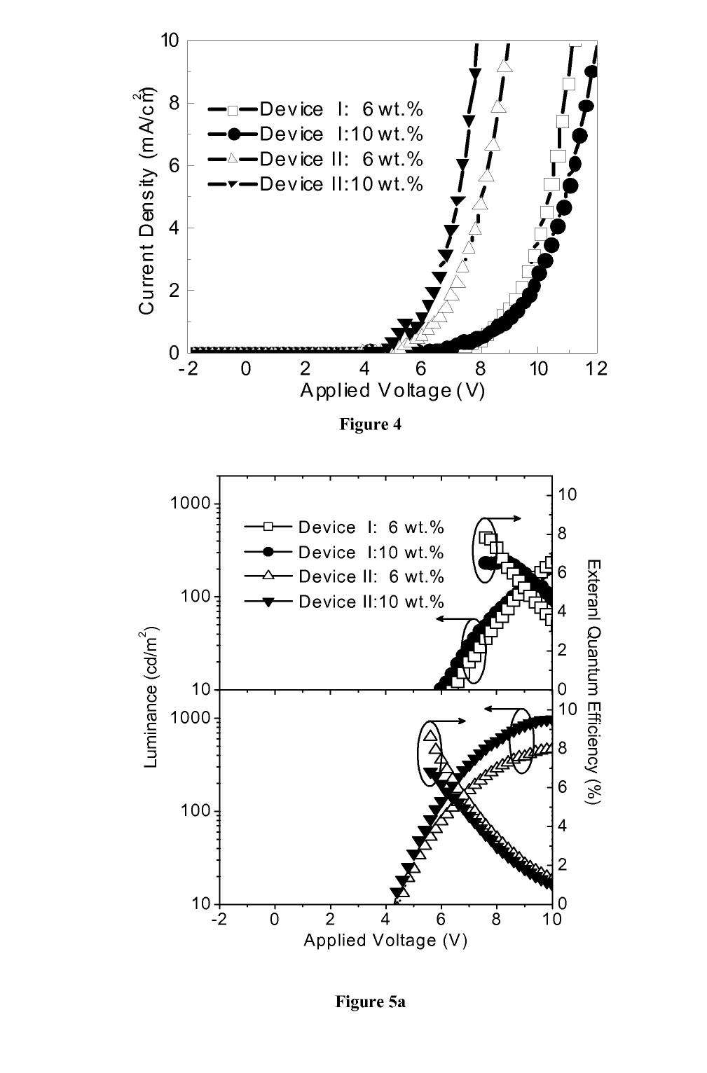

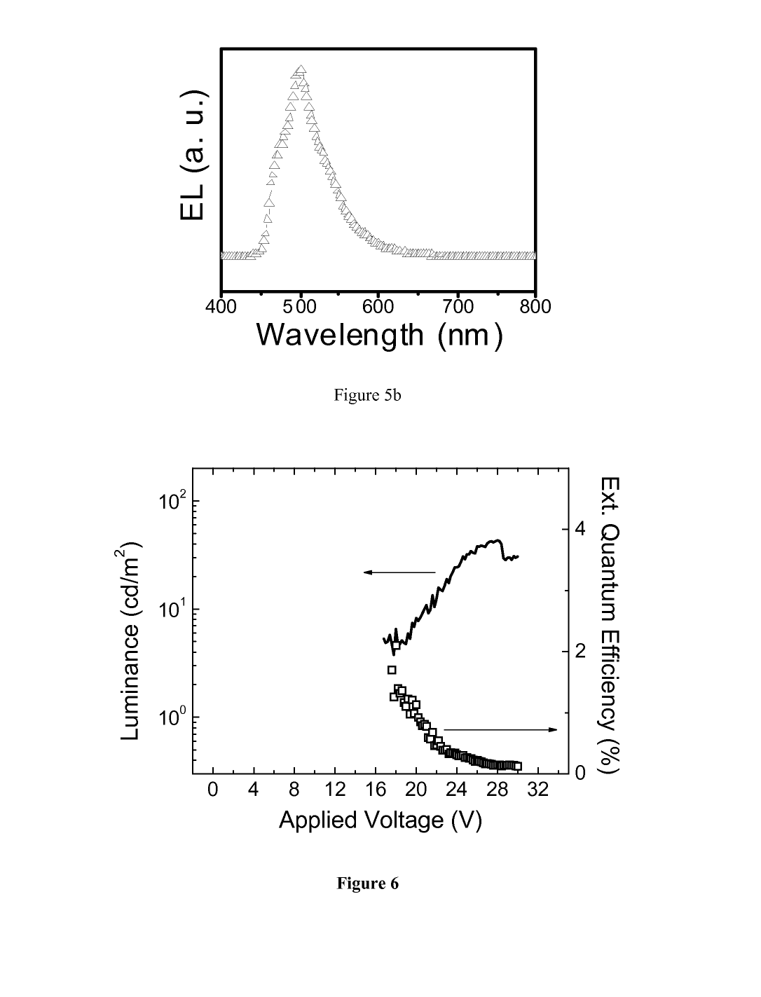

The current voltage (J-V) characteristics of the two device architectures, with PVK (device I) or CZ-I-25 (device II) as a HTL, are shown in FIG. 4. The luminance voltage (L-V) and external quantum efficiency (EQE) curves of the OLED devices are compared in FIG. 5a. At a luminance of 100 cd/m², device II shows maximum external quantum efficiencies (EQE) of 6.9% and a current efficiency of 12.9 cd/A, while device I shows efficiencies of 6.4% and 11.3 cd/A, respectively. These figures also show that the turn-on voltage and the luminance for blue-green OLEDs employing (1) as a host for Flrpic that incorporate CZ-I-25 as a hole-carrying layer are better than those based on PVK. Furthermore, the turn-on voltages (defined as the voltage required to obtain a brightness of 10 cd/m²) of device II (4.4 and 4.3 V for devices with 6 and 10 wt. % Flrpic, respectively) are clearly lower than those of device I (6.4 and 6.0 V for 6 and 10 wt. %). An example of the electroluminescence spectrum of device II with 6 wt. % of Flrpic is shown in FIG. 5b.

The EQE, current efficiencies, and electroluminescence (EL) spectra demonstrate that compound (1) is a good host material for Flrpic in electrophosphorescent blue OLEDs. Carrier injection and transport efficiency may be crucial issues affecting the charge balance and quantum efficiency of OLEDs. The differences between devices of types I and II may be attributable either to different hole mobility values and/or injection efficiencies in the two polymers.

### Example 3

### OLED Devices Employing 4,4′-Bis(phenylsulfonyl)-1,1-biphenyl (1) as an Electron Transmitting/Hole Blocking Material

OLED devices employing 4,4′-Bis(phenylsulfonyl)-1,1′-biphenyl, (1) as an electron transmitting/hole blocking material were prepared as follows. Glass/ITO substrates, prepared as described above, were spin-coated (60 s@1500 rpm, acceleration 10,000) with a solution prepared by dissolving 10 mg of Poly-TPD-F in 1 ml of distilled and degassed toluene, then photo-crosslinked using a standard broad-band UV light with a 0.7 mW/cm² power density for 1 minute, to form a 35 nm-thick hole transport layer on the ITO. Subsequently, an emissive layer 40 nm thick was prepared by dissolving 5 mg of YZ-I-293, 4.4 mg of PVK and 0.6 mg of the well-known green emitter, fac tris(2-phenylpyridinato-N,C2′) iridium [Ir(ppy)₃] in 1 ml of distilled and degassed chlorobenzene, and spin coating the solution onto the Glass/ITO/Poly-TPD-F device precursor. To form an electron transporting/hole-blocking layer, sulfone compound (1) was vacuum deposited at a pressure below 1×10⁻⁶ Torr at a rate of 0.4 Å/s. Finally, 2.5 nm of lithium fluoride (LiF) as an electron-injection layer and a 200 nm-thick aluminum cathode were vacuum deposited at a pressure below 1×10⁻⁶ Torr and at rates of 0.1 Å/s and 2 Å/s, respectively. A shadow mask was used for the evaporation of the metal to form five devices with an area of 0.1 cm² per substrate. Electronic testing was done immediately after the deposition of the metal cathode in inert atmosphere, without exposing the devices to air.

The results of the testing are shown in FIG. 6. As can be seen from this non-optimized example, sulfone compound (1) can be successfully used as an electron-transmitting/hole blocking material in OLEDs, and the devices of this example yielded efficiencies of 2.61% and 8.94 cd/A at 5.3 cd/m².

### Example 4

### Synthesis of 9,9-dihexyl-2,7-bis(phenylsulfonyl)-9-fluorene, Compound (2)

Compound (2) was synthesized via the multi-step procedure shown below:

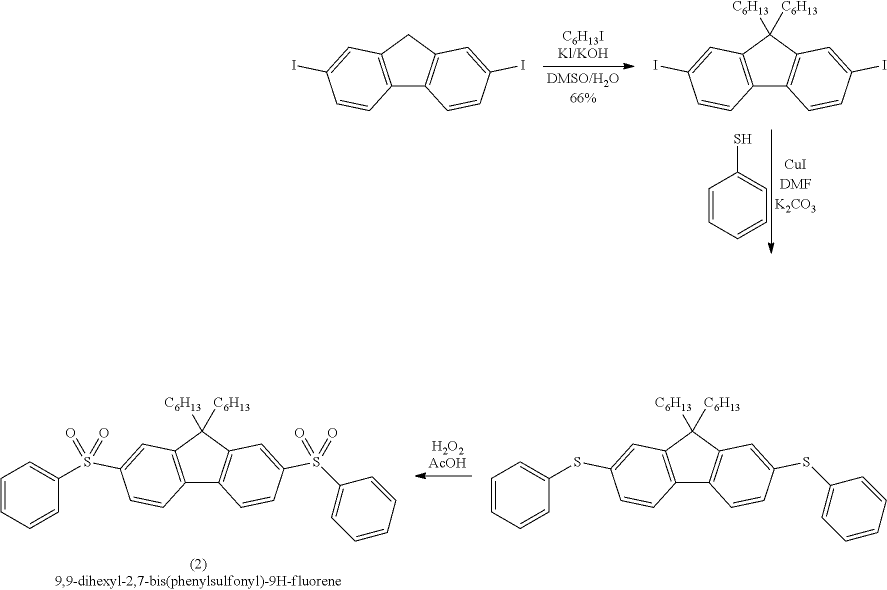

### 9,9-Dihexyl-2,7-diiodo-9H-fluorene

A solution of 6.45 g 2,7-diiodo-fluorene (15.4 mmol), 5.72 mL of iodo-hexane (38.6 mmol) and 307.4 mg of KI (1.8 mmol) in 100 mL of DMSO was stirred at room temperature under nitrogen. A solution of 3.9 g of KOH (69.5 mmol) in 5 mL of water was added slowly. The resulting solution was stirred overnight at room temperature. Water (200 mL) was added and the solution was filtered to obtain a brown solid. The solid was dissolved in dichloromethane and this organic layer was washed with brine, dried on MgSO₄, filtered and the solvents removed to obtain a orange solid (5.97 g, 66%). ¹H NMR (300 MHz, CDCl₃): δ (ppm) 7.66-7.63 (m, 4H), 7.40 (d, 8.0 Hz, 2H), 1.89 (t, J=8.3 Hz, 4H), 1.15-1.04 (m, 12H), 0.78 (t, J=7.6 Hz, 6H);

¹³C {¹H NMR (75 MHz, CDCl₃): δ (ppm) 139.7, 135.9, 131.9, 122.2, 121.4, 91.1, 55.5, 40.1, 31.4, 29.5, 23.6, 22.6, 14.0; GC-MS m/z (% relative intensity, ion): 586 (100, M+).

### (9,9-Dihexyl-9H-fluorene-2,7-diyl)bis(phenylsulfane)

A solution of 0.91 mL of benzenethiol (9 mmol), 2.00 g of 9,9-dihexyl-2,7-diiodo-9H-fluorene (3.4 mmol), 1.03 of K₂CO₃ (7.5 mmol) and 16 mg of CuI (0.09 mmol) in DMF (3 mL) are placed in a preheated oil bath at 100° C. The solution is stirred 24 h at 100° C. Then the solution is cooled to room temperature and 10 mL of water are added. Extractions are done with CH₂Cl₂ (3×20 mL). The organic layer is dried on MgSO₄, filtered and the solvents were removed under vacuum. The yellow solid is purified by chromatography with hexane/CH₂Cl₂(2:1) as eluant to obtain yellow oil. ¹H NMR (300 MHz, CDCl₃): δ (ppm) 7.62 (d, J=9.3 Hz, 2H), 7.37-7.34 (m, 4H), 7.32-7.26 (m, 10H), 1.87 (t, J=6.0 Hz, 4H), 1.15-0.99 (m, 16H), 0.78 (t, J=7.6 Hz, 6H); GC-MS m/z (% relative intensity, ion): 550 (100, M+).

### 9,9-Dihexyl-2,7-bis(phenylsulfonyl)-9H-fluorene (2)

A solution of 500 mg of (9,9-dihexyl-9H-fluorene-2,7-diyl)bis(phenylsulfane) (0.9 mmol) was mixed with 10 mL of H₂O₂ acetic acid (10 mL) was stirred 24 h at room temperature. The solution was filtered and the white solid was washed with water. The solid was purified by chromatography with hexane/dichloromethane/ethyl acetate (4:4:2) to obtain a white solid (56 mg, 10%). ¹H NMR (300 MHz, DMSO): δ (ppm) 7.98-7.89 (m, 8H), 7.80 (d, J=9.0 Hz, 2H), 7.56-7.47 (m, 6H), 1.99 (t, J=6.0 Hz, 4H), 1.07-0.92 (m, 16H), 0.73 (t, J=7.6 Hz, 6H,).

The optical absorbance and fluorescent emission spectra of 9,9-dihexyl-2,7-bis(phenylsulfonyl)-9H-fluorene in liquid dichloromethane are shown in FIG. 7a. The maximum absorption wavelength and the maximum emission wavelength are observed at 321 nm and 345 nm, respectively. An additional shoulder is present at 358 nm in the fluorescent emission spectra. FIG. 7b shows the phosphorescent emission spectrum of the same compound at 77 K in a 2-methyl-THF glass. The most energetic vibronic peak was observed at λₘₐₓ=455 nm, corresponding to a triplet energy of 2.72 eV.

### Example 5

### Synthesis of 2,7-bis(phenylsulfonyl)-9,9′-spirobi[fluorene](3)

2,7-bis(phenylsulfonyl)-9,9′-spirobi[fluorene] was synthesized via the multi-step procedure below;

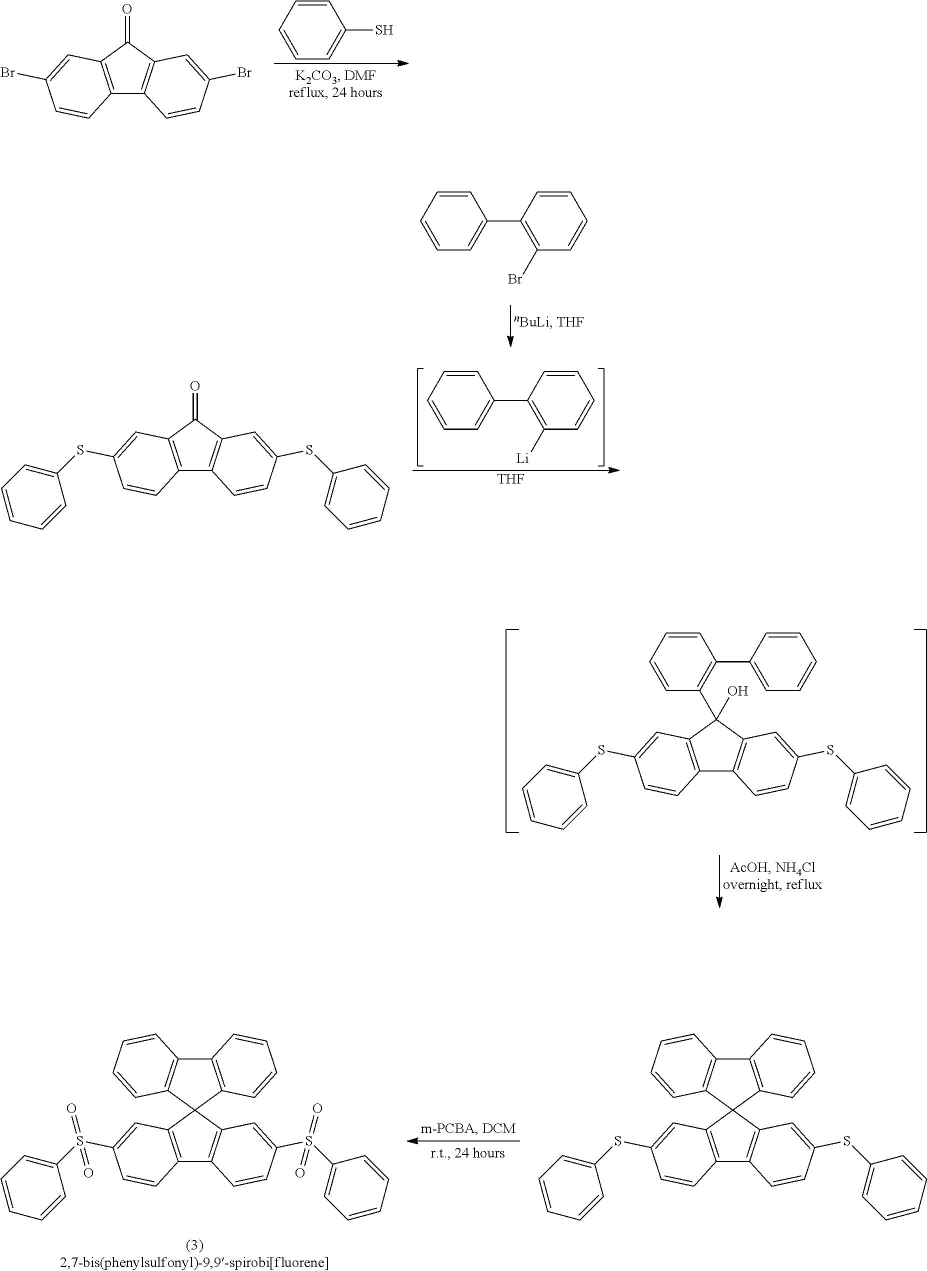

### 2,7-Bis(phenylthio)-9H-fluoren-9-one

To a stirred solution of 4,9-dibromofluorenone (5 g, 14.79 mmol, 1 eq), K₂CO₃ (8.17 g, 59.16 mmol, 4 eq) in DMF (192 mL) was added thiophenol (3.8 mL, 36.98 mmol, 2.5 eq) under nitrogen. The reaction mixture was then placed in a pre-heated bath at 130° C. for 24 hours. Water (200 mL) was added to the mixture and the organic layer was extracted 3 times with ethyl acetate. The organic phases was washed with brine (3×200 mL), dried over MgSO₄ and the solvents were removed under vacuum to obtain an orange solid. The solid was recrystallized from hexane/ethyl acetate to obtain orange needles (56%). ¹H NMR (400 MHz, CDCl₃): δ (ppm) 7.52 (m, 2H,), 7.42-7.28 (m, 14H); ¹³C{¹H} NMR (75 MHz, CDCl₃): δ (ppm): 192.5, 142.2, 138.5, 135.9, 134.9, 134.0, 132.1, 129.5, 128.0, 125.9, 120.8.

### 2,7-Bis(phenylthio)-9,9′-spirobi[fluorene]

2-bromobiphenyl (2.48 g, 10.62 mmol, 1 eq) was dissolved in THF (53 mL). The solution was degassed at −90° C. ⁿBuLi (4.25 mL, 10.62 mmol, 1 eq, 2.5 M) was added dropwise at this temperature to give a yellow solution. After stirring for 1 hour at −90° C., a solution of [00041] 2,7-bis(phenylthio)-9H-fluoren-9-one (4.21 g, 10.62 mmol, 1 eq) in THF (26 mL) was added dropwise. The reaction mixture turned orange. After stirring for 30 minutes at −90° C., the reaction mixture was warmed up at r.t. overnight. Water was added to the dark brown solution and the crude product was extracted 3 times with AcOEt. The organic layers were combined, dried on Na₂SO₄ and the solvents were evaporated. The resulting product was placed in suspension in AcOH (74 mL) and HCl (6.32 mL, 4 M) and the reaction mixture was stirred overnight at reflux. Water was then added and the crude product was extracted 3 times with CHCl₃. The organic layers were combined, dried on MgSO₄ and the solvents were evaporated. The compound was purified by chromatography on silica gel using DCM/Hexanes (6/4) as eluting system to give a white solid (2.54 g, 45%). ¹H NMR (300 MHz, CDCl₃): δ (ppm) 7.80 (dt, J=7.5 Hz, J=1.2 Hz, 2H), 7.71 (dd, J=8.1 Hz, J=0.6 Hz, 2H), 7.37 (td, J=7.5 Hz, J=0.9 Hz, 2H), 7.25 (dd, J=8.1 Hz, J=1.8 Hz, 2H), 7.21-7.11 (m, 12H), 6.80 (dd, J=1.8 Hz, J=0.6 Hz, 2H), 6.77 (dt, J=7.8 Hz, J=0.9 Hz, 2H);

¹³C{¹H} NMR (100 MHz, CDCl₃): δ (ppm) 149.9, 147.6, 141.7, 140.3, 136.0, 134.9, 130.9, 130.1, 129.0, 128.0, 127.9, 127.1, 126.7, 123.9, 120.7, 120.2, 65.6; Anal. Calcd for C₃₇H₂₄S₂: C, 83.42; 1-1, 4.54; S, 12.04. Found C, 83.41; 1-1, 4.55; S, 11.93; HRMS-EI (m/z): [M]⁺ calcd for C₃₇H₂₄S₂, 532.1319. found, 532.1314.

### 2,7-Bis(phenylsulfonyl)-9,9′-spirobi[fluorene](3)

A solution of m-CPBA (2.46 g, 14.62 mmol, 5 eq) in DCM (354 mL) was added to a solution of 7-bis(phenylthio)-9,9′-spirobi[fluorene] (1.52 g, 2.85 mmol, 1 eq) in DCM (594 mL) and stirred at room temperature for 2 days. A 10% K₂CO₃aq solution (300 mL) was added and stirred for 5 minutes. The organic layer was then extracted 3 times with DCM, washed again with a 10% K₂CO₃aq solution (300 mL) and then with H₂O. The combined organic layers were dried over MgSO₄, filtered and the solvents were removed under vacuum. The crude product was purified by chromatography on silica gel using AcOEt/Hexanes (7/3) as eluting system to give a white powder (600 mg, 35%). The compound was sublimed at 2. 10⁻⁶ mbar at 280° C. ¹H NMR (300 MHz, CDCl₃): δ (ppm) 7.93 (dd, J=8.1 Hz, J=0.6 Hz, 2H), 7.90 (m, 2H), 7.88 (dd, J=8.1 Hz, J=1.8 Hz, 2H), 7.79-7.75 (m, 4H), 7.54-7.48 (m, 2H), 7.45-7.38 (m, 8H), 7.08 (td, J=7.5 Hz, J=1.2 Hz, 2H), 7.54 (dt, J=7.5 Hz, J=0.9 Hz, 2H); ¹³C{¹H} NMR (100 MHz, CDCl₃): δ (ppm) 151.2, 145.3, 144.2, 142.1, 142.0, 141.2, 133.2, 129.2, 128.7, 128.2, 128.1, 127.5, 123.7, 123.6, 121.7, 120.7, 66.0; Anal. Calcd for C₃₇H₂₄S₂O₄: C, 74.47; H, 4.05; O, 10.73; S, 10.75. Found C, 74.44; H, 3.94; O, 10.55; S, 10.84; HRMS-EI (m/z): [M]⁺ calcd for C₃₇H₂₄S₂O₄: 596.1116. found, 596.1113.

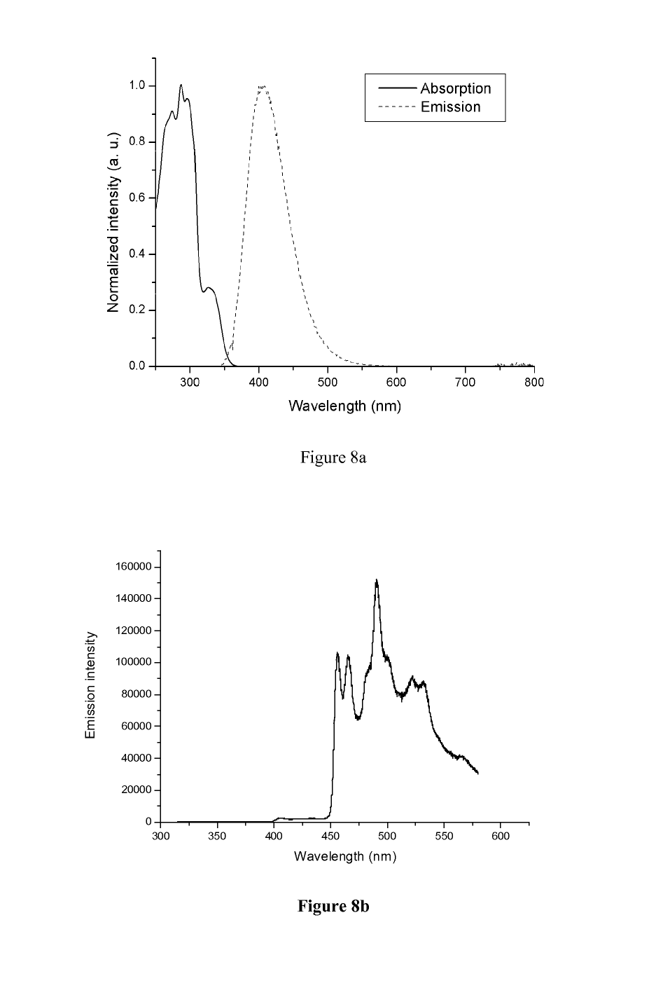

Optical absorption and fluorescent emission spectra for 2,7-bis(phenylsulfonyl)-9,9′-spirobi[fluorene] are shown in FIG. 8a. A red-shifted shoulder was observed at 327 nm in the absorption spectrum that may be related to a charge transfer between the differently substituted phenyl rings of the compound, and the fluorescent emission maximum was also red-shifted to a maximum of 406 nm. FIG. 8b shows the phosphorescent emission spectrum of the same compound at 77 K in a 2-methyl-THF glass. The most energetic vibronic peak was observed at λₘₐₓ=455 nm, corresponding to a triplet energy of 2.72 eV.

### Example 6

### OLED Devices Employing 2,7-bis(phenylsulfonyl)-9,9′-spirobi[fluorene] (3) as a Host in the Emissive Layer

OLED devices employing compound (3), 2,7-bis(phenylsulfonyl)-9,9′-spirobi[fluorene] as a host in the emissive layer, with the architectures ITO/PVK/(3)-Ir(ppy)₃/BCP/LiF/Al were prepared as follows. 35 nm of PVK was spin coated (60 s@1500 rpm, acceleration 10,000) onto air plasma treated indium tin oxide (ITO) coated glass substrates with a sheet resistance of 20 Ω/square (Colorado Concept Coatings, L.L.C.). Then, a concentration of 6% Ir(ppy)₃ was coevaporated with 2,7-bis(phenylsulfonyl)-9,9′-spirobi[fluorene]into a 20-nm-thick film. For the hole-blocking and electron transport layer, a 40 nm-thick layer of BCP was vacuum deposited at a pressure below 1×10⁻⁶ Torr. Finally, 2.5 nm of lithium fluoride (LiF) as an electron-injection layer and a 140 nm-thick aluminum cathode were vacuum deposited at a pressure below 1×10⁻⁶ Torr. A shadow mask was used for the evaporation of the metal to form five devices with an area of 0.1 cm² per substrate. The testing was done right after the deposition of the metal cathode in inert atmosphere without exposing the devices to air.

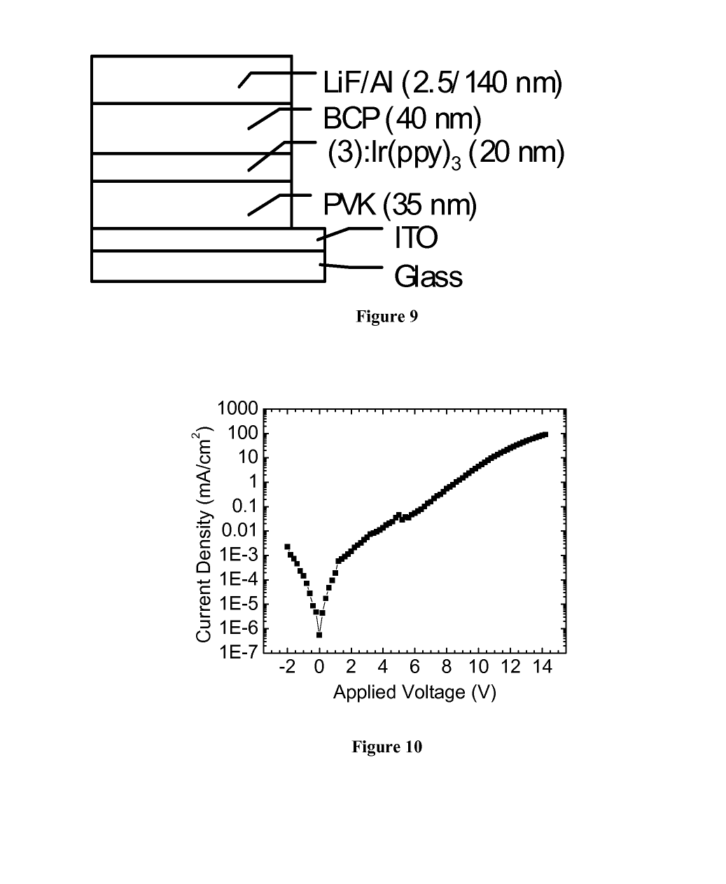

The resulting device architecture is shown in FIG. 9. Luminance-current-voltage (L-I-V) characteristics of the devices were measured using a Keithley 2400 source meter for current-voltage measurements inside a nitrogen-filled glovebox with O₂ and H₂O levels <20 and <1 ppm, respectively.

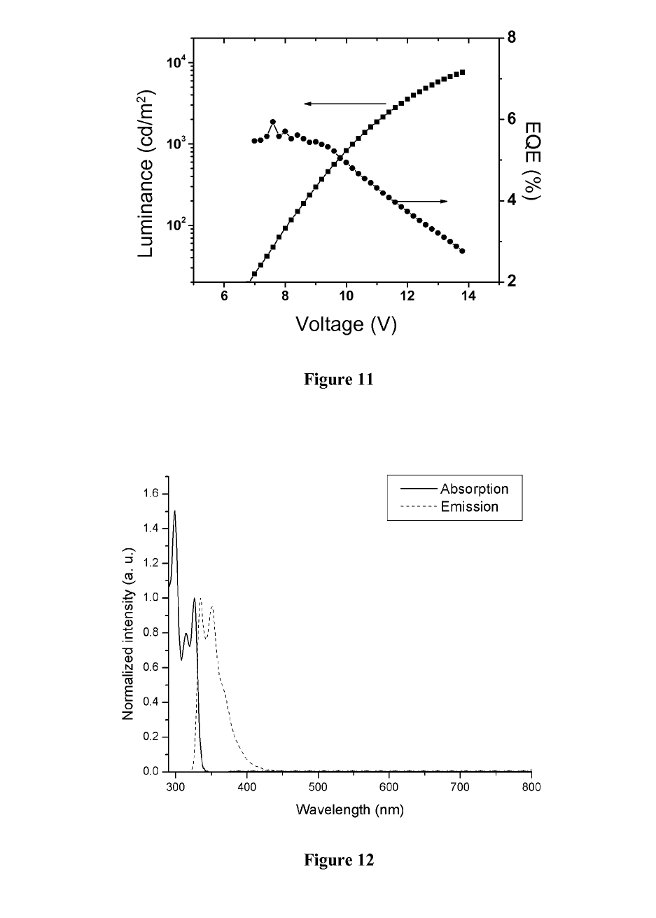

The J-V characteristics of the device architecture are shown in FIG. 10. The L-V and EQE curves of the OLED devices are shown in FIG. 11. At a luminance of 100 cd/m², the device shows maximum external quantum efficiencies (EQE) of 5.7% and a current efficiency of 19.5 cd/A. Furthermore, the turn-on voltage (defined as the voltage required to obtain a brightness of 10 cd/m²) of the device is 6.4 V.

The EQE, current efficiencies, and electroluminescence (EL) spectra demonstrate that 2,7-bis(phenylsulfonyl)-9,9′-spirobi[fluorene] is a good host material for Ir(ppy)₃ in electrophosphorescent green OLEDs.

### Example 7

### Synthesis of 2,2′,7,7′-tetrakis(phenylsulfonyl)-9,9′-spirobi[fluorene], Compound (4)

Compound 4 was synthesized via the multi-step procedure shown below;

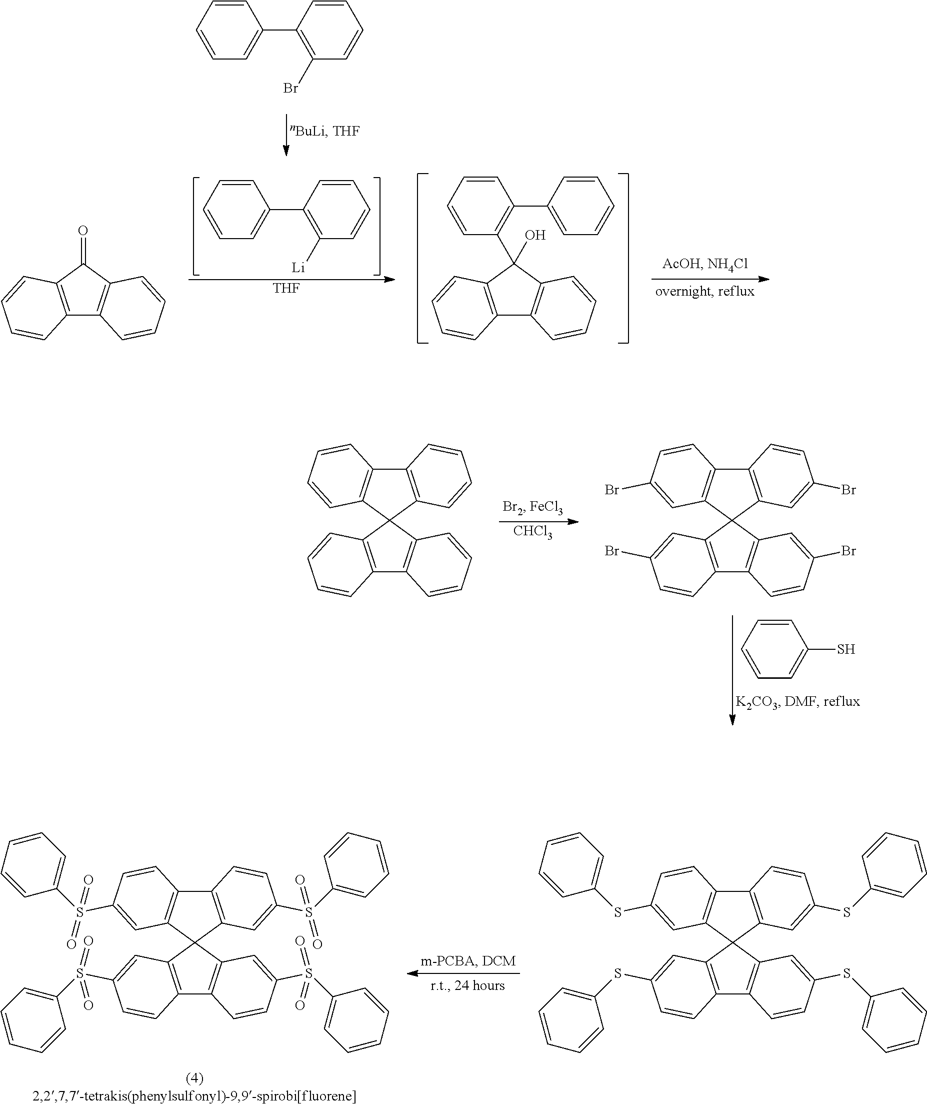

### 9,9′-Spirobi[fluorene]

2-bromobiphenyl (5 g, 21.46 mmol, 1 eq) was dissolved in THF (107 mL). The solution was degassed at −90° C. n-BuLi (15.8 mL, 25.74 mmol, 1.2 eq, 1.63 M) was added dropwise at this temperature to give a yellow solution. After stirring for 1 hour at −90° C., a solution of 9H-fluoren-9-one (3.86 g, 21.45 mmol, 1 eq) in THF (54 mL) was added dropwise. After stirring for 30 minutes at −90° C., the reaction mixture was warmed up to room temperature overnight. Water was added to the dark solution and the crude product was extracted 3 times with ethylacetate. The organic layers were combined, dried on Na₂SO₄ and the solvents were evaporated. The resulting product was placed in suspension in acetic acid (74 mL) and HCl (6.32 mL, 4 M) and the reaction mixture was stirred for 5 hours at reflux. After cooling, the precipitate formed was filtered, washed with acetic acid and dried under vacuum to give the desired compound (2.78 g, 41%). NMR (400 MHz, CDCl₃): δ (ppm): 7.68 (d, J=8 Hz, 2H), 7.53 (dd, J=8 Hz, J=1.2 Hz, 2H), 6.83 (d, J=1.2 Hz, 2H); ¹³C NMR (100 MHz, CDCl₃): δ (ppm) 148.7, 141.7, 127.8, 127.7, 124.0, 119.9, 65.9.

### 2,2′,7,7′Tetrabromo-9,9′-spirobi[fluorene]

9,9′-Spirobi[fluorene] (1.5 g, 4.74 mmol, 1 eq) was dissolved in CHCl₃ (4.7 mL). At 0° C. FeCl₃ (38 mg, 0.24 mmol, 0.05 eq) was added followed by a dropwise addition of a solution of bromine (1.9 mL, 19.43 mmol, 4.1 eq) in CHCl₃ (3 mL) using an addition funnel. After the addition, the dark reaction mixture was stirred for 10 hours. A saturated solution of sodium thiosulfate was added until the red color disappeared. The aqueous layer was extracted with CHCl₃. The combined organic layers were then washed with water, dried on MgSO₄ and evaporated to give a yellow solid (2.87 g, 96%). ¹H NMR (400 MHz, CDCl₃): δ (ppm): 7.67 (d, J=8.1 Hz, 2H), 7.53 (dd, J=8.1 Hz, J=1.8 Hz, 2H), 6.83 (d, J=1.8 Hz, 2H); ¹³C NMR (100 MHz, CDCl₃): δ (ppm) 148.7, 141.7, 127.8, 127.7, 124.0, 119.9, 65.9. EI (m/z): [M]⁺ calcd for C₂₅H₁₂Br₄: 631.8. found, 631.8.

### 2,2′,7,7′-Tetrakis(phenylthio)-9,9′-spirobi[fluorene]

To a stirred solution of 2,2′,7,7′-tetrabromo-9,9′-spirobi[fluorene] (2.85 g, 4.5 mmol, 1 eq), K₂CO₃ (4.98 g, 22.8 mmol, 8 eq) in 59 mL or DME was added thiophenol (6 mL, 5.85 mmol, 13 eq) under nitrogen. The reaction mixture was then placed in a pre-heated bath at 130° C. for 24 hours. Water (200 mL) was added to the mixture which led to the formation of a precipitate. The solid was filtered, washed with water and dried under vacuum to give a white powder (2.18 g, 56%). ¹H NMR (400 MHz, CDCl₃): δ (ppm) 7.68 (d, J=7.8 Hz, 4H), 7.30-7.10 (m, 26H), 6.85 (m, 4H); ¹³C NMR (75 MHz, CDCl₃): δ (ppm): 148.8, 140.2, 136.0, 135.1, 131.3, 130.1, 129.1, 127.0, 126.8, 120.9. HRMS-El (m/z): [M]⁺ calcd for C₄₉H₃₂S₄: 748.1387. found, 748.1369.

### 2,2′,7,7′-Tetrakis(phenylsulfonyl)-9,9′-spirobi[fluorene], (4)

A solution of m-CPBA (2.46 g, 28.6 mmol, 10 eq) in DCM (180 mL) was added to a solution of 2,2′,7,7′-tetrakis(phenylthio)-9,9′-spirobi[fluorene] (1.07 g, 2.86 mmol, 1 eq) in dichloromethane (300 mL) and stirred at room temperature for 2 days. A 10% K₂CO₃aq solution (300 mL) was added and stirred for 5 minutes. The organic layer was then extracted 3 times with dichloromethane, washed again with a 10% K₂CO₃ aq solution (300 mL) and then with H₂O. The combined organic layers were dried over MgSO₄, filtered and the solvents were removed under vacuum. The compound was purified by sublimation to give a white powder (177 mg, 7%). ¹H NMR (400 MHz, CDCl₃): δ (ppm) 8.04 (d, J=8 Hz, 4H), 7.95 (dd, J=8 Hz, J=1.6 Hz, 4H), 7.73 (m, 8H), 7.56 (tt, J=8 Hz, J=1.2 Hz, 4H), 7.47 (t, J=8 Hz, 8H), 7.27 (m, 4H); ¹³C NMR (100 MHz, CDCl₃): δ (ppm) 147.9, 144.5, 142.8, 140.7, 133.6, 129.5, 129.4, 127.4, 123.1, 122.6, 53.4; Anal. Calcd for C₄₉H₃₂S₄O₈: C, 67.10; H, 3.68; O, 14.59; S, 14.62. Found C, 67.29; H, 3.64; 0, 14.34; S, 14.50; HRMS-EI (m/z): calcd for C₄₉H₃₂S₄O₈: 876.0980. found, 876.0934.

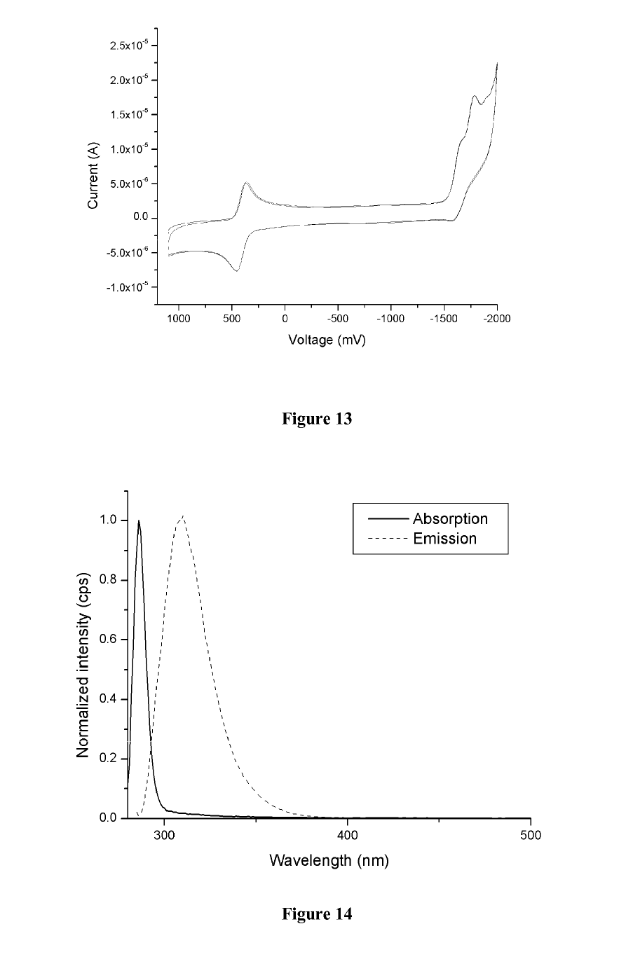

Optical absorption and emission spectra of 2,2′,7,7′-tetrakis(phenylsulfonyl)-9,9′-spirobi[fluorene] in dichloromethane are shown in FIG. 12. Two bands were observed in the emission spectra at 335 nm and 349 nm. A cyclic voltamogram of 2,2′,7,7′-tetrakis(phenylsulfonyl)-9,9′-spirobi[fluorene] in dichloromethane/tetrabutyl-ammonium hexafluorophosphate is shown in FIG. 13.

### Example 8

### Synthesis of 2,2′,6,6′-tetra methyl-4,4′-bis(phenylsulfonyl)biphenyl (5)

Compound 5 was synthesized via the multi-step procedure shown below;

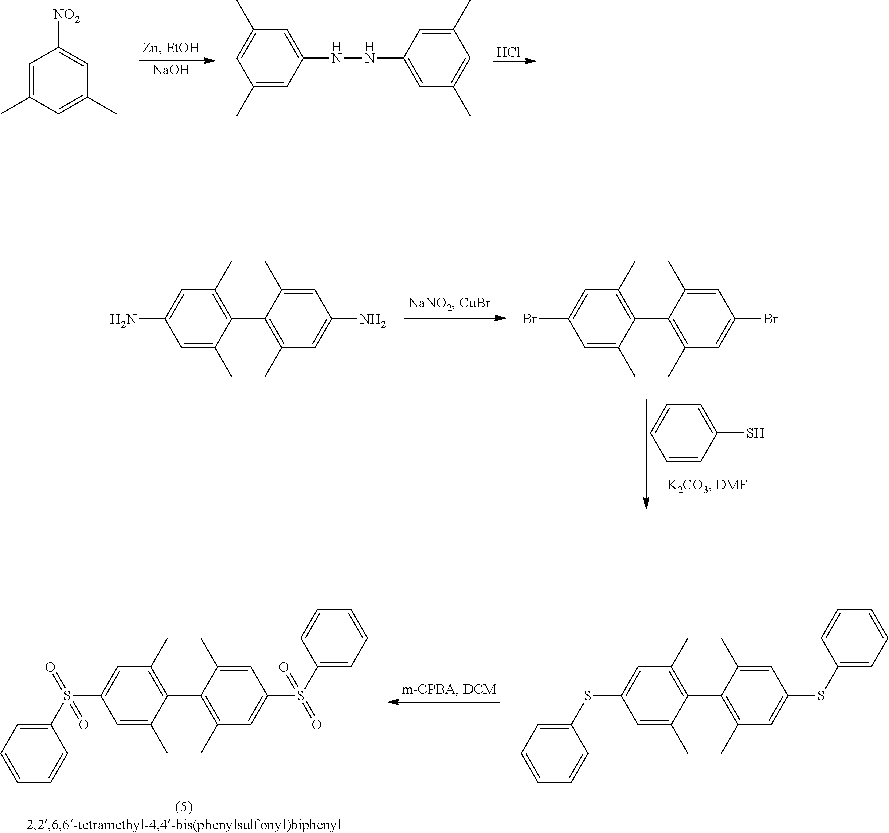

### 1,2-Bis(3,5-dimethylphenyl)hydrazine

A suspension of 1,3-dimethyl-5-nitrobenzene (20 g, 132.3 mmol, 1 eq.) and zinc dust (50.1 g, 765.9 mmol, 5.79 eq.) in ethanol (80 mL) were heated at reflux at which time heating was discontinued. NaOH (30 g, 750 mmol, 5.67 eq.) in water (100 mL) were then added dropwise. The reaction boiled vigorously during the first 30 minutes after which external heating was necessary to maintain reflux. After the addition was complete, the reaction mixture was refluxed for 4 hours under nitrogen and then filtered while hot through a preheated Buchner funnel into 150 mL of 30% acetic acid and 0.5M of Na/S₂O₅. The filtered off sludge was extracted twice with boiling ethanol and the extracts were added to the acetic acid solution. The acetic acid solution was then cooled to 10° C. and the product precipitated (3.03 g, 10%). ¹H NMR (300 MHz, CDCl₃): 5 (ppm) 6.50 (bs, 6H), 5.46 (s, 2H), 2.25 (s, 12H).

### 2,2′,6,6′-Tetramethyl-[1,1′-biphenyl]-4,4′-diamine

HCl (141 mL) was degassed for 30 minutes under nitrogen and then heated at reflux. 1,2-bis(3,5-dimethylphenyl)hydrazine (3 g, 12.2 mmol, 1 eq.) was added and the reaction mixture was refluxed for 5 hours and then stirred at room temperature overnight. The resulting was filtered and the filtrate was boiled for 30 minutes with activated carbon (8 g). The carbon was then filtered off and a 20% solution of NaOH was added to the filtrate until the solution became cloudy. The filtrate was then extracted with diethylether three times. The combined organic layers were dried on Na₂SO₄ and the solvent was removed under reduced pressure. The solid was then dissolved in hot benzene (20 mL) and 40 mL of hexanes were added. The product precipitated from the solution (1.543 g, 52%). ¹H NMR (300 MHz, CDCl₃): δ (ppm) 6.47 (s, 4H), 3.52 (s, 2H), 1.81 (s, 12H).

### 4,4′-Dibromo-2,2′,6,6′-tetramethyl-1,1′-biphenyl

2,2′,6,6′-tetramethyl-[1,1′-biphenyl]-4,4′-diamine (1.54 g, 6.26 mmol, 1 eq.) was dissolved in H₂SO₄ (14.2 mL). The mixture was cooled down at 10° C. (ice bath). NaNO₂ (965 mg) dissolved in water (9 mL) was added dropwise. The reaction mixture turned yellow. After stirring for 30 minutes at 10° C., the reaction mixture was added dropwise to a cold solution of CuBr (9.64 g) in HBr (48% aq., 97 mL) to give a precipitate. The reaction was heated 3 hours at 50° C. and then cooled to room temperature The resulting solution was extracted with Et₂O. The organic layer was washed with HCl and then water. The combined organic layers were dried on Na₂SO₄, filtered off and evaporated. The product was purified on silica gel using DCM/Hexanes (2/8) as eluant to give after evaporation white crystals (939 mg, 40%). ¹H NMR (300 MHz, CDCl₃): δ (ppm) 7.28 (s, 4H), 1.86 (s, 12H).

### (2,2′,6,6′-Tetramethyl-[1,1′-biphenyl]-4,4′-diyl)bis(phenylsulfane)

To a stirred solution of [00062] 4,4′-dibromo-2,2′,6,6′-tetramethyl-1,1′-biphenyl (939 mg, 2.55 mmol, 1 eq), K₂CO₃ (2.82 g, 20.4 mmol, 8 eq) in 33 mL of DMF was added thiophenol (1.05 mL, 10.2 mmol, 4 eq) under nitrogen. The reaction mixture was then placed in a pre-heated bath at 130° C. for 36 hours. Water (200 mL) was added to the mixture which was then extracted 3 times with ethylacetate. The combined organic layers were washed with saturated NaCl solution, dried over MgSO₄, filtered off and dried. The product was purified on silica gel (100% hexanes) (765 mg, 70%). ¹H NMR (300 MHz, CDCl₃): δ (ppm) 7.40-7.20 (m, 10H), 7.13 (s, 4H), 1.86 (s, 12H).

### 2,2′,6,6′-Tetramethyl-4,4′-bis(phenylsulfonyl)-1,1′-biphenyl

A solution of m-CPBA (2.46 g, 14.62 mmol, 5 eq) in DCM (354 mL) was added to a solution of (2,2′,6,6′-tetramethyl-[1,1′-biphenyl]-4,4′-diyl)bis(phenylsulfane) (1.52 g, 2.85 mmol, 1 eq) in dichloromethane (594 mL) and stirred at room temperature for 2 days. A 10% K₂CO₃ aq. solution (300 mL) was added and stirred for 5 minutes. The organic layer was then extracted 3 times with DCM, washed again with a 10% K₂CO₃ aq. solution (300 mL) and then with H₂O. The combined organic layers were dried over MgSO₄, filtered and the solvents were removed under vacuum. The crude product was purified by chromatography on silica gel using ethylacetate/Hexanes (7/3) as eluting system to give a white powder (600 mg, 68%). HRMS-EI (m/z): [M]+ calcd for C28H26S2O4: 490.1273. found, 490.1263. ¹H NMR (400 MHz, CDCl₃): δ (ppm) 7.97 (d, J=8.4 Hz, 4H), 7.70 (s, 4H), 7.62-7.52 (m, 6H), 1.87 (s, 12H); ¹³C NMR (100 MHz, CDCl₃): δ (ppm) 143.7, 141.6, 140.7, 136.9, 133.2, 129.3, 127.8, 126.8, 19.9. Anal. Calcd for C₂₈H₂₆S₂O₄: C, 68.54; H, 5.34; 0, 13.04; S, 13.07. Found C, 68.14; H, 5.29; 0, 12.89; S, 13.43. HRMS-EI (m/z): [M]+ calcd for C₂₈H₂₆S₂O₄: 490.1273. found, 490.1263.

Optical absorption and emission spectra of 2,2′,6,6′-tetramethyl-4,4′-bis(phenylsulfonyl)-1,1′-biphenyl in DCM are shown in FIG. 14.

### Example 9

### OLED Devices Employing 2,2′,6,6′-tetramethyl-4,4′-bis(phenylsulfonyl)biphenyl (5) as a Host in an Emissive Layer Processed from Solution With A Green-Emitting Phosphor

OLED devices employing compound (5), 2,2′,6,6′-tetramethyl-4,4′-bis(phenylsulfonyl)biphenyl, as a host in the emissive layer, with the architectures ITO/Poly-TPD-F/Compound (5)-Ir(pppy)₃/BCP/LiF/Al/Ag were prepared as follows. Indium tin oxide (ITO)-coated glass (Colorado Concept Coatings LLC) with a sheet resistivity of ˜15 Ω/sq was used as the substrates for the OLED fabrication. The ITO substrates were cleaned in an ultrasonic bath of detergent water, rinsed with deionized water, and then cleaned in sequential ultrasonic baths of deionized water, acetone, and isopropanol. Each ultrasonic bath lasted for 20 minutes. Nitrogen was used to dry the substrates after each of the last three baths.

For the Poly-TPD-F hole-transport layer, 10 mg of Poly-TPD-F were dissolved in 1 ml of distilled and degassed over night chloroform with purity of 99.8%. 35 nm thick films of the hole-transport material were spin coated (60 s @ 1500 rpm, acceleration 10,000) onto indium tin oxide (ITO) coated glass substrates treated with O₂ plasma for 3 minutes. After spin-coating, the following steps were carried-out in a glove box: (i) Remove part of layer with fresh chloroform on the ITO part of substrate to ensure better anode connection; (ii) Pumping in the glove box ante-chamber for 15 minutes; (iii) Annealing at 75° C. on a hot plate for 15 minutes; (iv) Expose under UV lamp at an irradiance of 0.7 mW/cm² for 1 minute. For the emissive layer, compound (5) was mixed with a weight concentration of 6 wt % of Ir(pppy)₃. The guest emitter Ir(pppy)₃ was synthesized via a known procedure as recited in Example 7 of US Patent Publication 2006/127696.

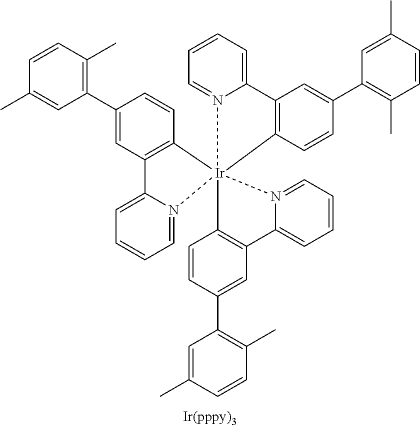

Compound (5) and Ir(pppy)₃ were dissolved in 1 ml of distilled and degassed over night chlorobenzene with purity of 99.8%. 40-50 nm thick films of the emissive layers were spin coated (60 s @ 1000 rpm, acceleration 10,000) onto the UV crosslinked poly-TPD-F layer. After spin-coating, substrates were annealed at 75° C. for 15 minutes. The hole-blocking and electron transport layer BCP was deposited in an EvoVac Angstrom Engineering vacuum system. 40 nm BCP was vacuum deposited at a pressure below 2×10⁻⁷ Torr and at a deposition rate of 0.4 Å/s. Then, a 2.4 nm-thick layer of lithium fluoride (LiF) was deposited as an electron-injection layer, followed by a 40 nm-thick aluminum cathode deposited at a pressure below 3×10⁻⁷ Torr and at a rate of 0.15 Å/s and 2 Å/s, respectively. Finally, 100 nm-thick layer of silver was vacuum deposited at a pressure below 3×10⁻⁷ Torr and at a rate of 1.1 Å/s. A shadow mask was used for the evaporation of the metal to form five devices with an area of roughly 0.1 cm² per substrate.

The testing was done right after the deposition of the metal cathode in inert atmosphere without exposing the devices to air. Luminance-current-voltage (L-I-V) characteristics of the devices were measured using a Keithley 2400 source meter for current-voltage measurements inside a nitrogen-filled glovebox with O₂ and H₂O levels <20 and <1 ppm, respectively.

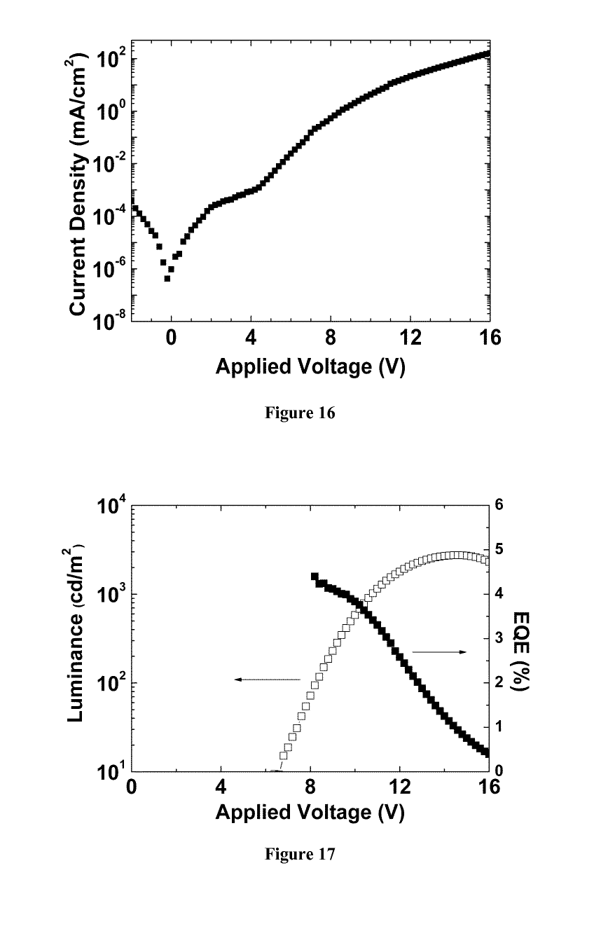

The J-V characteristics of the device architecture are shown in FIG. 16. The L-V and EQE curves of the OLED devices are shown in FIG. 17. At a luminance levels of 100 cd/m² and 1,000 cd/m² the device shows maximum external quantum efficiencies (EQE) of 4.4% and 3.5%, respectively. Furthermore, the turn-on voltage (defined as the voltage required to obtain a brightness of 10 cd/m²) of the device is low and has a value of 6.6 V.

The EQE, current efficiencies, and electroluminescence (EL) spectra demonstrate that compound (4), 2,2′,6,6′-tetramethyl-4,4′-bis(phenylsulfonyl)biphenyl, is a good host material for the green emitting Ir(pppy)₃ phosphor in electrophosphorescent OLEDs. Furthermore, this example illustrates that the compounds of this invention can be processed in some instances from solution and lead to efficient devices in which the emissive layer is processed from solution.

### Example 10

### OLED Devices Employing 2,2′,6,6′-tetramethyl-4,4′-bis(phenylsulfonyl)biphenyl (5) as a Host in an Emissive Layer Processed From Solution with a Blue/Green Emitting Phosphor

OLED devices employing compound (4), 2,2′,6,6′-tetramethyl-4,4′-bis(phenylsulfonyl)biphenyl, as a host in the emissive layer, with the architectures ITO/PEDOT:PSS A14083F/(5)-Flrpic/BCP/LiF/Al/Ag were prepared as follows. Indium tin oxide (ITO)-coated glass (Colorado Concept Coatings LLC) with a sheet resistivity of ˜15 Ω/sq was used as the substrates for the OLED fabrication. The ITO substrates were cleaned in an ultrasonic bath of detergent water, rinsed with deionized water, and then cleaned in sequential ultrasonic baths of deionized water, acetone, and isopropanol. Each ultrasonic bath lasted for 20 minutes. Nitrogen was used to dry the substrates after each of the last three baths. For the PEDOT: PSS hole-transport layer, PEDOT:PSS A14083 (see structure below) was purchased from H.C. Starck Clevios and spin coated (60 s @ 5000 rpm, acceleration 10,000) onto indium tin oxide (ITO) coated glass substrates treated with O₂ plasma for 3 minutes. After spin-coating, the PEDOT:PSS films were annealed at 140° C. on a hot plate for 10 minutes.

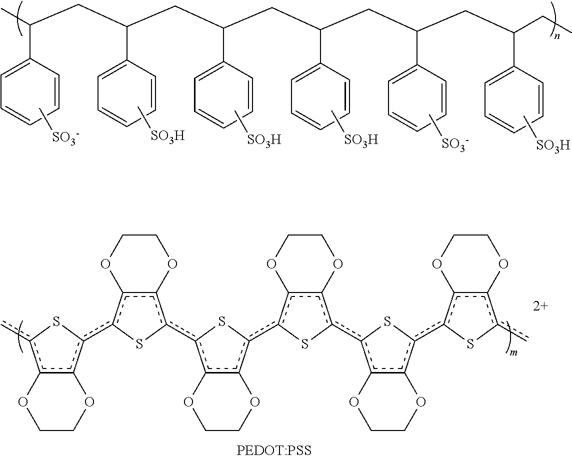

For the emissive layer, compound (5) was mixed with a weight concentration of 12 wt % of Flrpic. Both compounds were dissolved in 1 ml of distilled and degassed over night chlorobenzene with purity of 99.8%. 40-50 nm thick films of the emissive layers were spin coated (60 s @ 1000 rpm, acceleration 10,000) onto the PEDOT:PSS layers. After spin-coating, substrates were annealed at 75° C. for 15 minutes. The hole-blocking and electron transport layer BCP was deposited in an EvoVac Angstrom Engineering vacuum system. 40 nm BCP was vacuum deposited at a pressure below 2×10⁻⁷ Torr and at a deposition rate of 0.4 Å/s. Then, a 2.4 nm-thick layer of lithium fluoride (LiF) was deposited as an electron-injection layer, followed by a 40 nm-thick aluminum cathode deposited at a pressure below 3×10⁻⁷ Torr and at a rate of 0.15 Å/s and 2 Å/s, respectively. Finally, 100 nm-thick layer of silver was vacuum deposited at a pressure below 3×10⁻⁷ Torr and at a rate of 1.1 Å/s. A shadow mask was used for the evaporation of the metal to form five devices with an area of roughly 0.1 cm² per substrate.

The testing was done right after the deposition of the metal cathode in inert atmosphere without exposing the devices to air. Luminance-current-voltage (L-1-V) characteristics of the devices were measured using a Keithley 2400 source meter for current-voltage measurements inside a nitrogen-Filled glovebox with O₂ and H₂O levels <20 and <1 ppm, respectively.

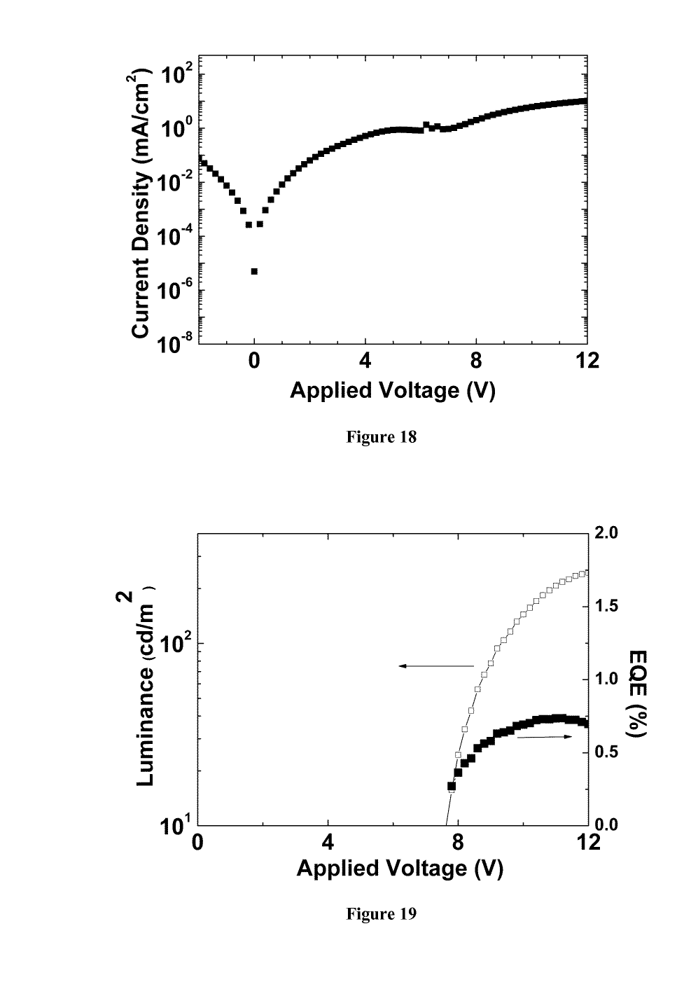

The J-V characteristics of the device architecture are shown in FIG. 18. The L-V and EQE curves of the OLED devices are shown in FIG. 19. At a luminance level of 100 cd/m² the device shows maximum external quantum efficiencies (EQE) of 0.64%. The EQE, current efficiencies, and electroluminescence (EL) spectra demonstrate that compound (5), 2,2′,6,6′-tetramethyl-4,4′-bis(phenylsulfonyl)biphenyl, can serve is a host material for blue emitting Flrpic phosphor in electrophosphorescent OLEDs.

### Example 11

### OLED Devices Employing 2,7-bis(phenylsulfonyl)-9,9′-spirobi[fluorene] (3) as an Electron Transport Layer

OLED devices employing compound (5), 2,7-bis(phenylsulfonyl)-9,9′-spirobi[fluorene], as an electron transport layer in devices with the architecture ITO/PEDOT:PSS A14083F/α-NPD/CBP:Ir(ppy)₃/(3)/LiF/Al/Ag were prepared as follows. Indium tin oxide (ITO)-coated glass (Colorado Concept Coatings LLC) with a sheet resistivity of ˜15 Ω/sq was used as the substrates for the OLED fabrication. The ITO substrates were cleaned in an ultrasonic bath of detergent water, rinsed with deionized water, and then cleaned in sequential ultrasonic baths of deionized water, acetone, and isopropanol. Each ultrasonic bath lasted for 20 minutes. Nitrogen was used to dry the substrates after each of the last three baths. For the PEDOT:PSS hole-transport layer, PEDOT:PSS A14083 was purchased from H.C. Starck Clevios and spin coated (60 s @ 5000 rpm, acceleration 10,000) onto indium tin oxide (ITO) coated glass substrates treated with O₂ plasma for 3 minutes. After spin-coating, the PEDOT:PSS films were annealed at 140° C. on a hot plate for 10 minutes. For the hole transport layer, 35 nm α-NPD was deposited in an EvoVac Angstrom Engineering vacuum deposition system at a pressure below 2×10⁻⁷ Torr and at a deposition rate of 0.6 Å/s. α-NPD was purchased from Luminescence technology corp., Taiwan.

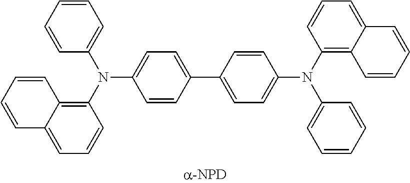 [SMILES: c1ccc(N(c2ccc(-c3ccc(N(c4ccccc4)c4cccc5ccccc45)cc3)cc2)c2cccc3ccccc23)cc1]

For the emissive layer, CBP and Ir(ppy)₃ were co-deposited in the EvoVac system at a pressure below 10×10⁻⁸ Torr and at a deposition rate of 1 and 0.06 Å/s, respectively. CBP was purchased from Sigma Aldrich

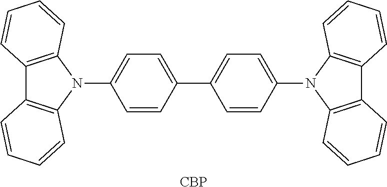 [SMILES: c1ccc2c(c1)c1ccccc1n2-c1ccc(-c2ccc(-n3c4ccccc4c4ccccc43)cc2)cc1 ; "CBP"]

For the hole-blocking and electron transport layer, 40 nm compound (3), 2,7-bis(phenylsulfonyl)-9,9′-spirobi[fluorene], was vacuum deposited at a pressure below 2×10⁻⁷ Torr and at a deposition rate of 0.4 Å/s. Then, a 2.4 nm-thick layer of lithium fluoride (LiF) was deposited as an electron-injection layer, followed by a 40 nm-thick aluminum cathode deposited at a pressure below 3×10⁻⁷ Torr and at a rate of 0.15 Å/s and 2 Å/s, respectively. Finally, 100 nm of silver was vacuum deposited at a pressure below 3×10⁻⁷ Torr and at a rate of 1.1 Å/s. A shadow mask was used for the evaporation of the metal to form five devices with an area of roughly 0.1 cm² per substrate.

The testing was done right after the deposition of the metal cathode in inert atmosphere without exposing the devices to air. Luminance-current-voltage (L-TV) characteristics of the devices were measured using a Keithley 2400 source meter for current-voltage measurements inside a nitrogen-filled glovebox with O₂ and H₂O levels <20 and <1 ppm, respectively.

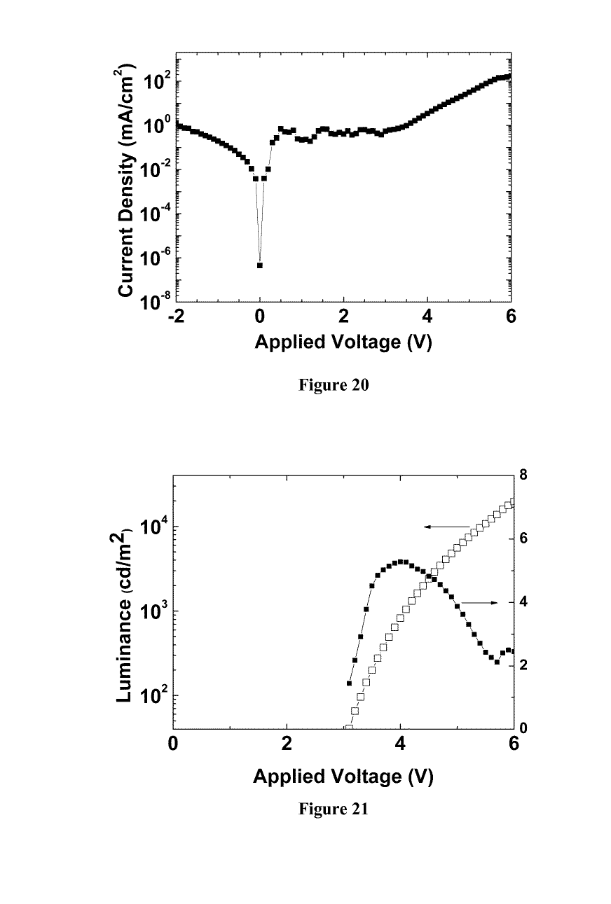

The J-V characteristics of the device architecture are shown in FIG. 20. The L-V and EQE curves of the OLED devices are shown in FIG. 21. At a luminance level of 1,000 cd/m² the device shows maximum external quantum efficiencies (EQE) of 5.27%. The EQE, current efficiencies, and electroluminescence (EL) spectra demonstrate that compound (3), 2,7-bis(phenylsulfonyl)-9,9′-spirobi[fluorene], can serve is a good electron transport material in electrophosphorescent OLEDs.

### Example 12

### Device Using Bis(Phenylsulfonyl)Biphenyl (1) as a Host in the Emissive Layer

Indium tin oxide (ITO)-coated glass slides (Colorado Concept Coatings LLC) with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were O₂ plasma treated for 2 min.

PVK was processed in the glove box under nitrogen. 10 mg of PVK was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of a host—(1) and an emitter—Flrpic was deposited by co-evaporation of the two components at 0.88 Å/s and 0.12 Å/s respectively. The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

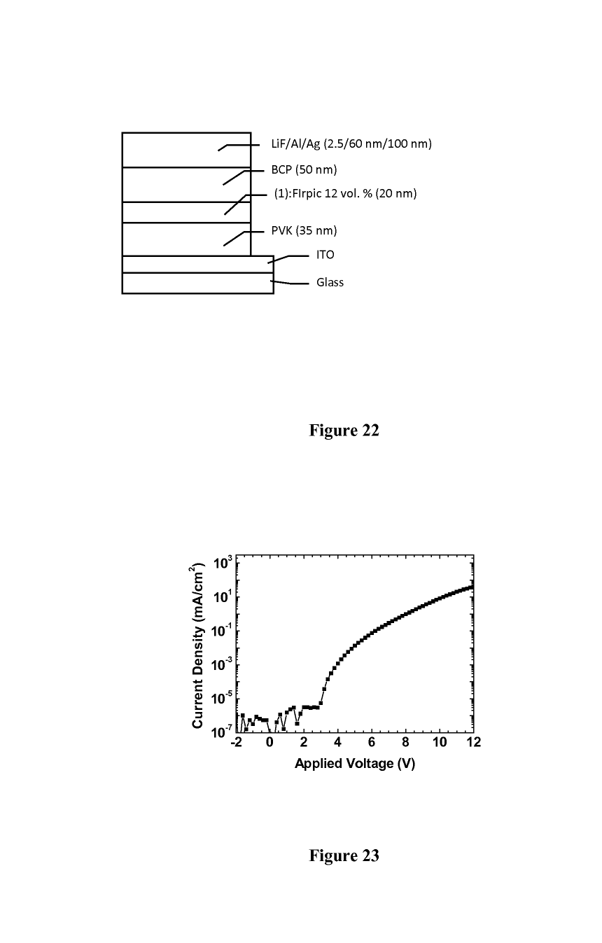

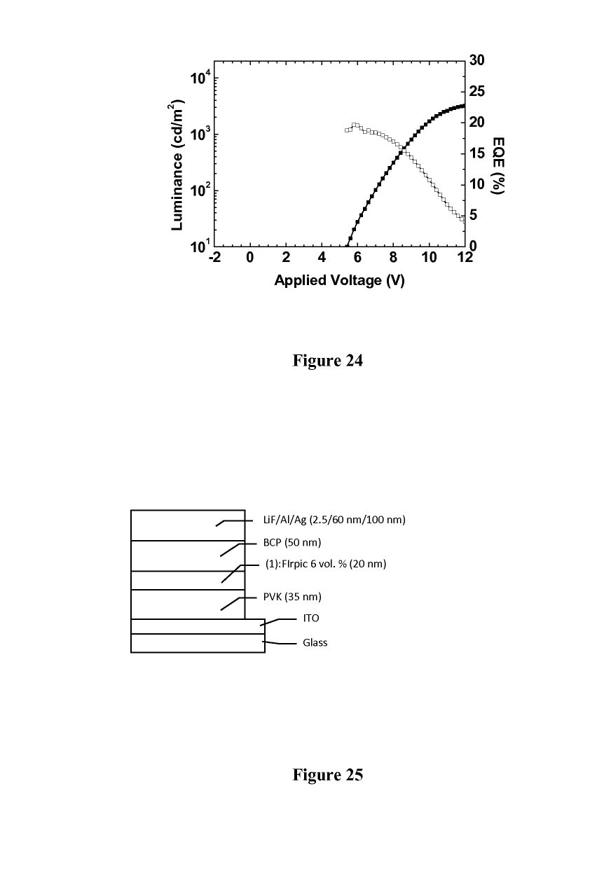

FIG. 22 shows a schematic of the resulting device, FIG. 23 shows the current density across an applied voltage and FIG. 24 shows the luminance and quantum efficiency across a voltage range.

### Example 13

### Device Using Bis(Phenylsulfonyl)Biphenyl (1) as a Host in the Emissive Layer

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were O₂ plasma treated for 2 min.

PVK was processed in the glove box under nitrogen. 10 mg of PVK was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of a host—(1) and an emitter—Flrpic was deposited by co-evaporation of the two components at 0.94 Å/s and 0.06 Å/s respectively. The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

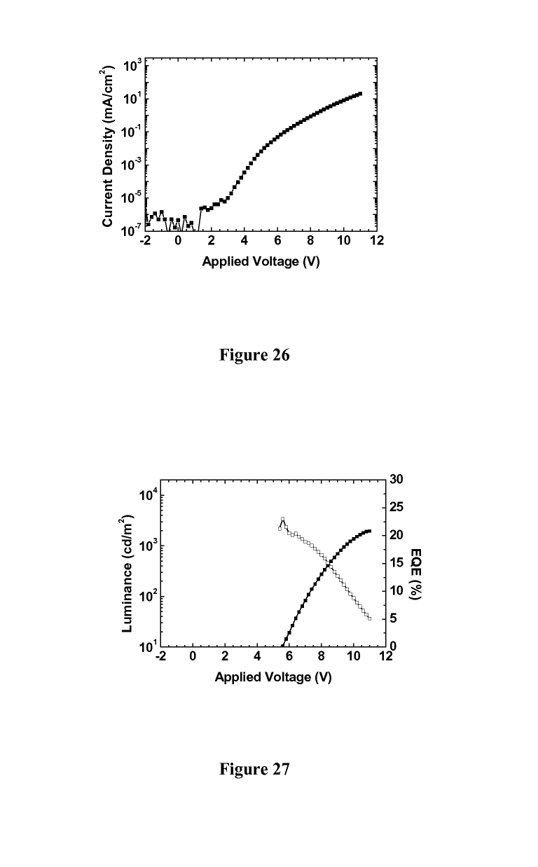

FIG. 25 shows a schematic of the resulting device, FIG. 26 shows the current density across an applied voltage and FIG. 27 shows the luminance and quantum efficiency across a voltage range.

### Example 14

### Device using 3,4′-bis(m-tolylsulfonyl)biphenyl as a Host in the Emissive Layer

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were 0, plasma treated for 2 min.

p-TPDF was processed in the glove box under nitrogen. 10 mg of p-TPDF was dissolved in 1 ml of anhydrous chlorobenzene. The hole-transport layer was spin-coated onto ITO at 1500 rpm, acceleration 1,000 rpm/sec for 60 sec. The films were then heated at 80° C. for 15 minutes to remove solvent and subsequently exposed to 365 nm UV light for 10 min to photo cross-link the p-TPDF film.

Emissive layer, consisting of a host—3,4′-bis(m-tolylsulfonyl)biphenyl and an emitter—Ir(ppy)₃ was deposited by co-evaporation of the two components at 0.94 Å/s and 0.06 Å/s respectively. The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

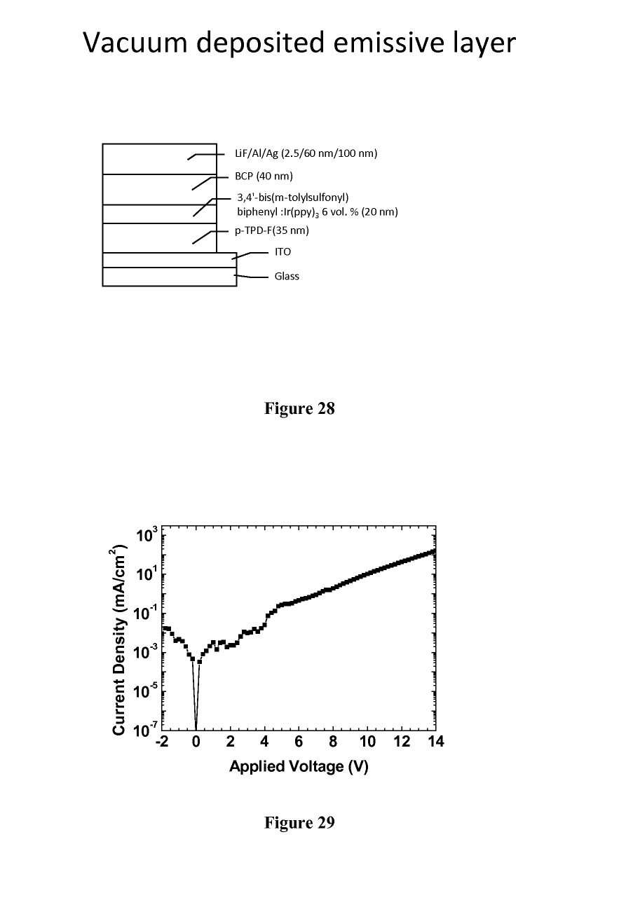

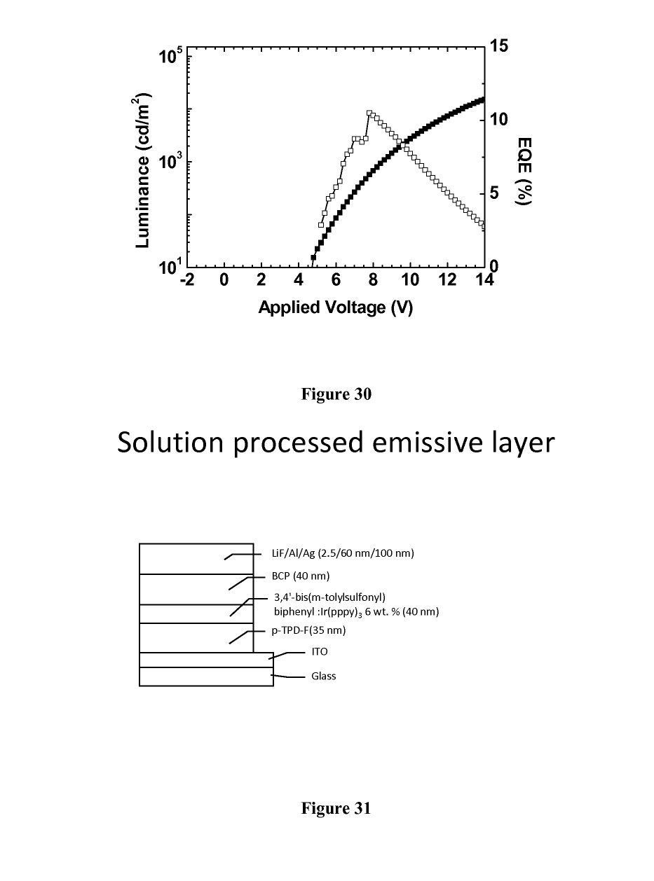

FIG. 28 shows a schematic of the resulting device, FIG. 29 shows the current density across an applied voltage and FIG. 30 shows the luminance and quantum efficiency across a voltage range.

### Example 15

### Device Using Solution Processed Emissive Layer with 3,4′-bis(m-tolylsulfonyl)biphenyl as a Host

Indiuz tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were 0, plasma treated for 2 min.

p-TPDF was processed in the glove box under nitrogen. 10 mg of p-TPDF was dissolved in 1 ml of anhydrous chlorobenzene. The hole-transport layer was spin-coated onto ITO at 1500 rpm, acceleration 1,000 rpm/sec for 60 sec. The films were then heated at 80° C. for 15 minutes to remove solvent and subsequently exposed to 365 nm UV light for 10 min to photo cross-link the p-TPDF film.

Emissive layer, consisting of the 3,4′-bis(m-tolylsulfonyl)biphenyl host and emitter was prepared in the following way in the glove box: 10 mg of 3,4′-bis(m-tolylsulfonyl)biphenyl was dissolved in 1 ml chlorobenzene and 10 mg of Ir(pppy)₃ in 1 ml of chlorobenzne. 64 μl of Ir(pppy)₃ was added to 1 ml of the solution of AS-II-25. The solution was then spin-coated onto the HTL at 1000 rpm, 1000 rpm/sec, 60 sec. The films were dried at 75° C. for 10-15 min.

The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

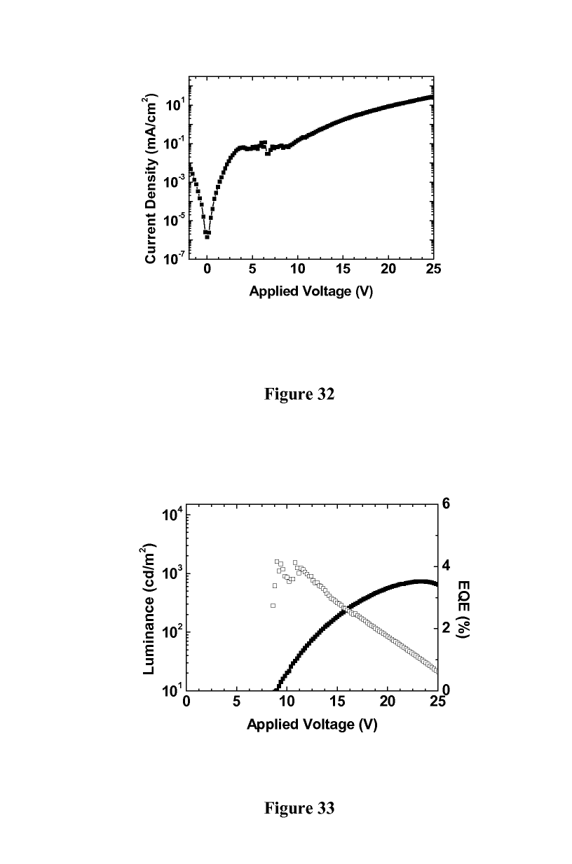

FIG. 31 shows a schematic of the resulting device, FIG. 32 shows the current density across an applied voltage and FIG. 33 shows the luminance and quantum efficiency across a voltage range.

### Example 16

### Device Using Solution Processed Emissive Layer with 3,4′-bis(m-tolylsulfonyl)biphenyl as a Host

Indium tin oxide (ITO)-coated glass slides with a sheet resistivity of ˜15 μl/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were 0, plasma treated for 2 min.

p-TPDF was processed in the glove box under nitrogen. 10 mg of p-TPDF was dissolved in 1 ml of anhydrous chlorobenzene. The hole-transport layer was spin-coated onto ITO at 1500 rpm, acceleration 1,000 rpm/sec for 60 sec. The films were then heated at 80° C. for 15 minutes to remove solvent and subsequently exposed to 365 nm UV light for 10 min to photo cross-link the p-TPDF film.

Emissive layer, consisting of the 3,4′-bis(m-tolylsulfonyl)biphenyl host and emitter was prepared in the following way in the glove box: 10 mg of AS-II-25 was dissolved in 1 ml chlorobenzene and 10 mg of Flrpic in 1 ml of chlorobenzne. 128 μl of Flrpic was added to 1 ml of the solution of 3,4′-bis(m-tolylsulfonyl)biphenyl. The solution was then spin-coated onto the HTL at 1000 rpm, 1000 rpm/sec, 60 sec. The films were dried at 75° C. for 10-15 min.

The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

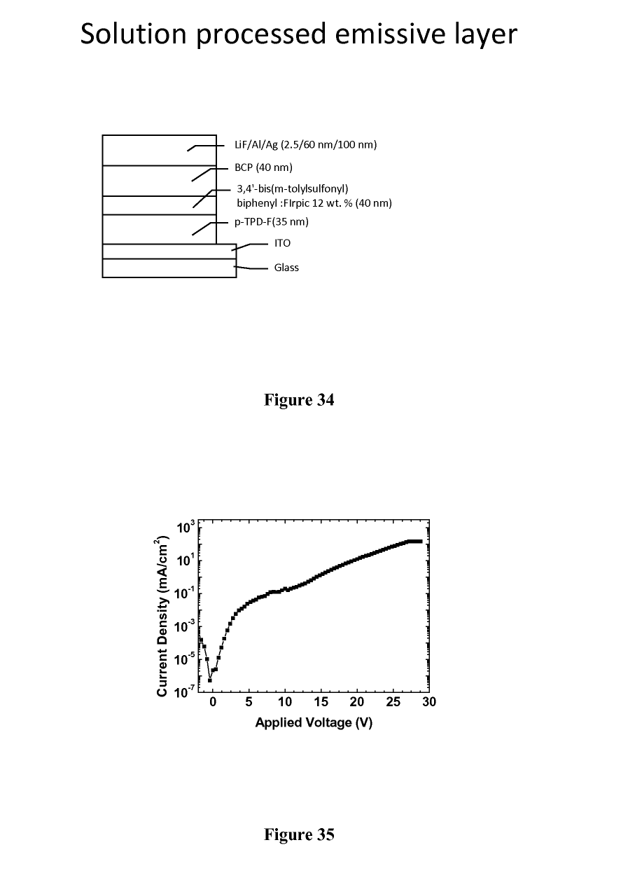

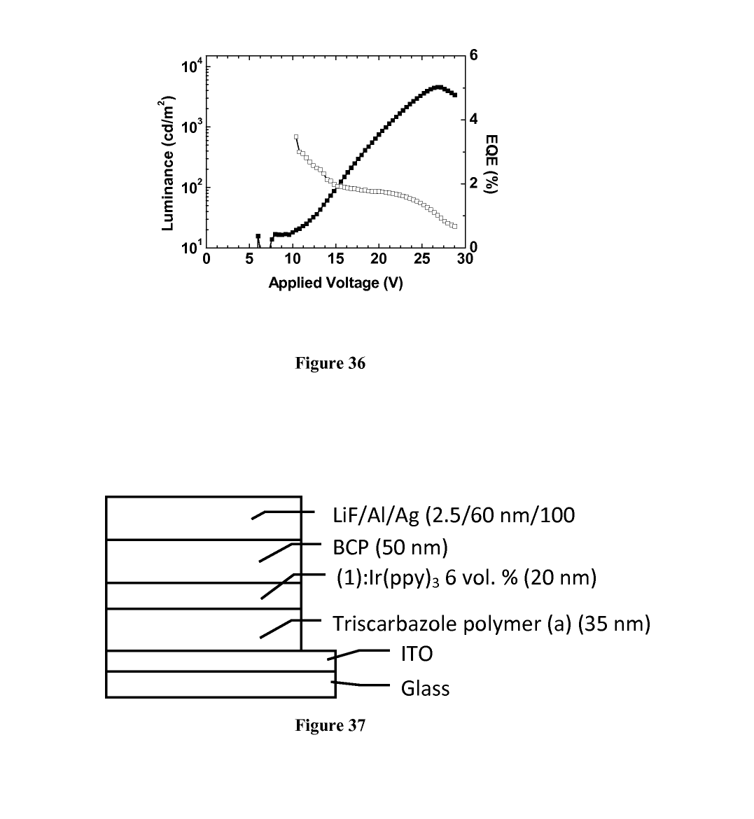

FIG. 34 shows a schematic of the resulting device, FIG. 35 shows the current density across an applied voltage and FIG. 36 shows the luminance and quantum efficiency across a voltage range.

### Example 17

### Using (1) as a Host in an Emissive Layer and Triscarbazole Polymer (a) as a Hole-Transport Material

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were 0, plasma treated for 2 min.

Triscarbazole polymer (a) was processed in the glove box under nitrogen. 10 mg of triscarbazole polymer (a) was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of a host—(1) and an emitter—Ir(ppy)₃ was deposited by co-evaporation of the two components at 0.94 Å/s and 0.06 Å/s respectively. The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

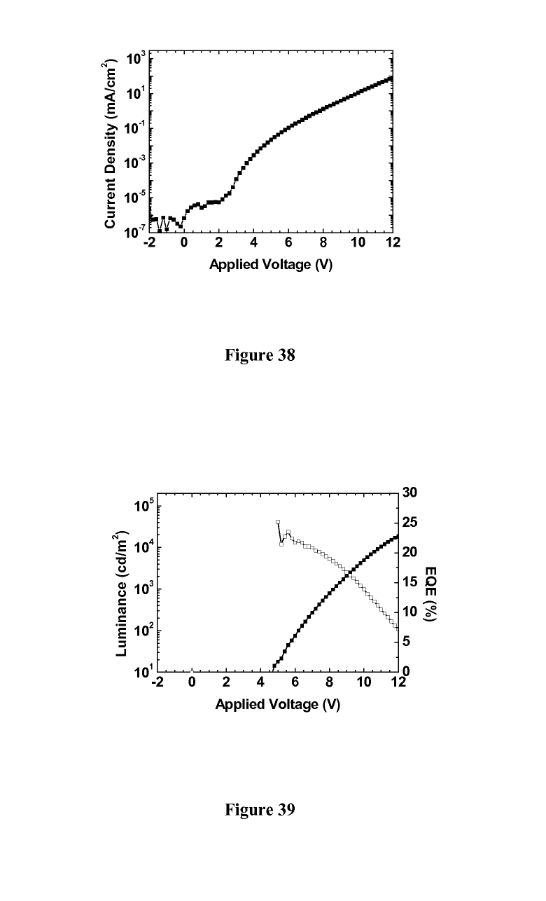

FIG. 37 shows a schematic of the resulting device, FIG. 38 shows the current density across an applied voltage and FIG. 39 shows the luminance and quantum efficiency across a voltage range.

### Example 18

### Using (1) as a Host in an Emissive Layer and Triscarbazole Polymer (a) as a Hole-Transport Material

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were O₂ plasma treated for 2 min.

The hole injection layer, MoO₃ was thermally evaporated at 0.2 Å/s. The pressure in the vacuum chamber was 1×10⁻⁷ Torr.

Triscarbazole polymer (a) was processed in the glove box under nitrogen. 10 mg of tricarbazole polymer was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of a host—(I) and an emitter—Ir(ppy)₃ was deposited by co-evaporation of the two components at 0.94 Å/s and 0.06 Å/s respectively. The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

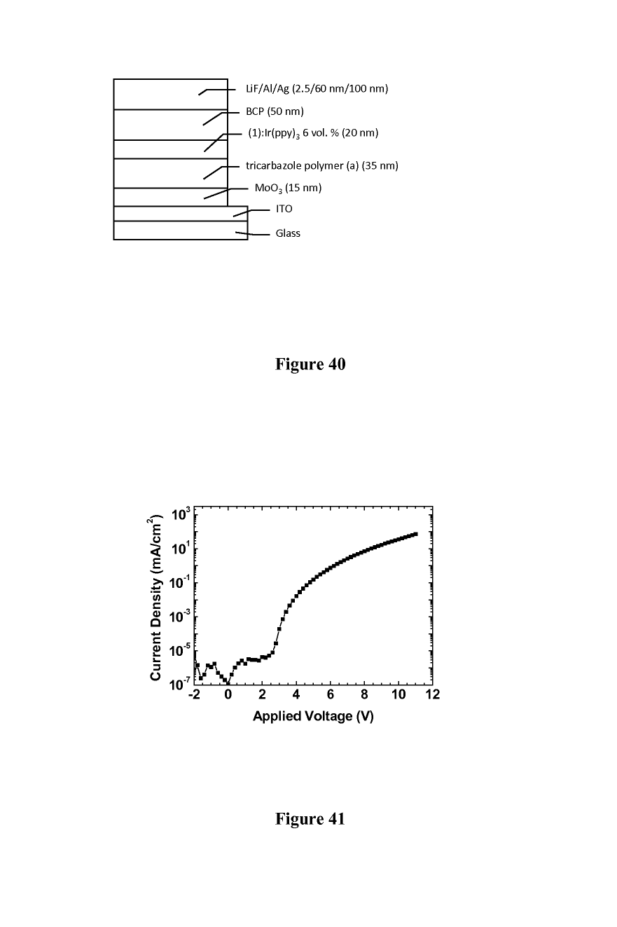

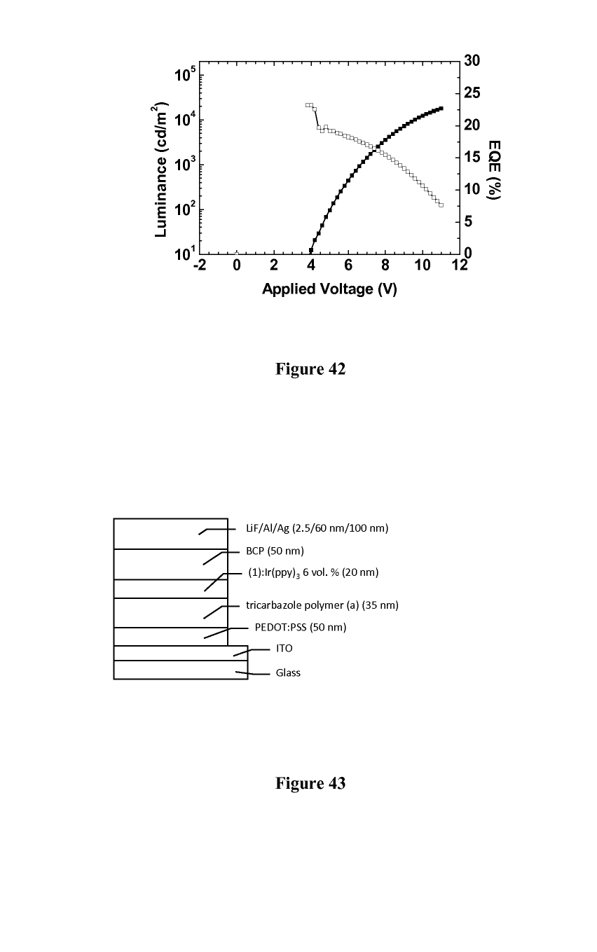

FIG. 40 shows a schematic of the resulting device, FIG. 41 shows the current density across an applied voltage and FIG. 42 shows the luminance and quantum efficiency across a voltage range.

### Example 19

### Using (1) as a Host in an Emissive Layer and Triscarbazole Polymer (a) as a Hole-Transport Material

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were 0, plasma treated for 2 min.

Immediately after O₂ plasma treatment of the ITO slides, PEDOT:PSS AI4083 was spin-coated at 5000 rpm, acceleration—928 rpm/s for 60 sec. Subsequently, the films were heated on a hot plate at 140° C. for 15 min. PEDOT:PSS was deposited in air.

Triscarbazole polymer (a) was processed in the glove box under nitrogen. 10 mg of tricarbazole polymer (a) was dissolved in 1 ml of anhydrous chlorobenzene. 35, nm thick films of the hole-transport material were spin-coated at 1500 rpm, acceleration 1,000 rpm/sec for 60 sec. The films were then heated on a hot plate at 120° C. for 20 minutes.

Emissive layer, consisting of a host—(1) and an emitter—Ir(ppy)₃ was deposited by co-evaporation of the two components at 0.94 Å/s and 0.06 Å/s respectively. The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

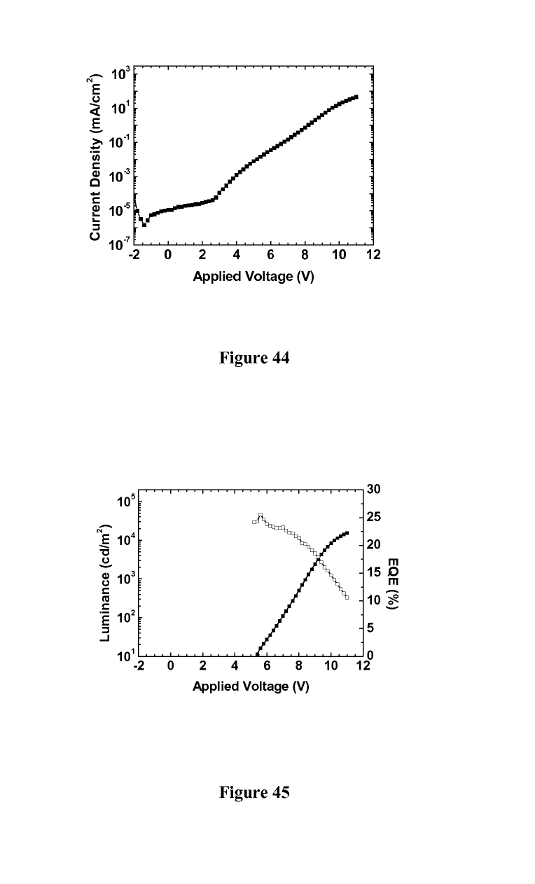

FIG. 43 shows a schematic of the resulting device, FIG. 44 shows the current density across an applied voltage and FIG. 45 shows the luminance and quantum efficiency across a voltage range.

### Example 20

### Using (1) as a Host in an Emissive Layer and Triscarbazole Polymer (a) as a Hole-Transport Material

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were O₂ plasma treated for 2 min.

Triscarbazole polymer (a) was processed in the glove box under nitrogen. 10 mg of tricarbazole polymer (a) was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of a host—(1) and an emitter—Flrpic was deposited by co-evaporation of the two components at 0.88 Å/s and 0.12 Å/s respectively. The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

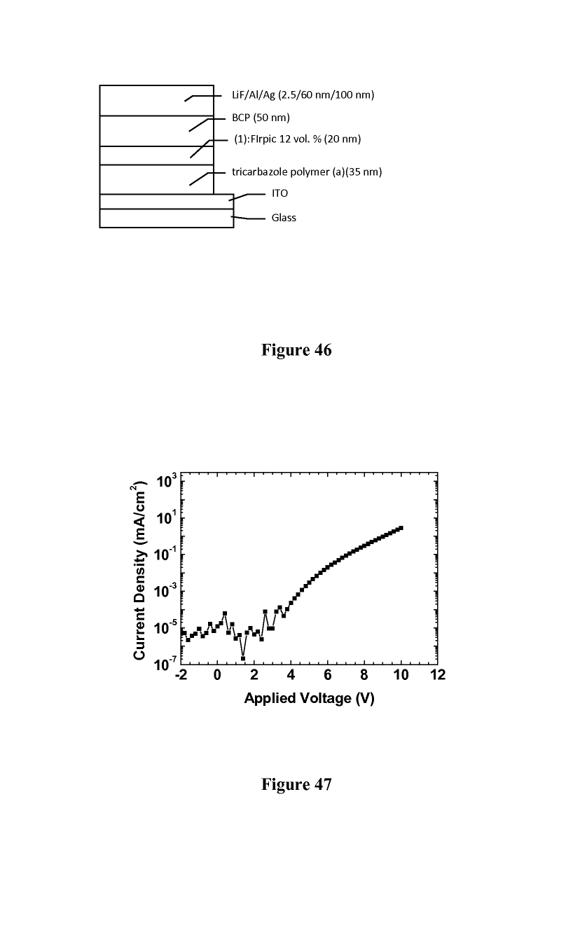

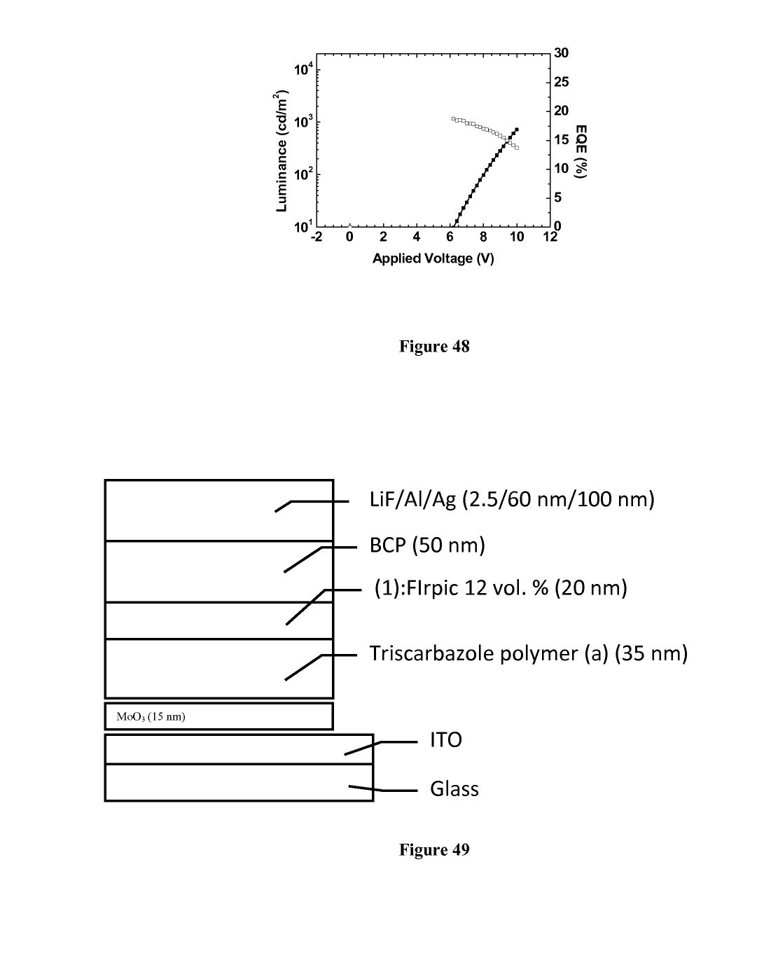

FIG. 46 shows a schematic of the resulting device, FIG. 47 shows the current density across an applied voltage and FIG. 48 shows the luminance and quantum efficiency across a voltage range.

### Example 21

### Using (1) as a Host in an Emissive Layer and Triscarbazole Polymer (a) as a Hole-Transport Material

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were O₂ plasma treated for 2 min.

The hole injection layer, MoO₃ was thermally evaporated at 0.2 Å/s. The pressure in the vacuum chamber was 1×10⁻⁷ Torr.

Triscarbazole polymer (a) was processed in the glove box under nitrogen. 10 mg of triscarbazole polymer (a) was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of a host—(1) and an emitter—Flrpic was deposited by co-evaporation of the two components at 0.88 Å/s and 0.12 Å/s respectively. The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

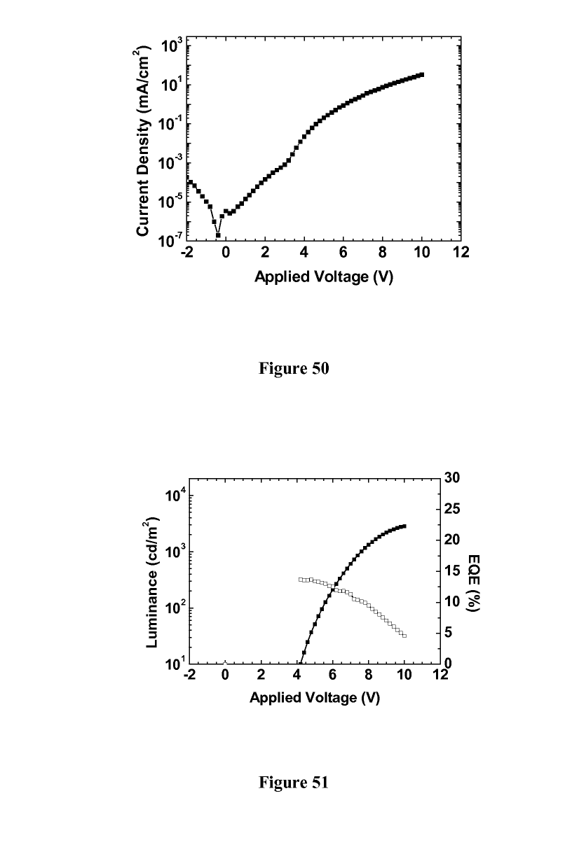

FIG. 49 shows a schematic of the resulting device, FIG. 50 shows the current density across an applied voltage and FIG. 51 shows the luminance and quantum efficiency across a voltage range.

### Example 22

### Using (1) as a Host in an Emissive Layer and Triscarbazole Polymer (a) as a Hole-Transport Material

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were O₂ plasma treated for 2 min.

Immediately after O₂ plasma treatment of the ITO slides, PEDOT:PSS AI4083 was spin-coated at 5000 rpm, acceleration—928 rpm/s for 60 sec. Subsequently, the films were heated on a hot plate at 140° C. for 15 min. PEDOT:PSS was deposited in air.

Triscarbazole polymer (a) was processed in the glove box under nitrogen. 10 mg of triscarbazole was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of a host—(1) and an emitter—Flrpic was deposited by co-evaporation of the two components at 0.88 Å/s and 0.12 Å/s respectively. The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

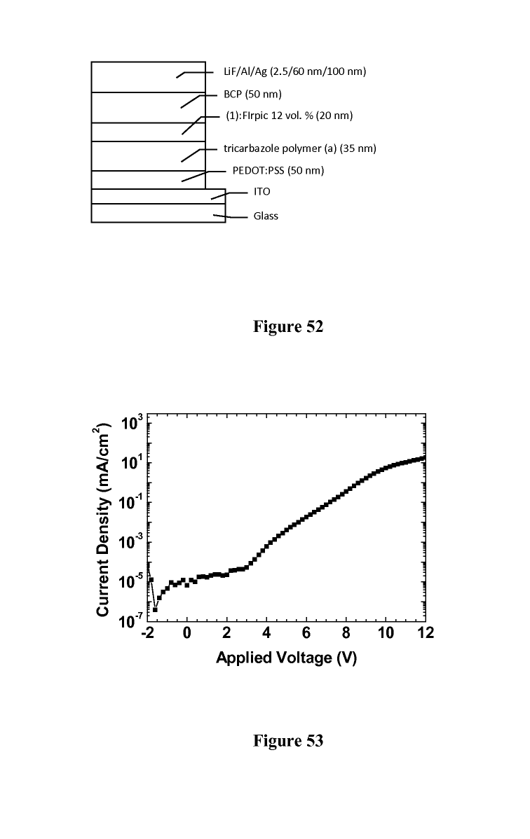

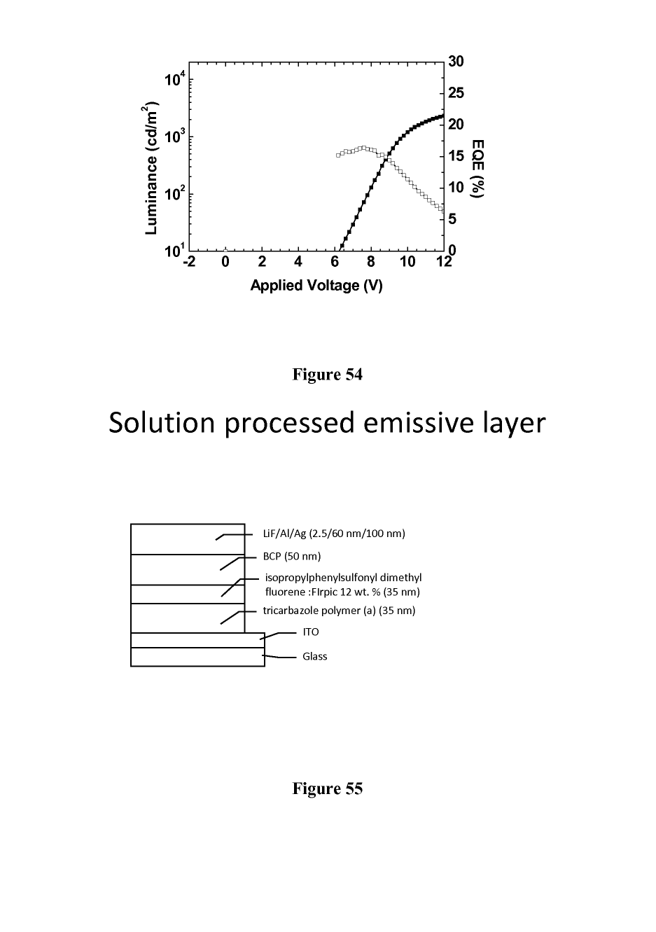

FIG. 52 shows a schematic of the resulting device, FIG. 53 shows the current density across an applied voltage and FIG. 54 shows the luminance and quantum efficiency across a voltage range.

### Example 23

### Solution Processed Emissive Layer of 1,7-bis(4′-isopropylphenylsulfonyl)-9,9-dimethyl-9H-fluorene

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were O₂ plasma treated for 2 min.

Triscarbazole polymer (a) was processed in the glove box under nitrogen. 10 mg of triscarbazole polymer (a) was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of the 1,7-bis(4-isopropylphenylsulfonyl)-9,9-dimethyl-9H-fluorene host and emitter was prepared in the following way in the glove box: 10 mg of 1,7-bis(4-isopropylphenylsulfonyl)-9,9-dimethyl-9H-fluorene was dissolved in 1 ml acetonitrile and 10 mg of Flrpic in 1 ml of acetonitrile. 128 μl of Flrpic was added to 1 ml of the solution of 1,7-bis(4-isopropylphenylsulfonyl)-9,9-dimethyl-9H-fluorene. The solution was then spin-coated onto the HTL at 1000 rpm, 1000 rpm/sec, 60 sec. The films were dried at 75° C. for 10-15 min.

The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

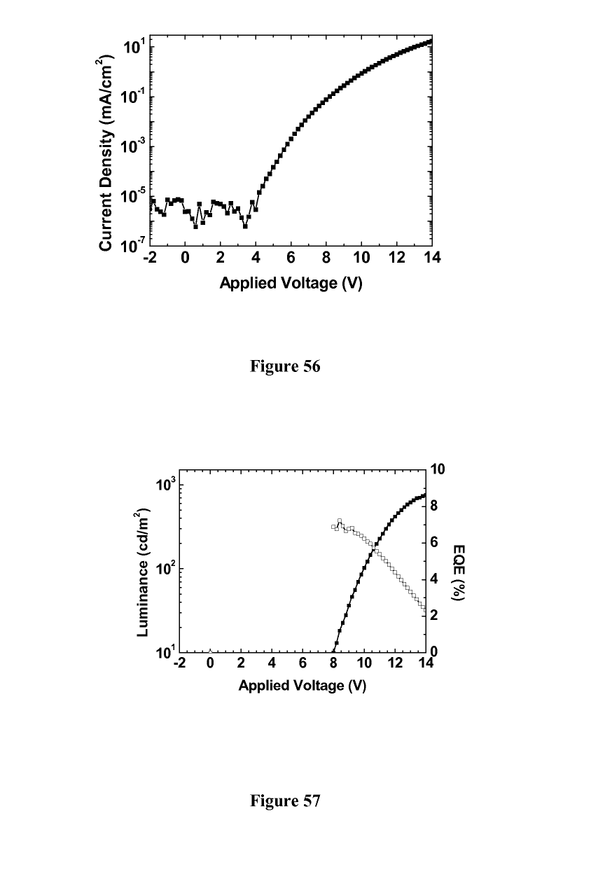

FIG. 55 shows a schematic of the resulting device, FIG. 56 shows the current density across an applied voltage and FIG. 57 shows the luminance and quantum efficiency across a voltage range.

### Example 24

### Solution Processed Emissive Layer of 1,7-bis(4-isopropylphenylsulfonyl)-9,9-dimethyl-9H-fluorene

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were O₂ plasma treated for 2 min.

Immediately after O₂ plasma treatment of the ITO slides, PEDOT:PSS A14083 was spin-coated at 5000 rpm, acceleration—928 rpm/s for 60 sec. Subsequently, the films were heated on a hot plate at 140° C. for 15 min. PEDOT:PSS was deposited in air.

Triscarbazole was processed in the glove box under nitrogen. 10 mg of triscarbazole polymer (a) was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of the 1,7-bis(4-isopropylphenylsulfonyl)-9,9-dimethyl-9H-fluorene host and emitter was prepared in the following way in the glove box: 10 mg of 1,7-bis(4-isopropylphenylsulfonyl)-9,9-dimethyl-9H-fluorene was dissolved in 1 ml acetonitrile and 10 mg of Flrpic in 1 ml of acetonitrile. 128 μl of Flrpic was added to 1 ml of the solution of 1,7-bis(4-isopropylphenylsulfonyl)-9,9-dimethyl-9H-fluorene. The solution was then spin-coated onto the HTL at 1000 rpm, 1000 rpm/sec, 60 sec. The films were dried at 75° C. for 10-15 min.

The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

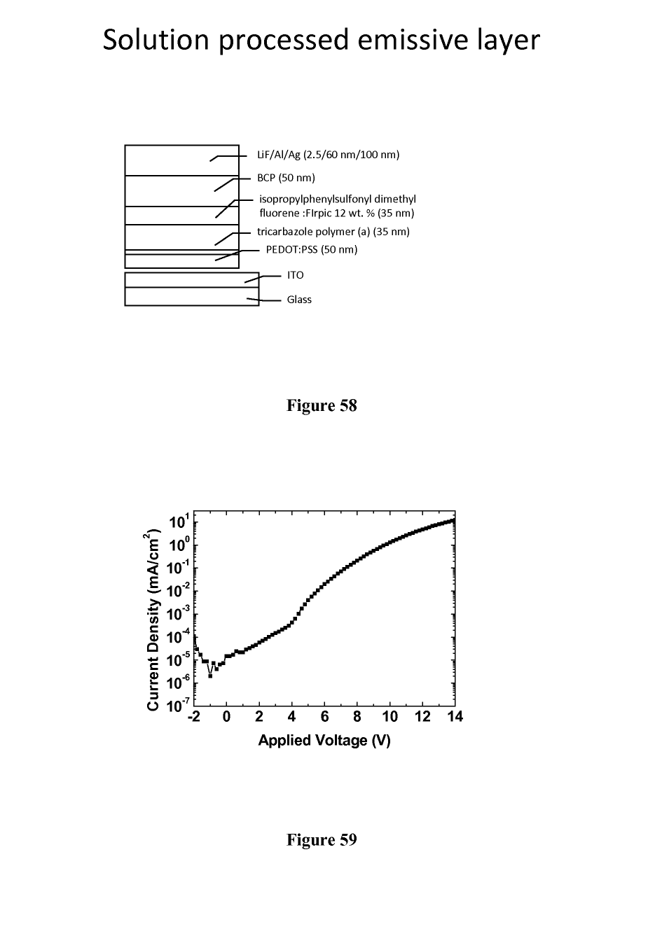

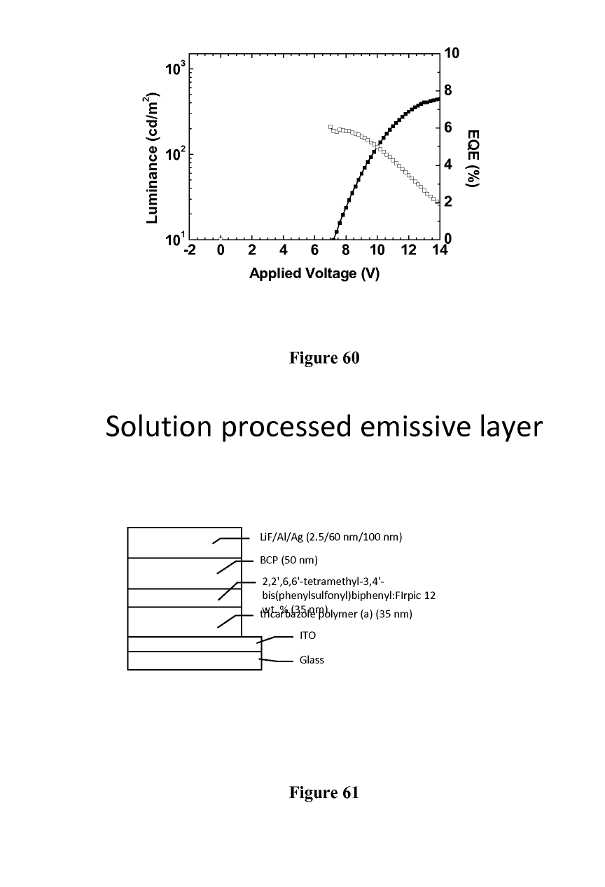

FIG. 58 shows a schematic of the resulting device, FIG. 59 shows the current density across an applied voltage and FIG. 60 shows the luminance and quantum efficiency across a voltage range.

### Example 25

### Solution Processed Emissive Layer of 2,2′,6,6′-tetramethyl-3,4′-bis(phenylsulfonyl)biphenyl

Indium tin oxide (ITO)-coated glass slides with a sheet resistivity of ˜15 Ω/sq were used as substrates for the OLEDs fabrication. The ITO substrates were masked with kapton tape and the exposed ITO was etched in acid vapor (1:3 by volume, HNO₃:HCl) for 5 min at 60° C. The substrates were cleaned in an ultrasonic bath in the following solutions: detergent water, distilled water, acetone, and isopropanol for 20 min in each step. At the end the substrates were blown dry with nitrogen. Subsequently, ITO substrates were 0, plasma treated for 2 min.

Triscarbazole polymer (a) was processed in the glove box under nitrogen. 10 mg of tricarbazole polymer (a) was dissolved in 1 ml of anhydrous chlorobenzene. 35 nm thick films of the hole-transport material were spin-coated at 1500 rpm, acceleration 1,000 rpm/sec for 60 sec. The films were then heated on a hot plate at 120° C. for 20 minutes.

Emissive layer, consisting of the 2,2′,6,6′-tetramethyl-3,4′-bis(phenylsulfonyl)biphenyl host and emitter was prepared in the following way in the glove box: 10 mg of 2,2′,6,6′-tetramethyl-3,4′-bis(phenylsulfonyl)biphenyl was dissolved in 1 ml acetonitrile and 10 mg of Flrpic in 1 ml of acetonitrile. 128 μl of Flrpic was added to 1 ml of the solution of 2,2′,6,6′-tetramethyl-3,4′-bis(phenylsulfonyl)biphenyl. The solution was then spin-coated onto the HTL at 1000 rpm, 1000 rpm/sec, 60 sec. The films were dried at 75° C. for 10-15 min.

The electron transport layer, BCP, the electron-injection layer, LiF and aluminum were thermally evaporated at 1 Å/s, 0.2 Å/s and 2 Å/s respectively. The pressure in the vacuum chamber was 1×10⁻⁷ Torr. The active area of the tested devices was about 0.1 cm². The devices were tested in a glove box under nitrogen.

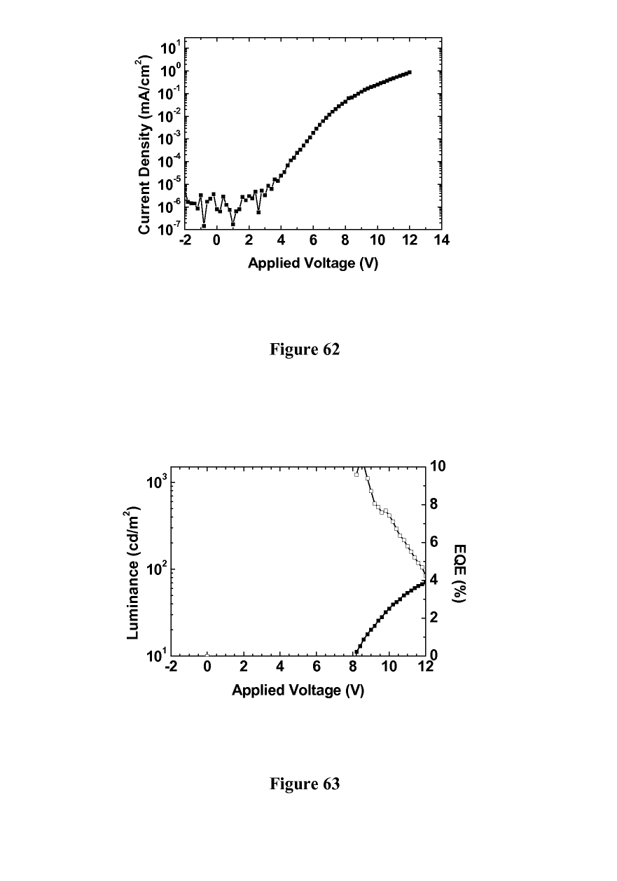

FIG. 61 shows a schematic of the resulting device, FIG. 62 shows the current density across an applied voltage and FIG. 63 shows the luminance and quantum efficiency across a voltage range.

### CONCLUSIONS

The above specification, examples and data provide exemplary description of the manufacture and use of the various compositions and devices of the inventions, and methods for their manufacture and use. In view of those disclosures, one of ordinary skill in the art will be able to envision many additional specific aspects, embodiments, and/or sub-genera of the inventions disclosed and claimed herein to be obvious, and that they can be made without departing from the various inventions explicitly described herein. The claims hereinafter appended define some of those aspects, embodiments, and/or sub-genera.

1. An electronic device comprising one of more compounds having the formula: 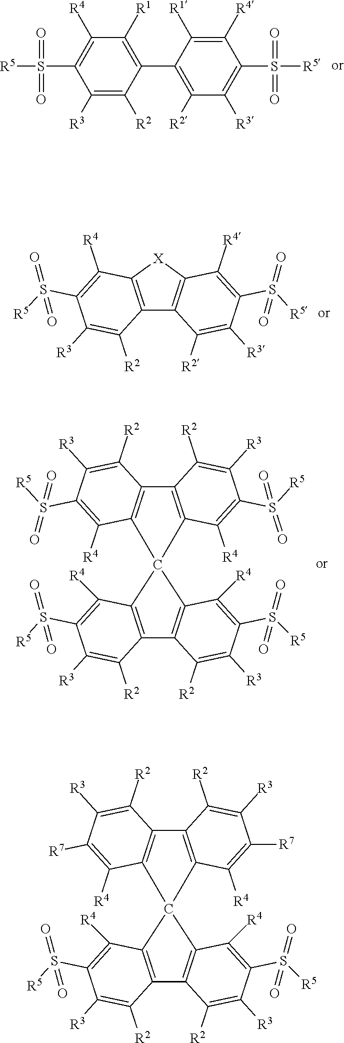
wherein
a) each of R¹-R⁴, R^{1′}-R^{4′} and R⁷ are independently selected from hydrogen, halogen, cyano, or an independently selected and optionally substituted C₁-C₃₀ organic group selected from alkyl, perfluoroalkyl, alkoxy, perfluoroalkoxy, aryl, and heteroaryl groups;
b) each of R⁵ and R^{5′} are independently selected from optionally substituted C₁-C₃₀ organic groups selected from alkyl, perfluoroalkyl, alkoxy, perfluoroalkoxy, aryl, or heteroaryl groups;
c) X is S, S(O), SO₂, or a C₁-C₃₀ organic group selected from C(R⁶)₂, C(R⁶)Ar, C(Ar)₂, Si(R⁶)₂, Si(R⁶)Ar, Si(Ar)₂, NR⁶, NAr, PR⁶, PAr, P(O)R⁶, or P(O)Ar group, wherein
i) R⁶ is a C₁-C₂₀ alkyl or perfluoroalkyl group, and
ii) Ar is a C₁-C₃₀ aryl or heteroaryl group that does not comprise a diphenyl amine group.

2. The electronic device of claim 1 wherein the one or more compounds have the formula

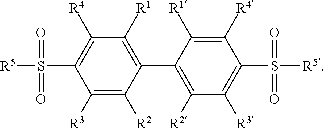

3. The electronic device of claim 1 wherein the one or more compounds have the formula

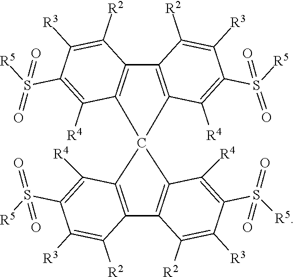

4. The electronic device of claim 1 wherein the one or more compounds have the formula

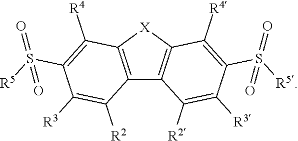

5. The electronic device of claim 1 wherein the one or more compounds have the formula

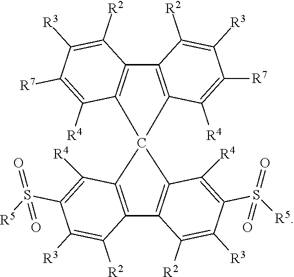

6. The electronic device of any one of claims 1-5 wherein each of R¹-R⁴, R^{1′}-R^{4′} and R⁷ are independently selected from hydrogen, cyano, alkyl, and perfluoroalkyl.

7. The electronic device of claim 1 or 4 wherein X is C(R⁶)₂.

8. The electronic device of claim 1 or 4 wherein X is C(R⁶)Ar.

9. The electronic device of claim 1 or 4 wherein X is a S, S(O), SO₂, or a C₁-C₃₀ organic group selected from C(R⁶)₂, C(R⁶)Ar, Si(R⁶)₂, Si(R⁶)Ar, or Si(Ar)₂, group.

10. The electronic device of any one of claims 8 and 9 wherein Ar is a phenyl, fluorinated phenyl, pyridyl, pyrazine, or pyridazine group.

11. The electronic device of any one of claims 1-5 wherein R⁵ and R^{5′} are independently selected alkyl or perfluoroalkyl groups.

12. The electronic device of any one of claims 1-5 wherein R⁵ and R^{5′} are independently selected aryl groups having the structure 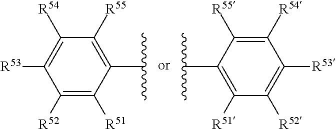
wherein each of R⁵¹-R⁵⁵ and R^{51′}-R^{55′} are independently selected from hydrogen, halogen, cyano, or an independently selected and optionally substituted C₁-C₃₀ organic group selected nom alkyl, perfluoroalkyl, alkoxy, perfluoroalkoxy, aryl, or heteroaryl group

13. The electronic device of any one of claims 1-12 wherein the compound:
a) a lowest singlet excited state at an energy of about 2.27 eV or higher, and
b) has a lowest triplet excited state at an energy of about 2.17 eV or higher.

14. The electronic device of any one of claims 1-12 wherein the compound:
a) a lowest singlet excited state at an energy of about 2.63 eV or higher, and
b) has a lowest triplet excited state at an energy of about 2.53 eV or higher.

15. The electronic device of any one of claims 1-14 that is a light-emitting diode.

16. The electronic device of claim 15 wherein the light-emitting diode comprises an electron transporting layer that comprises the one or more of the compounds.

17. The electronic device of claim 15 wherein the light-emitting diode comprises an emissive layer that comprises the one or more compounds as a host material, and a phosphorescent emitter.

18. The electronic device of claim 17 wherein the phosphorescent emitter emits blue or green light.

19. The electronic device of claim 17 wherein the phosphorescent emitter does not emit red light.

20. The electronic device of claim 17 wherein fluorescent emission spectrum of the one or more compounds overlaps with the absorption spectrum of the phosphorescent emitter.

21. The electronic device of any one of claims 1-20 wherein the device is a light-emitting diode, and the one or more compounds are applied during the manufacture of the device by a vacuum deposition.

22. The electronic device or any one of claims 1-20 wherein the one or more compounds are applied during the manufacture of the device by a solution deposition process.

23. A compound having the formula 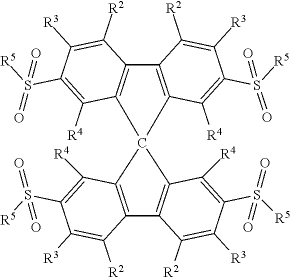
wherein
a) each of R¹-R⁴ and R^{1′}-R^{4′} are independently selected from hydrogen, halogen, cyano, or an independently selected and optionally substituted C₁-C₃₀ organic group selected from alkyl, perfluoroalkyl, alkoxy, perfluoroalkoxy, aryl, and heteroaryl groups;
b) each of R⁵ and R^{5′} are independently selected from optionally substituted C₁-C₃₀ organic groups selected from alkyl, perfluoroalkyl, alkoxy, perfluoroalkoxy, aryl, or heteroaryl groups.

24. The compounds of claim 23 that:
a) a lowest singlet excited state at an energy of about 2.48 eV or higher, and
b) has a lowest triplet excited state at an energy of about 2.40 eV or higher.

25. The compounds of claim 23 that:
a) have a lowest singlet excited state at an energy of about 2.75 eV or higher, and
b) has a lowest triplet excited state at an energy of about 2.70 eV or higher.

26. A compound having the formula 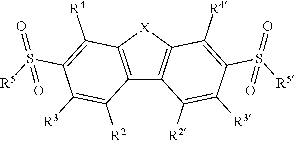
wherein
a) each of R¹-R⁴ and R^{1′}-R^{4′} are independently selected from hydrogen, halogen, cyano, or an independently selected and optionally substituted C₁-C₃₀ organic group selected from alkyl, perfluoroalkyl, alkoxy, perfluoroalkoxy, aryl, and heteroaryl groups;
b) each of R⁵ and R^{5′} are independently selected from optionally substituted C₁-C₃₀ organic groups selected from alkyl, perfluoroalkyl, alkoxy, perfluoroalkoxy, aryl, or heteroaryl groups;
c) X is S, S(O), SO₂, or a C₁-C₃₀ organic group selected from C(R⁶)₂, C(R⁶)Ar, C(Ar)₂, Si(R⁶)₂, Si(R⁶)Ar, Si(Ar)₂, NR⁶, NAr, PR⁶, PAr, P(O)R⁶, or P(O)Ar group, wherein
i) R⁶ is a C₁-C₂₀ alkyl or perfluoroalkyl group,
ii) Ar is a C₁-C₃₀ aryl or heteroaryl group that does not comprise a diphenyl amine group.

27. The compounds of claim 26 wherein X is a S, S(O), SO₂, or a C₁-C₃₀ organic group selected from C(R⁶)₂, C(R⁶)Ar, Si(R⁶)₂, Si(R⁶)Ar, or Si(Ar)₂, group.

28. The compounds of claim 26 wherein X is C(R⁶)₂.

29. The compounds of claim 28 wherein R⁶ is independently selected from hydrogen, fluoride, cyano, C₁-C₄ alkyl, C₁-C₄ perfluoroalkyl, phenyl, and perfluorophenyl.

30. The compounds of any one of claims—26-29 that:
a) a lowest singlet excited state at an energy of about 2.48 eV or higher, and
b) have a lowest triplet excited state at an energy of about 2.40 eV or higher.

31. The compounds or any one of claims 25-28 that:
a) have a lowest singlet excited state at an energy of about 2.75 eV or higher, and
b) has a lowest triplet excited state at an energy of about 2.70 eV or higher.

32. A compound having the formula 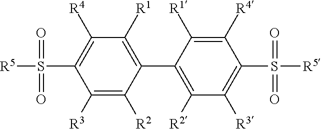
wherein
a) each of R¹-R⁴ and R^{1′}-R^{4′} are independently selected from hydrogen, halogen, cyano, or an independently selected and optionally substituted C₁-C₃₀ organic group selected from alkyl, perfluoroalkyl, alkoxy, perfluoroalkoxy, aryl, and heteroaryl groups, with the proviso that at least one of R¹-R⁴ and R^{1′}-R^{4′} are not hydrogen;
b) each of R⁵ and R^{5′} are independently selected from optionally substituted C₁-C₃₀ organic groups selected from alkyl, perfluoroalkyl, alkoxy, perfluoroalkoxy, aryl, or heteroaryl groups.

33. The compounds of claim 32 wherein at least one of R¹ and R^{1′} is independently selected from optionally substituted fluoro, cyano, or C₁-C₃₀ alkyl, alkoxy, perfluoroalkyl, perfluoroalkoxy, aryl, and heteroaryl groups.

34. The compounds of claim 32 wherein at least two of R¹, R^{1′}, R², and R^{2′} are independently selected from optionally substituted fluoro, cyano, or C₁-C₃₀ alkyl, alkoxy, perfluoroalkyl, perfluoroalkoxy, aryl, and heteroaryl groups.

35. The compounds of claim 32 that:
a) have a lowest singlet excited state at an energy of about 2.48 eV or higher, and
b) has a lowest triplet excited state at an energy or about 2.40 eV or higher.

36. The compounds of claim 32 that:
a) have a lowest singlet excited state at an energy of about 2.75 eV or higher, and
b) has a lowest triplet excited state at an energy of about 2.70 eV or higher.

37. A compound having the formula 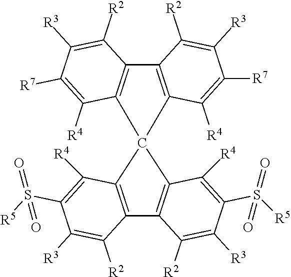
wherein
a) each of R¹-R⁴, R^{1′}-R^{4′} and R⁷ are independently selected from hydrogen, halogen, cyano, or an independently selected and optionally substituted C₁-C₃₀ organic group selected from alkyl, perfluoroalkyl, alkoxy, perfluoroalkoxy, aryl, and heteroaryl groups;
b) each of R⁵ and R^{5′} are independently selected from optionally substituted C₁-C₃₀ organic groups selected from alkyl, perfluoroalkyl, alkoxy, perfluoroalkoxy, aryl, or heteroaryl groups.

38. The compounds of claim 37 that:
a) have a lowest singlet excited state at an energy of about 2.48 eV or higher, and
b) have a lowest triplet excited state at an energy of about 2.40 eV or higher.

39. The compounds of claim 37 that:
a) have a lowest singlet excited state at an energy of about 2.75 eV or higher, and
b) have a lowest triplet excited state at an energy of about 2.70 eV or higher.
